(19) United States
(12) Patent Application Publication
(10) Pub. No.: US 2026/0354010 A1
(43) Pub. Date: Nov. 5, 2026

(54) METAL IRIDIUM COMPLEX AND ORGANIC ELECTROLUMINESCENT DEVICE

(71) Applicant: GUANGDONG AGLAIA OPTOELECTRONIC MATERIALS CO., LTD, Guangdong (CN)

(72) Inventors: Xiaofeng TAN, Guangdong (CN); Shaofu CHEN, Guangdong (CN); Jiahui TAN, Guangdong (CN); Xu WANG, Guangdong (CN); Lei DAI, Guangdong (CN); Lifei CAI, Guangdong (CN)

(73) Assignee: GUANGDONG AGLAIA OPTOELECTRONIC MATERIALS CO., LTD, Guangdong (CN)

(21) Appl. No.: 19/649,312

(22) Filed: Apr. 16, 2026

(30) Foreign Application Priority Data
Apr. 16, 2025 (CN) 202510483155.3

(51) Int. Cl. H10K 85/30; C07B 59/00; C07F 15/00; C09K 11/06; H10K 50/12

(52) U.S. Cl. CPC H10K 85/342; C07B 59/004; C07F 15/0033; C09K 11/06; C09K 2211/1007; C09K 2211/1029; C09K 2211/1033; C09K 2211/1088; C09K 2211/185; H10K 50/12

(57) ABSTRACT

A metal iridium complex and use thereof. The metal iridium complex has a general formula of Ir(La)(Lb)(Lc), and a structure is shown in formula (1).

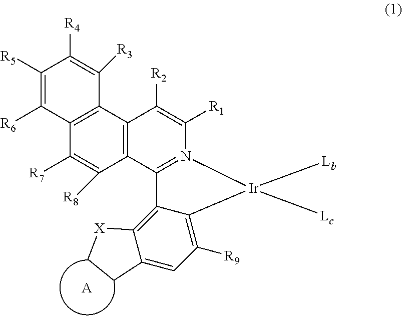

### CROSS-REFERENCE TO RELATED APPLICATIONS

The present application claims priority to Chinese Patent Application No. 202510483155.3, filed Apr. 16, 2025, the entire disclosures of which are incorporated herein by reference.

### TECHNICAL FIELD

The present disclosure relates to the technical field of organic electroluminescence, in particular, to an organic luminescent material, and more particularly, to a metal iridium complex and use thereof in an organic electroluminescent device.

### BACKGROUND

Organic electroluminescent devices (OLEDs), as a new generation of display and lighting technologies, have attracted extensive attention and possess broad application prospects. The basic structure of an OLED device is a sandwich-like structure composed of various organic functional material thin films sandwiched between metal iridium electrodes. Driven by an electric current, holes and electrons are injected from the anode and cathode respectively. After migrating for a certain distance, the holes and electrons recombine in the light-emitting layer and release energy in the form of light or heat, thereby realizing the light emission of OLEDs. However, the key performance indicators of existing devices, such as luminous efficiency, driving voltage and service lifespan, still need to be optimized and improved.

The organic functional materials are the core compositions of the organic electroluminescent device, and their thermal stability, photochemical stability, electrochemical stability, quantum yield, film forming stability, crystallinity, color saturation, and other properties are all important factors affecting the performance of the device.

Organic functional materials generally include fluorescent materials and phosphorescent materials. Fluorescent materials are usually organic small molecule materials, generally, only 25% of the singlet luminescence is used, resulting in low luminous efficiency. In contrast, phosphorescent materials can utilize not only 25% of singlet state but also 75% of triplet exciton energy due to the spin-orbit coupling induced by the heavy atom effect, leading to a significant improvement in luminous efficiency. Nevertheless, compared with fluorescent materials, phosphorescent materials have a relatively late development history, and their thermal stability, lifespan, color saturation and other properties still need to be enhanced, which remains challenging.

At present, various organometallic iridium compounds have been developed as such phosphorescent materials. For example, patent application CN111039987A discloses a class of metal iridium complexes

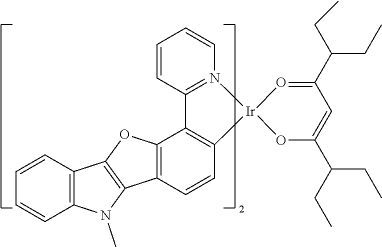

with a compound that connects a heterofused ring to a pyridine ring as a ligand, but the stability of such materials needs to be improved. Patent application US20180097185A1 discloses a green iridium complex

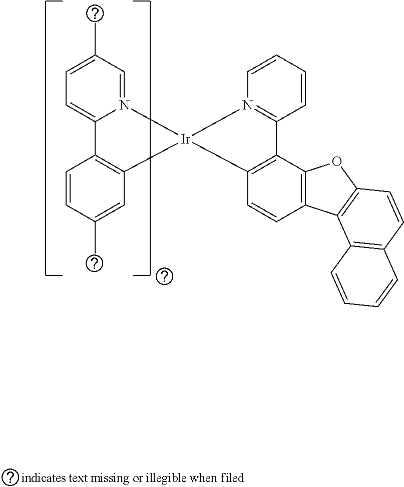

with naphthobenzofuran connected to pyridine as a ligand, such materials are conducive to spectrum narrowing but exhibit unsatisfactory luminous efficiency. Patent application CN116444573A discloses an iridium complex with naphthobenzofuran connected to N-heterodibenzothiophene

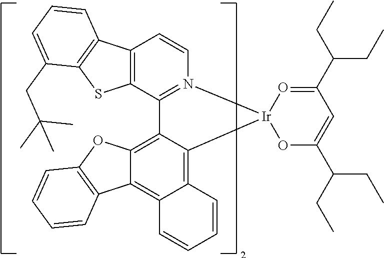

as a ligand, but such materials have a relatively wide full width at half maximum (FWHM), and their color saturation and device efficiency need to be further improved.

Therefore, it is necessary to further develop novel materials capable of improving the performance of organic electroluminescent devices.

### SUMMARY

The present disclosure aims to solve at least one of the technical problems existing in the existing technologies. To this end, the present disclosure proposes a metal iridium complex and use thereof, thereby providing a high-performance organic electroluminescent device and a novel material capable of preparing such an organic electroluminescent device.

To achieve the aforementioned objective, the present applicant has repeatedly conducted in-depth studies and as a result, found that a high-performance organic electroluminescent device can be obtained by using a metal iridium complex containing a structure represented by the following formula (1) as a ligand.

One of the objectives of the present disclosure is to provide a metal iridium complex, which has the advantages of a low vapor deposition temperature, a high photochemical and electrochemical stability, a narrow half width at half maximum, a high color saturation, a high luminous efficiency, and a long device lifespan, and can be used in organic electroluminescent devices. Especially as a red light-emitting dopant, it has the potential to be applied in the OLED industry.

In some embodiments, the metal iridium complex has a general formula of Ir(La)(Lb)(Lc), and a structural formula represented by formula (1):

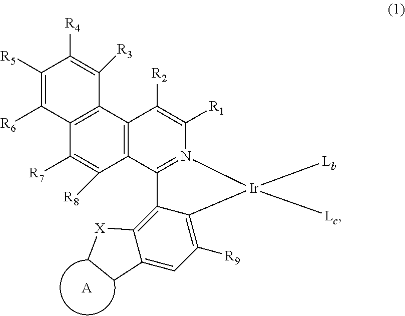

wherein:

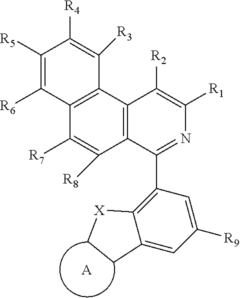

is a ligand La;
X is selected from the group consisting of O, S, and Se;
ring A is selected from the group consisting of a substituted or unsubstituted naphthalene ring, a substituted or unsubstituted phenanthrene ring, a substituted or unsubstituted azanaphthalene ring, and a substituted or unsubstituted azaphenanthrene ring;
R₁-R₉ are each independently selected from the group consisting of hydrogen, deuterium, halogen, cyano, isocyano, phosphino, substituted or unsubstituted C1-C40 alkyl, substituted or unsubstituted C3-C40 cycloalkyl, substituted or unsubstituted C1-C40 heteroalkyl, substituted or unsubstituted C3-C40 heterocycloalkyl, substituted or unsubstituted C3-C30 alkylsilyl, substituted or unsubstituted C1-C10 alkoxy, substituted or unsubstituted C7-C30 aralkyl, substituted or unsubstituted C6-C30 aryloxy, substituted or unsubstituted C2-C20 alkenyl, substituted or unsubstituted C2-C20 alkynyl, substituted or unsubstituted C6-C30 aryl, substituted or unsubstituted C3-C30 heteroaryl, substituted or unsubstituted C6-C30 arylsilyl, and substituted or unsubstituted C0-C20 alkylamino;
each substitution in R₁-R₉ is at least one selected from the group consisting of deuterium, F, Cl, Br, cyano, isocyano, phosphino, C1-C4 alkyl, C1-C4 alkoxy, C3-C6 cycloalkyl, and C1-C4 alkyl-substituted amino, wherein a number of substitutions ranges from monosubstitution to a maximum number of substitutions;
a heteroatom in the heteroalkyl, heterocycloalkyl, or heteroaryl is at least one selected from the group consisting of S, O, and N;
Lb and Lc are each a monoanionic bidentate ligand; optionally, any two of La, Lb, and Lc are connected by chemical bonds to form a multidentate ligand, or all three of La, Lb, and Lc are connected pairwise by chemical bonds to form a multidentate ligand; and
at least two of La, Lb and Lc are the same.

Compared with the existing technologies, the beneficial effects of the present disclosure are as follows:

The metal iridium complex material of the present disclosure has the advantages of a high photochemical and electrochemical stability, a narrow half width at half maximum, a high color saturation, a high luminous efficiency, and a long device lifespan, and can be used in organic electroluminescent devices. The metal iridium complex material described herein, as a deep red phosphorescent material, can convert triple excited states into light, improve the luminous efficiency of organic electroluminescent devices, thereby reducing energy consumption, and has the potential to be applied in the OLED industry.

Other features and advantages of the present disclosure will be set forth in part in the description below, and in part will be obvious from the description, or may be learned by practice of the present disclosure.

### BRIEF DESCRIPTION OF THE DRAWINGS

The present disclosure will be further described below with reference to the accompanying drawings and embodiments, wherein:

FIG. 1 is a ¹HNMR spectrum of the compound Ir(La017)₂(Lb007) of the present disclosure in deuterated chloroform solution;

FIG. 2 is an emission spectrum of the compound Ir(La017)₂(Lb007) of the present disclosure in toluene solution; and

FIG. 3 is a structural representation of an organic electroluminescent device according to an embodiment of the present disclosure.

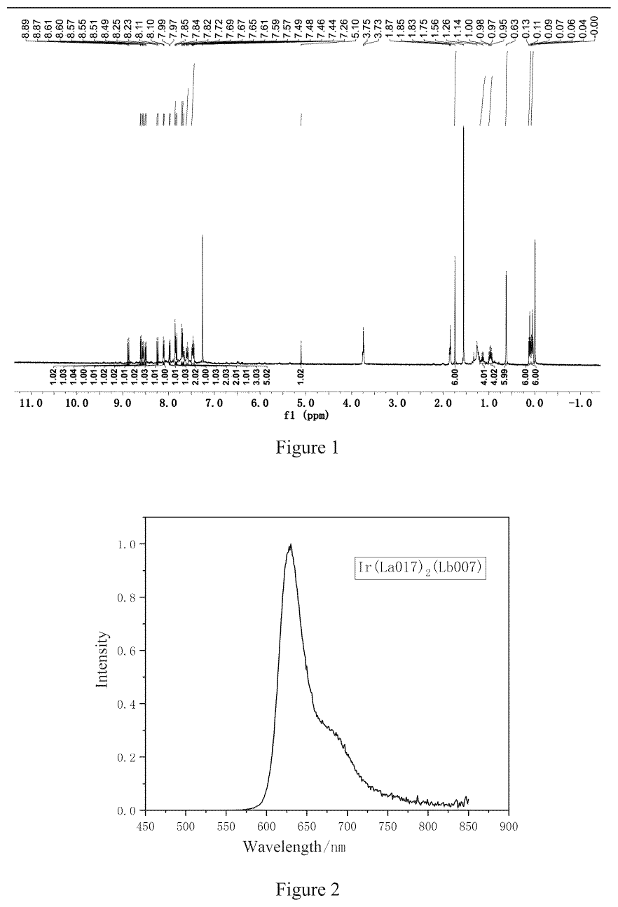

### DETAILED DESCRIPTION

To enable those skilled in the art to understand the technical solutions described in the present disclosure more clearly, the following embodiments are provided for illustration. It should be noted that the following embodiments do not constitute a limitation on the protection scope claimed in the present disclosure.

Unless otherwise specified, the raw materials, reagents or devices used in the following examples are all commercially available through conventional channels or can be obtained by existing known methods.

In the description of the present disclosure, references to terms such as “some embodiments” mean that the specific features, structures, materials or characteristics described in connection with such embodiment or example are included in at least one embodiment or example of the present disclosure. In this description, the schematic representations of the above terms do not necessarily refer to the same embodiment or example. Furthermore, the specific features, structures, materials or characteristics described may be combined in any one or more embodiments or examples in a suitable manner.

In the description of the present disclosure, the descriptions of “first”, “second”, “third”, etc., are only for the purpose of distinguishing technical features, and shall not be construed as indicating or implying relative importance, or implicitly indicating the number of the indicated technical features, or implicitly indicating the sequential relationship of the indicated technical features.

According to a first aspect of the present disclosure, a metal iridium complex is provided. The metal iridium complex has a general formula of Ir(La)(Lb)(Lc), and a structure formula represented by formula (1):

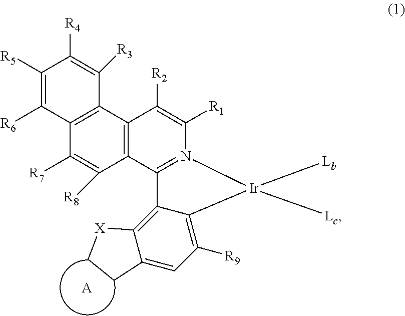

wherein:

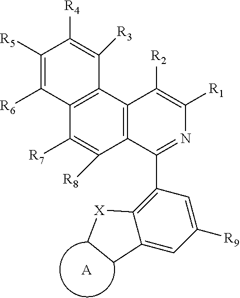

is a ligand La;
X is selected from the group consisting of O, S, and Se;
ring A is selected from the group consisting of a substituted or unsubstituted naphthalene ring, a substituted or unsubstituted phenanthrene ring, a substituted or unsubstituted azanaphthalene ring, and a substituted or unsubstituted azaphenanthrene ring;
R₁-R₉ are each independently selected from the group consisting of hydrogen, deuterium, halogen, cyano, isocyano, phosphino, substituted or unsubstituted C1-C40 alkyl, substituted or unsubstituted C3-C40 cycloalkyl, substituted or unsubstituted C1-C40 heteroalkyl, substituted or unsubstituted C3-C40 heterocycloalkyl, substituted or unsubstituted C3-C30 alkylsilyl, substituted or unsubstituted C1-C10 alkoxy, substituted or unsubstituted C7-C30 aralkyl, substituted or unsubstituted C6-C30 aryloxy, substituted or unsubstituted C2-C20 alkenyl, substituted or unsubstituted C2-C20 alkynyl, substituted or unsubstituted C6-C30 aryl, substituted or unsubstituted C3-C30 heteroaryl, substituted or unsubstituted C6-C30 arylsilyl, and substituted or unsubstituted C0-C20 alkylamino;
each substitution in R₁-R₉ is at least one selected from the group consisting of deuterium, F, Cl, Br, cyano, isocyano, phosphino, C1-C4 alkyl, C1-C4 alkoxy, C3-C6 cycloalkyl, and C1-C4 alkyl-substituted amino, wherein a number of substitutions ranges from monosubstitution to a maximum number of substitutions;
a heteroatom in the heteroalkyl, heterocycloalkyl, or heteroaryl is at least one selected from the group consisting of S, O, and N;
Lb and Lc are each a monoanionic bidentate ligand; optionally, any two of La, Lb, and Lc are connected by chemical bonds to form a multidentate ligand, or all three of La, Lb, and Lc are connected pairwise by chemical bonds to form a multidentate ligand; and
at least two of La, Lb and Lc are the same.

In some embodiments, a number of aza in the azanaphthalene ring or azaphenanthrene ring is from mono-aza to a maximum number of aza, for example mono-aza, di-aza, or tri-aza.

In some embodiments, the azanaphthalene ring or azaphenanthrene ring is a mono-azanaphthalene ring or a mono-azaphenanthrene ring.

In some embodiments, the ring A is one of the following structures: a substituted or unsubstituted naphthalene ring, a substituted or unsubstituted quinoline ring, a substituted or unsubstituted isoquinoline ring, a substituted or unsubstituted phenanthrene ring, a substituted or unsubstituted benzo[h]isoquinoline ring, a substituted or unsubstituted benzo[f]isoquinoline ring, or a substituted or unsubstituted 6-benzo[f]quinoline ring.

In some embodiments, the ligand La is one of the structures represented by the following formulas (2) to (7):

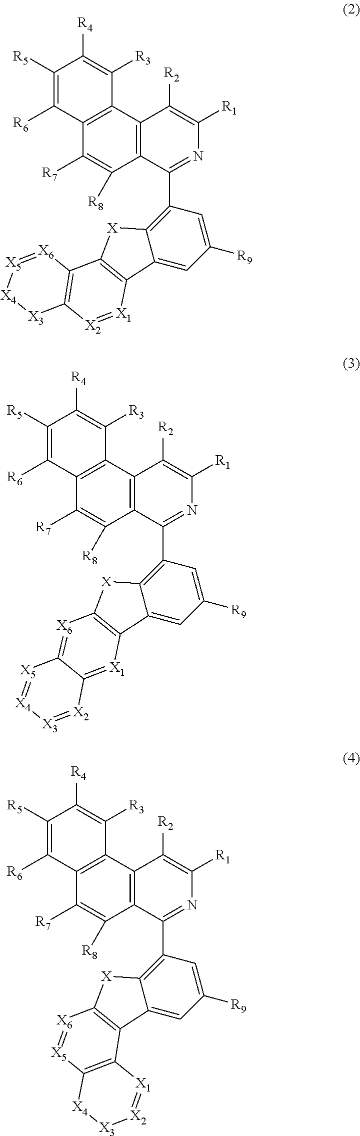

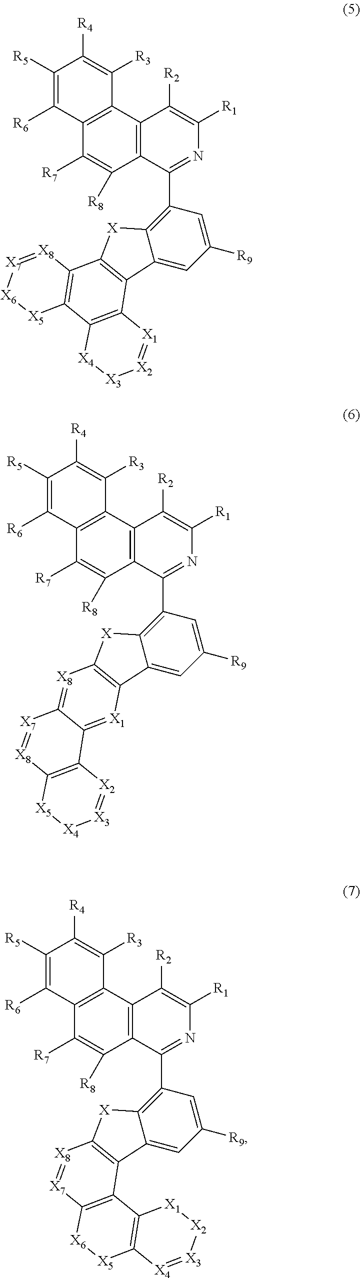

wherein:
X₁-X₈ are each independently selected from the group consisting of CR₀ and N;
R₀ is independently selected from the group consisting of hydrogen, deuterium, cyano, nitro, halogen, C1-C40 alkyl, C1-C40 heteroalkyl, C2-C40 alkenyl, C2-C40 alkynyl, C3-C40 cycloalkyl, C3-C40 heterocycloalkyl, C1-C40 alkoxy, C7-C30 aralkyl, C6-C30 aryloxy, C6-C30 aryl, C3-C30 heteroaryl,

C3-C40 alkylsilane group, and C1-C40 alkylboryl.

In some embodiments, at most two of X₁-X₈ are N.

In some embodiments, at most one of X₁-X₈ is N.

In some embodiments, X₃ or X₄ in formula (2) is N; X₁, X₃ or X₆ in formula (3) is N; X₃, X₄, X₅ or X₆ in formula (4) is N; X₂ in formula (5) is N; and X₂, X₇ or X₈ in formula (7) is N.

In some embodiments, R₀ is independently selected from the group consisting of hydrogen, deuterium, cyano, nitro, halogen, C1-C30 alkyl, C1-C30 heteroalkyl, C2-C30 alkenyl, C2-C30 alkynyl, C3-C30 cycloalkyl, C3-C30 heterocycloalkyl, C1-C30 alkoxy, C7-C20 aralkyl, C6-C20 aryloxy, C6-C20 aryl, C3-C20 heteroaryl, C3-C30 alkylsilane group, and C1-C30 alkylboryl.

In some embodiments, R₀ is independently selected from the group consisting of hydrogen, deuterium, cyano, nitro, halogen, C1-C20 alkyl, C1-C20 heteroalkyl, C2-C20 alkenyl, C2-C20 alkynyl, C3-C20 cycloalkyl, C3-C20 heterocycloalkyl, C1-C20 alkoxy, C7-C18 aralkyl, C6-C18 aryloxy, C6-C18 aryl, C3-C18 heteroaryl, C3-C20 alkylsilane group, and C1-C20 alkylboryl.

In some embodiments, R₀ is independently selected from the group consisting of hydrogen, deuterium, cyano, halogen, C1-C20 alkyl, C3-C20 cycloalkyl, C3-C20 heterocycloalkyl, C6-C18 aryl, and C3-C18 heteroaryl.

In some embodiments, R₀ is independently selected from the group consisting of hydrogen, deuterium, cyano, halogen, C1-C10 alkyl, C3-C10 cycloalkyl or C6-C12 aryl, and C3-C12 heteroaryl.

In some embodiments, R₀ is independently selected from the group consisting of hydrogen, deuterium, cyano, halogen, C1-C6 alkyl, C3-C6 cycloalkyl or C6-C10 aryl, and C3-C10 heteroaryl.

In some embodiments, R₀ is independently selected from the group consisting of hydrogen, deuterium, cyano, phenyl, F, and C1-C4 alkyl.

In some embodiments, Lb is a structure represented by formula (8):

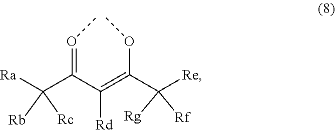

wherein:
a dotted line indicates a position connected to the metal iridium Ir;
Ra-Rg are each independently selected from the group consisting of hydrogen, deuterium, halogen, substituted or unsubstituted C1-C40 alkyl, substituted or unsubstituted C3-C40 cycloalkyl, substituted or unsubstituted C1-C40 heteroalkyl, and substituted or unsubstituted C3-C40 heterocycloalkyl;
optionally, any two of Ra, Rb, and Rc are connected to form an aliphatic ring structure, and optionally, any two of Re, Rf, and Rg are connected to form an aliphatic ring structure;
each substitution in Ra-Rg is at least one selected from the group consisting of deuterium, F, Cl, Br, cyano, isocyano, phosphino, C1-C4 alkyl, C1-C4 alkoxy, C3-C6 cycloalkyl, and C1-C4 alkyl-substituted amino, wherein a number of substitutions ranges from monosubstitution to a maximum number of substitutions.

In some embodiments, the aliphatic ring structure may be a 3- to 20-membered liphatic ring structure; in some embodiments, the aliphatic ring structure may be a 3- to 10-membered aliphatic ring structure; in some embodiments, the aliphatic ring structure may be a 3- to 6-membered aliphatic ring structure, for example, a 5-membered or 6-membered aliphatic ring structure.

In some embodiments, Ra, Rb, Rc are the same as Re, Rf, Rg, respectively.

In some embodiments, Ra-Rg are each independently selected from the group consisting of hydrogen, deuterium, halogen, substituted or unsubstituted C1-C30 alkyl, substituted or unsubstituted C3-C30 cycloalkyl, substituted or unsubstituted C1-C30 heteroalkyl, and substituted or unsubstituted C3-C30 heterocycloalkyl.

In some embodiments, Ra, Rb, Rc, Re, Rf, and Rg are each independently selected from the group consisting of hydrogen, deuterium, halogen, substituted or unsubstituted C1-C20 alkyl, or substituted or unsubstituted C3-C20 cycloalkyl, substituted or unsubstituted C1-C20 heteroalkyl, and substituted or unsubstituted C3-C20 heterocycloalkyl.

In some embodiments, Ra, Rb, Rc, Re, Rf, and Rg are each independently selected from the group consisting of hydrogen, deuterium, halogen, substituted or unsubstituted C1-C20 alkyl, and substituted or unsubstituted C3-C20 cycloalkyl; optionally, any two of Ra, Rb and Rc are connected to form a 3- to 10-membered aliphatic ring structure, and optionally, any two of Re, Rf, and Rg are connected to form a 3- to 10-membered aliphatic ring structure.

In some embodiments, Ra, Rb, Rc, Re, Rf, and Rg are each independently selected from the group consisting of hydrogen, deuterium, halogen, substituted or unsubstituted C1-C10 alkyl, and substituted or unsubstituted C3-C10 cycloalkyl; optionally, any two of Ra, Rb, and Rc are connected to form a 3- to 6-membered aliphatic ring structure, and optionally, any two of Re, Rf, and Rg are connected to form a 3- to 6-membered aliphatic ring structure.

In some embodiments, Ra, Rb, Rc, Re, Rf, and Rg are each independently selected from the group consisting of hydrogen, deuterium, substituted or unsubstituted C1-C10 alkyl, and substituted or unsubstituted C3-C6 cycloalkyl; optionally, any two of Ra, Rb, and Rc are connected to form a 5-membered or 6-membered aliphatic ring structure, and optionally, any two of Re, Rf, and Rg are connected to form a 5-membered or 6-membered aliphatic ring structure.

In some embodiments, Rd is selected from the group consisting of hydrogen, deuterium, halogen, and substituted or unsubstituted C1-C20 alkyl.

In some embodiments, Rd is selected from the group consisting of hydrogen, deuterium, halogen, and substituted or unsubstituted C1-C10 alkyl.

In some embodiments, Rd is selected from the group consisting of H, deuterium, and substituted or unsubstituted C1-C4 alkyl.

In some embodiments, each substitution in Ra-Rg is at least one selected from the group consisting of deuterium, F, Cl, Br, C1-C4 alkyl, and C3-C6 cycloalkyl.

In some embodiments, Lc and La are the same, forming a (La) 2Ir (Lb) structure.

In some embodiments, Lc and Lb are the same, forming a (La) Ir (Lb) 2 structure.

In some embodiments, X is O.

In some embodiments, R₁-R₉ are each independently selected from the group consisting of hydrogen, deuterium, halogen, cyano, isocyano, phosphino, substituted or unsubstituted C1-C30 alkyl, substituted or unsubstituted C3-C30 cycloalkyl, substituted or unsubstituted C1-C30 heteroalkyl, substituted or unsubstituted C3-C30 heterocycloalkyl, substituted or unsubstituted C3-C20 alkylsilyl, substituted or unsubstituted C1-C10 alkoxy, substituted or unsubstituted C7-C20 aralkyl, substituted or unsubstituted C6-C20 aryloxy, substituted or unsubstituted C2-C10 alkenyl, substituted or unsubstituted C2-C10 alkynyl, substituted or unsubstituted C6-C20 aryl, substituted or unsubstituted C3-C20 heteroaryl, substituted or unsubstituted C6-C20 arylsilyl, and substituted or unsubstituted C0-C10 alkylamino.

In some embodiments, R₁-R₉ are each independently selected from the group consisting of hydrogen, deuterium, halogen, cyano, isocyano, phosphino, substituted or unsubstituted C1-C20 alkyl, substituted or unsubstituted C3-C20 cycloalkyl, substituted or unsubstituted C1-C20 heteroalkyl, substituted or unsubstituted C3-C20 heterocycloalkyl, substituted or unsubstituted C3-C10 alkylsilyl, substituted or unsubstituted C1-C6 alkoxy, substituted or unsubstituted C7-C18 aralkyl, substituted or unsubstituted C6-C18 aryloxy, substituted or unsubstituted C2-C6 alkenyl, substituted or unsubstituted C2-C6 alkynyl, substituted or unsubstituted C6-C18 aryl, substituted or unsubstituted C3-C18 heteroaryl, substituted or unsubstituted C6-C18 arylsilyl, and substituted or unsubstituted C0-C6 alkylamino.

In some embodiments, R₁-R₈ are each independently selected from the group consisting of hydrogen, deuterium, halogen, cyano, isocyano, substituted or unsubstituted C1-C20 alkyl, substituted or unsubstituted C3-C20 cycloalkyl, substituted or unsubstituted C1-C20 heteroalkyl, substituted or unsubstituted C3-C20 heterocycloalkyl, substituted or unsubstituted C6-C18 aryl, and substituted or unsubstituted C3-C18 heteroaryl.

In some embodiments, R₁-R₈ are each independently selected from the group consisting of hydrogen, deuterium, halogen, cyano, isocyano, substituted or unsubstituted C1-C10 alkyl, substituted or unsubstituted C3-C10 cycloalkyl, substituted or unsubstituted C1-C10 heteroalkyl, substituted or unsubstituted C3-C10 heterocycloalkyl, substituted or unsubstituted C6-C12 aryl, and substituted or unsubstituted C3-C12 heteroaryl.

In some embodiments, R₁-R₈ are each independently selected from the group consisting of hydrogen, deuterium, halogen, cyano, substituted or unsubstituted C1-C10 alkyl, and substituted or unsubstituted C3-C6 heteroaryl.

In some embodiments, R₁-R₈ are each independently selected from the group consisting of hydrogen, deuterium, F, cyano, pyridyl, and substituted or unsubstituted C1-C6 alkyl.

In some embodiments, at least one of R₁-R₈ is an electron-withdrawing group, the others of R₁-R₈ are hydrogen or deuterium; and the electron-withdrawing group is cyano, pyridyl, F, or F-substituted C1-C4 alkyl.

In some embodiments, R₉ is selected from s the group consisting of substituted or unsubstituted C1-C20 alkyl, substituted or unsubstituted C3-C20 cycloalkyl, substituted or unsubstituted C1-C20 heteroalkyl, and substituted or unsubstituted C3-C20 heterocycloalkyl.

In some embodiments, R₉ is selected from the group consisting of substituted or unsubstituted C1-C10 alkyl, substituted or unsubstituted C3-C10 cycloalkyl, substituted or unsubstituted C1-C10 heteroalkyl, and substituted or unsubstituted C3-C10 heterocycloalkyl.

In some embodiments, R₉ is substituted or unsubstituted C1-C6 alkyl or substituted or unsubstituted C3-C6 cycloalkyl.

In some embodiments, Lb is one of the following structural formulas, or one of the following structural formulas in which hydrogen is substituted by at least one selected from the group consisting of deuterium and fluorine, wherein a number of substitutions ranges from monosubstitution to a maximum number of substitutions:

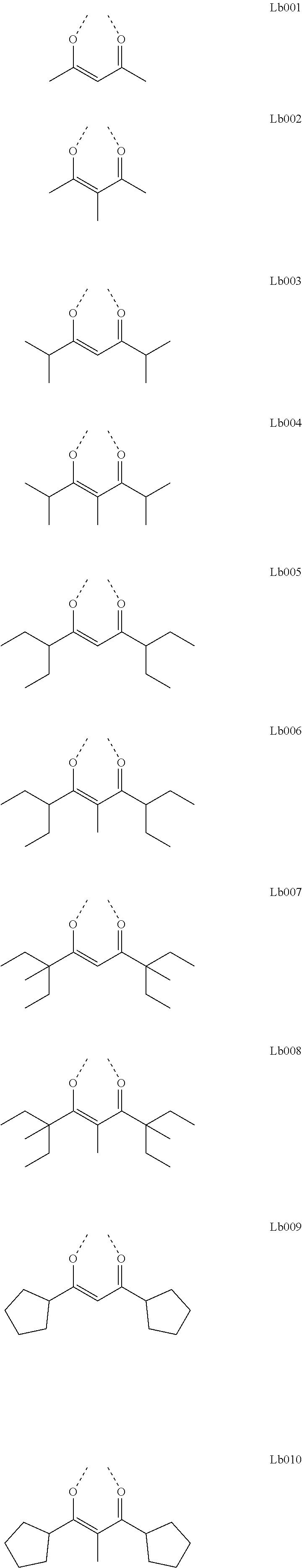

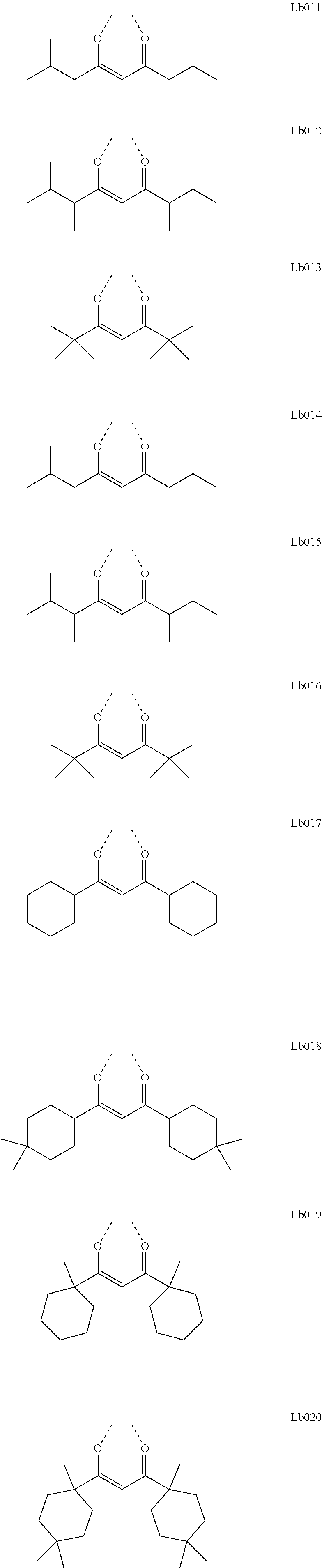

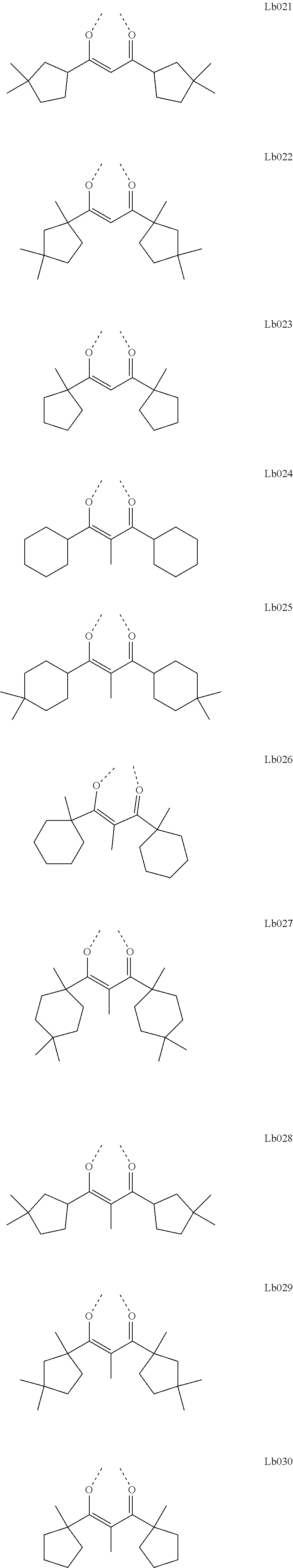

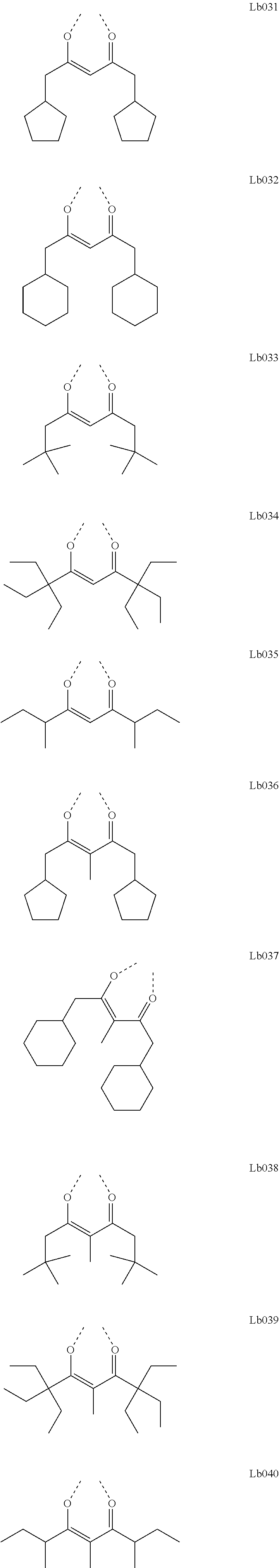

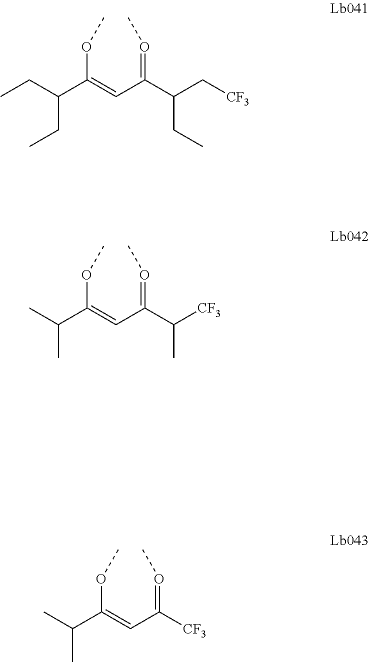

In some embodiments, La is one of the following structural formulas, or one of the following structural formulas in which hydrogen is substituted by at least one selected from the group consisting of deuterium and fluorine, wherein a number of substitutions ranges from monosubstitution to a maximum number of substitutions:

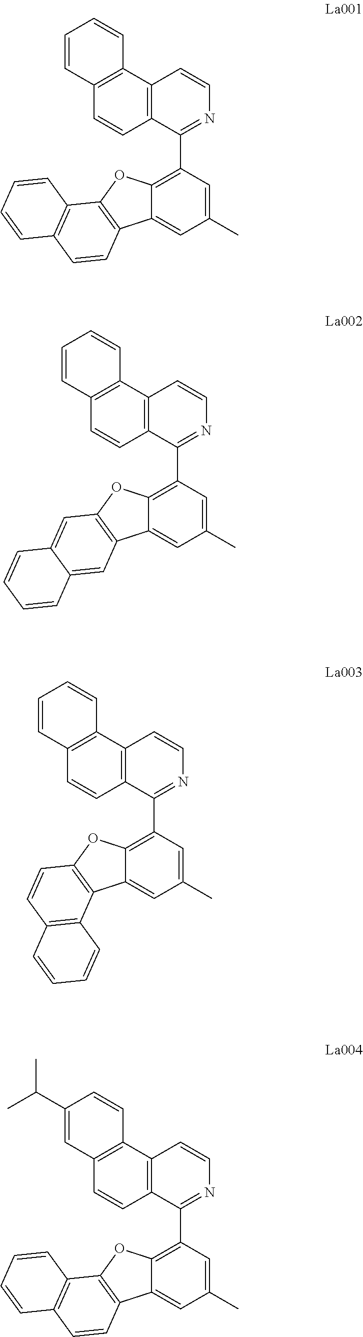 [SMILES: Cc1cc(-c2nccc3c2ccc2ccccc23)c2oc3c4ccccc4ccc3c2c1 ; Cc1cc(-c2nccc3c2ccc2ccccc23)c2oc3cc4ccccc4cc3c2c1 ; Cc1cc(-c2nccc3c2ccc2ccccc23)c2oc3ccc4ccccc4c3c2c1 ; Cc1cc(-c2nccc3c2ccc2cc(C(C)C)ccc23)c2oc3c4ccccc4ccc3c2c1]

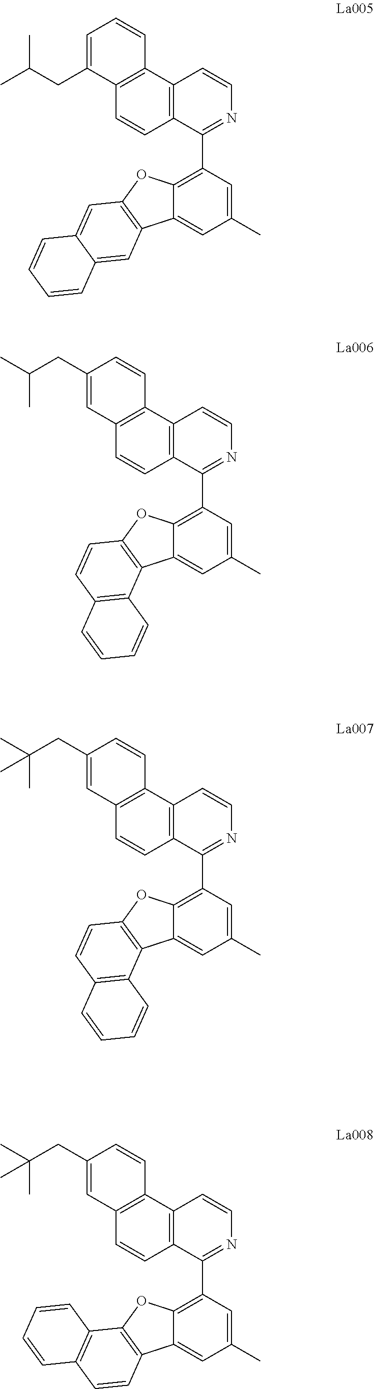

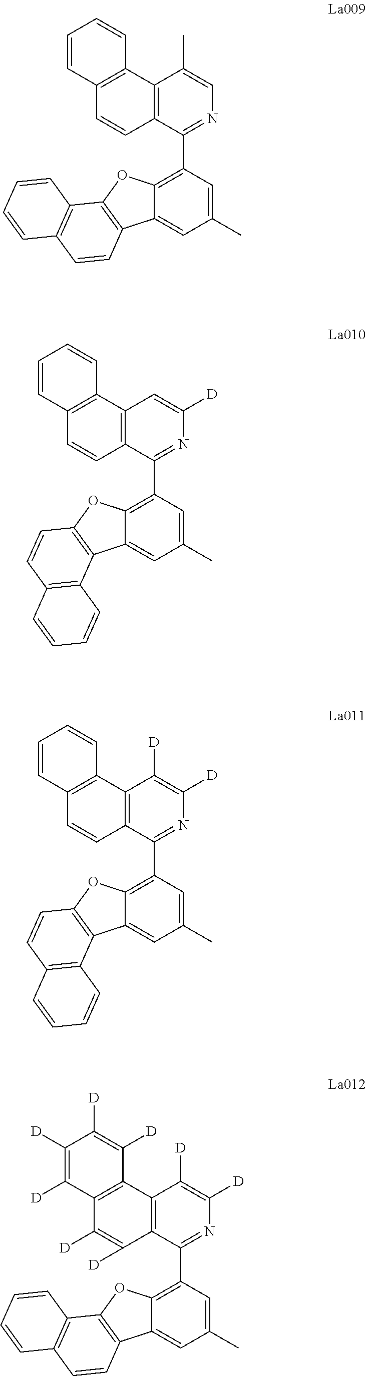 [SMILES: Cc1cc(-c2ncc(C)c3c2ccc2ccccc23)c2oc3c4ccccc4ccc3c2c1 ; [2H]c1cc2c(ccc3ccccc32)c(-c2cc(C)cc3c2oc2ccc4ccccc4c23)n1 ; [2H]c1nc(-c2cc(C)cc3c2oc2ccc4ccccc4c23)c2ccc3ccccc3c2c1[2H] ; [2H]c1nc(-c2cc(C)cc3c2oc2c4ccccc4ccc32)c2c([2H])c([2H])c3c([2H])c([2H])c([2H])c([2H])c3c2c1[2H]]

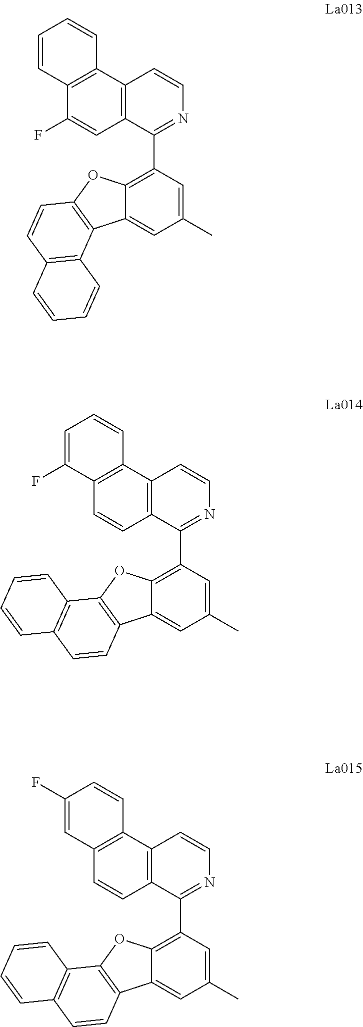 [SMILES: Cc1cc(-c2nccc3c2cc(F)c2ccccc23)c2oc3ccc4ccccc4c3c2c1 ; Cc1cc(-c2nccc3c2ccc2c(F)cccc23)c2oc3c4ccccc4ccc3c2c1 ; Cc1cc(-c2nccc3c2ccc2cc(F)ccc23)c2oc3c4ccccc4ccc3c2c1]

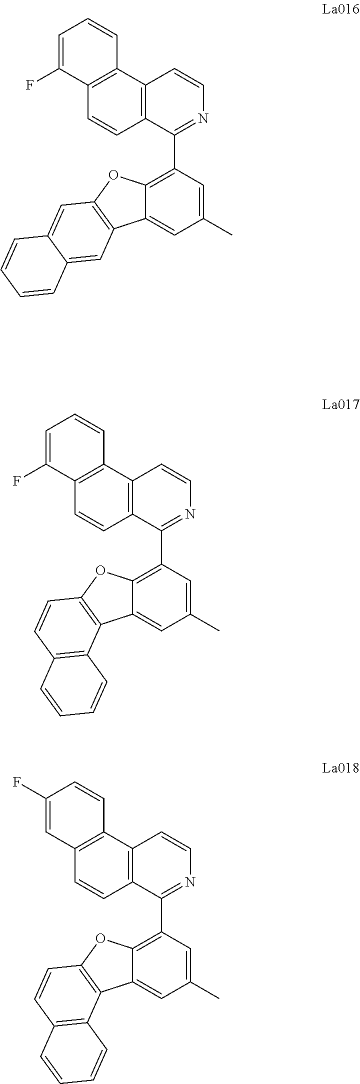 [SMILES: Cc1cc(-c2nccc3c2ccc2c(F)cccc23)c2oc3cc4ccccc4cc3c2c1 ; Cc1cc(-c2nccc3c2ccc2c(F)cccc23)c2oc3ccc4ccccc4c3c2c1 ; Cc1cc(-c2nccc3c2ccc2cc(F)ccc23)c2oc3ccc4ccccc4c3c2c1]

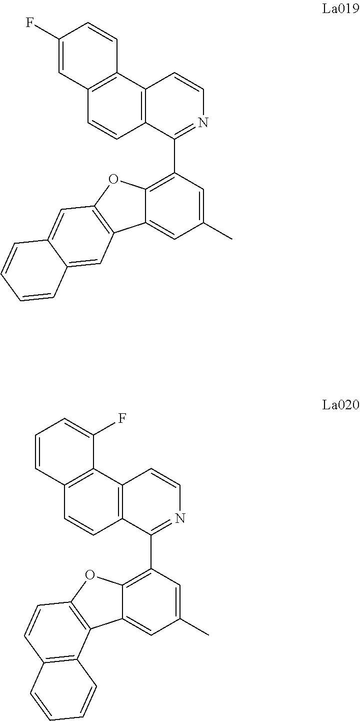 [SMILES: Cc1cc(-c2nccc3c2ccc2cc(F)ccc23)c2oc3cc4ccccc4cc3c2c1 ; Cc1cc(-c2nccc3c2ccc2cccc(F)c23)c2oc3ccc4ccccc4c3c2c1]

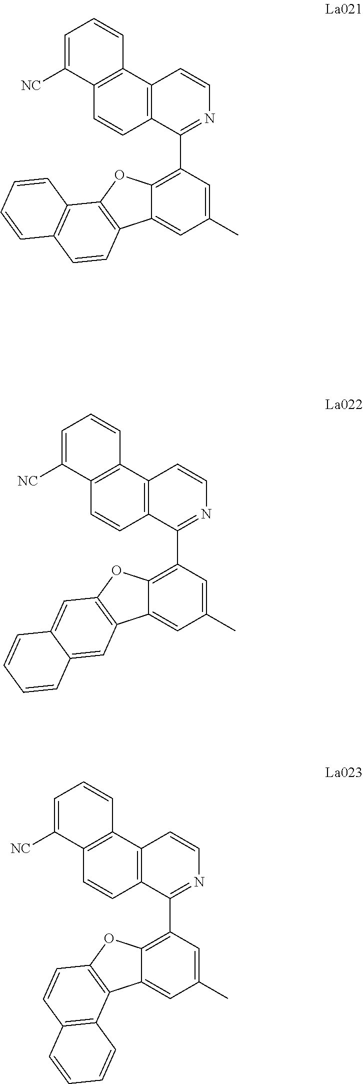 [SMILES: Cc1cc(-c2nccc3c2ccc2c(C#N)cccc23)c2oc3c4ccccc4ccc3c2c1 ; Cc1cc(-c2nccc3c2ccc2c(C#N)cccc23)c2oc3cc4ccccc4cc3c2c1 ; Cc1cc(-c2nccc3c2ccc2c(C#N)cccc23)c2oc3ccc4ccccc4c3c2c1]

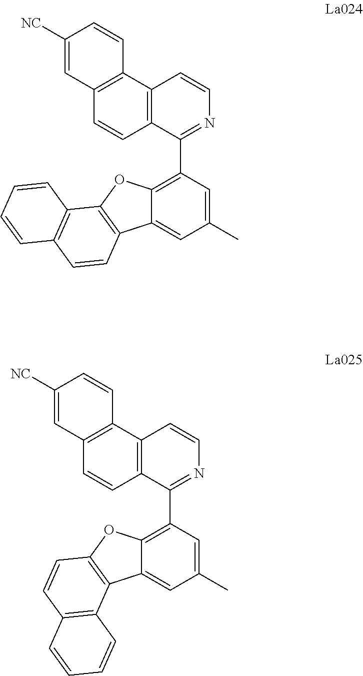 [SMILES: Cc1cc(-c2nccc3c2ccc2cc(C#N)ccc23)c2oc3c4ccccc4ccc3c2c1 ; Cc1cc(-c2nccc3c2ccc2cc(C#N)ccc23)c2oc3ccc4ccccc4c3c2c1]

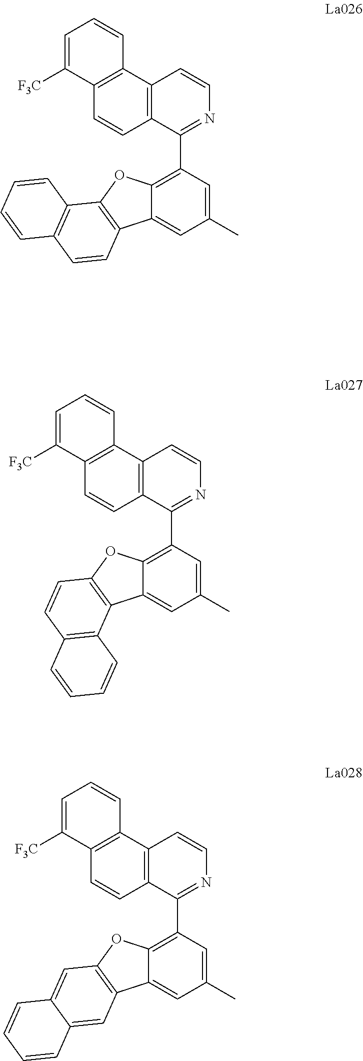 [SMILES: Cc1cc(-c2nccc3c2ccc2c(C(F)(F)F)cccc23)c2oc3c4ccccc4ccc3c2c1 ; Cc1cc(-c2nccc3c2ccc2c(C(F)(F)F)cccc23)c2oc3ccc4ccccc4c3c2c1 ; Cc1cc(-c2nccc3c2ccc2c(C(F)(F)F)cccc23)c2oc3cc4ccccc4cc3c2c1]

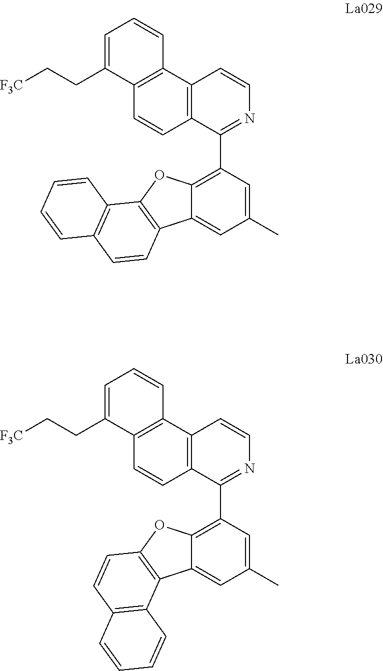 [SMILES: Cc1cc(-c2nccc3c2ccc2c(CCC(F)(F)F)cccc23)c2oc3c4ccccc4ccc3c2c1 ; Cc1cc(-c2nccc3c2ccc2c(CCC(F)(F)F)cccc23)c2oc3ccc4ccccc4c3c2c1]

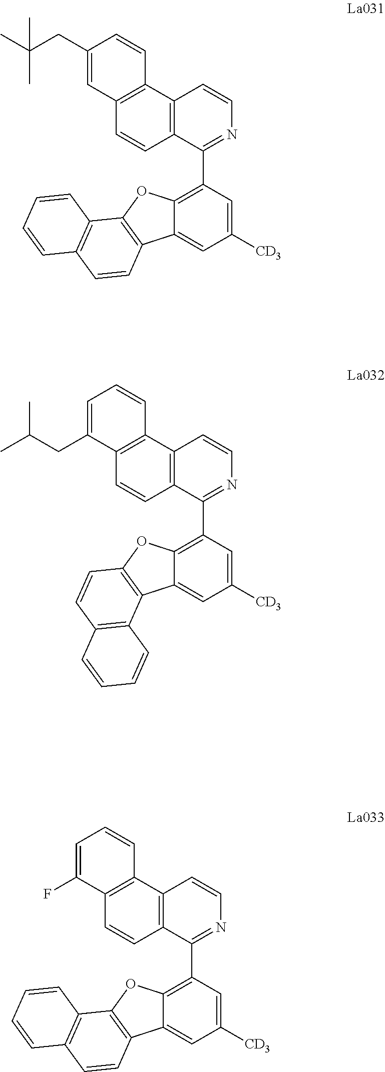 [SMILES: [2H]C([2H])([2H])c1cc(-c2nccc3c2ccc2cc(CC(C)(C)C)ccc23)c2oc3c4ccccc4ccc3c2c1 ; [2H]C([2H])([2H])c1cc(-c2nccc3c2ccc2c(CC(C)C)cccc23)c2oc3ccc4ccccc4c3c2c1 ; [2H]C([2H])([2H])c1cc(-c2nccc3c2ccc2c(F)cccc23)c2oc3c4ccccc4ccc3c2c1]

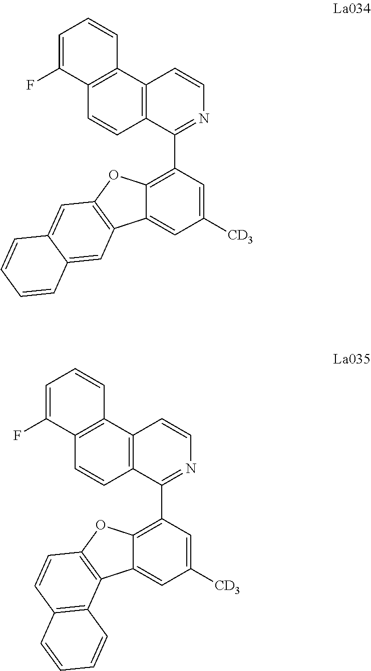 [SMILES: [2H]C([2H])([2H])c1cc(-c2nccc3c2ccc2c(F)cccc23)c2oc3cc4ccccc4cc3c2c1 ; [2H]C([2H])([2H])c1cc(-c2nccc3c2ccc2c(F)cccc23)c2oc3ccc4ccccc4c3c2c1]

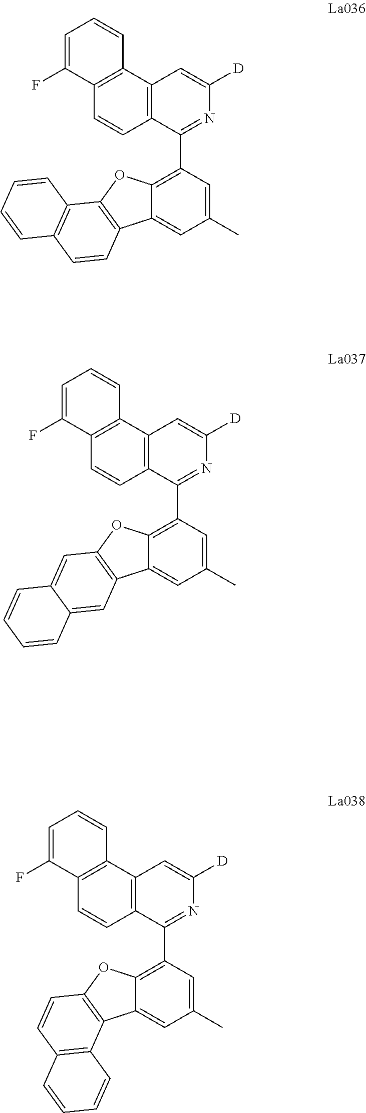 [SMILES: [2H]c1cc2c(ccc3c(F)cccc32)c(-c2cc(C)cc3c2oc2c4ccccc4ccc32)n1 ; [2H]c1cc2c(ccc3c(F)cccc32)c(-c2cc(C)cc3c2oc2cc4ccccc4cc23)n1 ; [2H]c1cc2c(ccc3c(F)cccc32)c(-c2cc(C)cc3c2oc2ccc4ccccc4c23)n1]

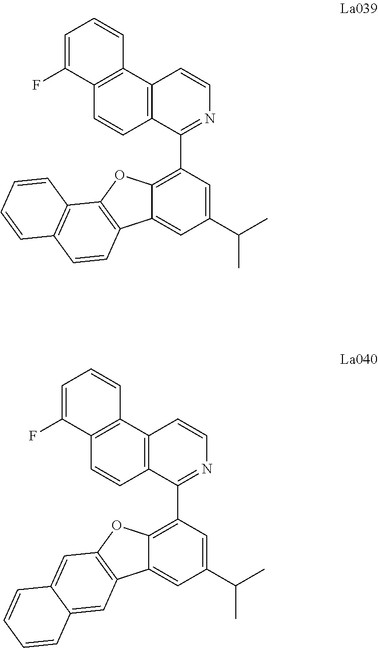 [SMILES: CC(C)c1cc(-c2nccc3c2ccc2c(F)cccc23)c2oc3c4ccccc4ccc3c2c1 ; CC(C)c1cc(-c2nccc3c2ccc2c(F)cccc23)c2oc3cc4ccccc4cc3c2c1]

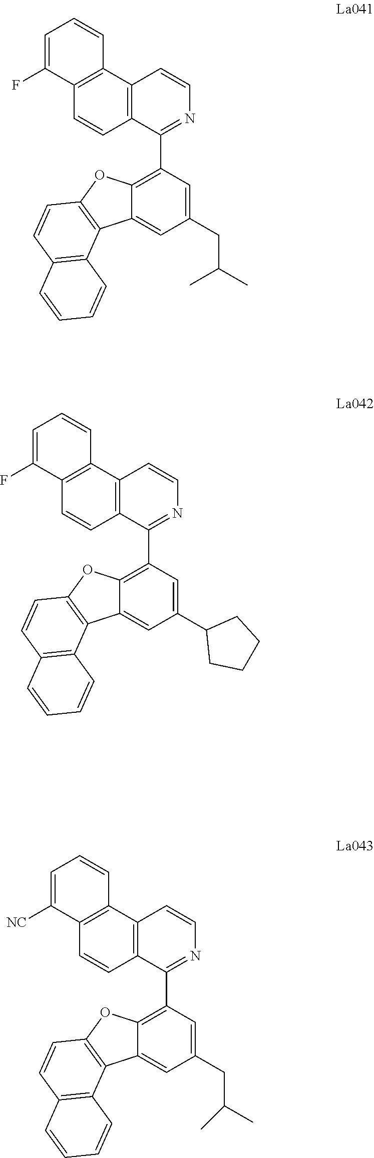 [SMILES: CC(C)Cc1cc(-c2nccc3c2ccc2c(F)cccc23)c2oc3ccc4ccccc4c3c2c1 ; Fc1cccc2c1ccc1c(-c3cc(C4CCCC4)cc4c3oc3ccc5ccccc5c34)nccc12 ; CC(C)Cc1cc(-c2nccc3c2ccc2c(C#N)cccc23)c2oc3ccc4ccccc4c3c2c1]

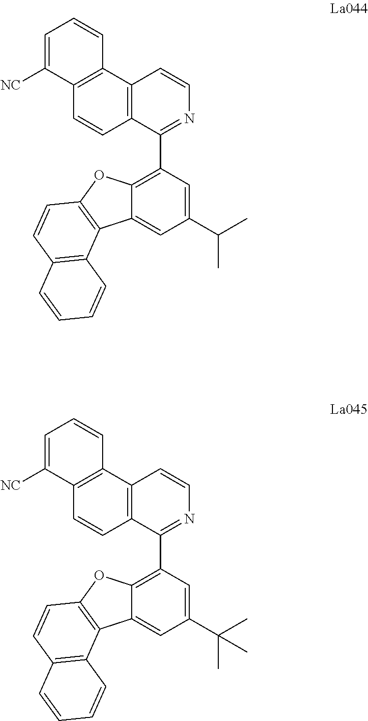 [SMILES: CC(C)c1cc(-c2nccc3c2ccc2c(C#N)cccc23)c2oc3ccc4ccccc4c3c2c1 ; CC(C)(C)c1cc(-c2nccc3c2ccc2c(C#N)cccc23)c2oc3ccc4ccccc4c3c2c1]

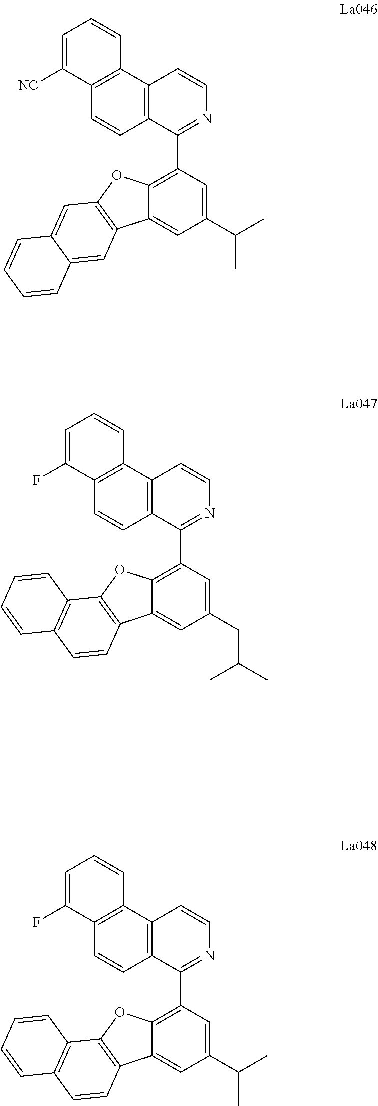 [SMILES: CC(C)c1cc(-c2nccc3c2ccc2c(C#N)cccc23)c2oc3cc4ccccc4cc3c2c1 ; CC(C)Cc1cc(-c2nccc3c2ccc2c(F)cccc23)c2oc3c4ccccc4ccc3c2c1 ; CC(C)c1cc(-c2nccc3c2ccc2c(F)cccc23)c2oc3c4ccccc4ccc3c2c1]

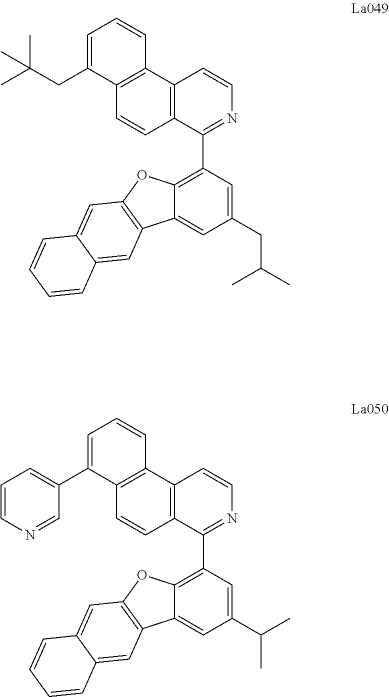 [SMILES: CC(C)Cc1cc(-c2nccc3c2ccc2c(CC(C)(C)C)cccc23)c2oc3cc4ccccc4cc3c2c1 ; CC(C)c1cc(-c2nccc3c2ccc2c(-c4cccnc4)cccc23)c2oc3cc4ccccc4cc3c2c1]

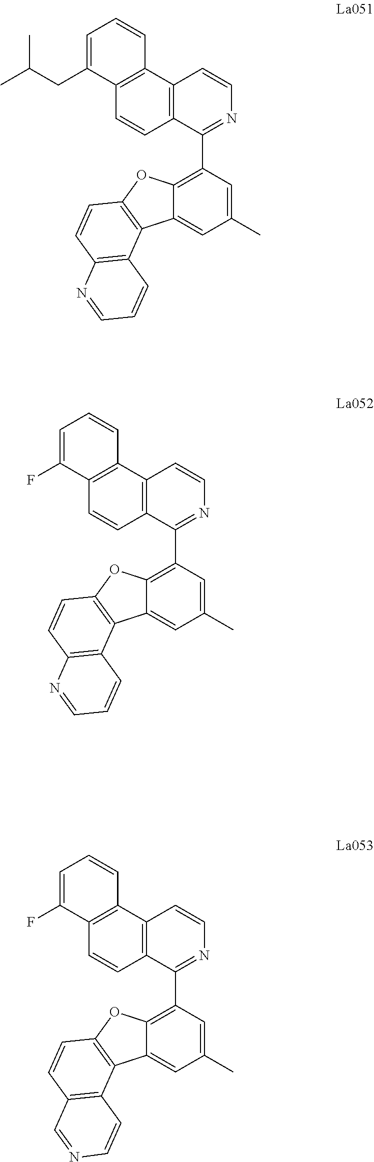 [SMILES: Cc1cc(-c2nccc3c2ccc2c(CC(C)C)cccc23)c2oc3ccc4ncccc4c3c2c1 ; Cc1cc(-c2nccc3c2ccc2c(F)cccc23)c2oc3ccc4ncccc4c3c2c1 ; Cc1cc(-c2nccc3c2ccc2c(F)cccc23)c2oc3ccc4cnccc4c3c2c1]

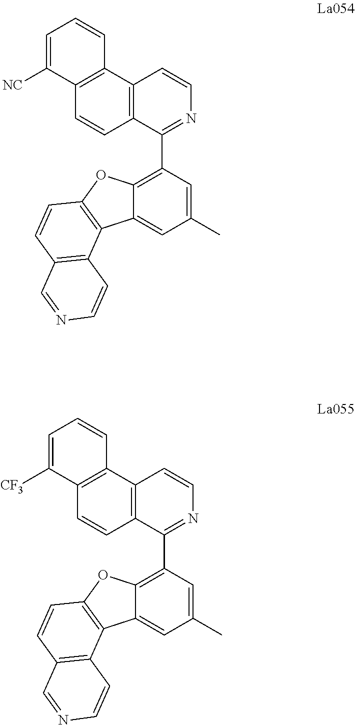 [SMILES: Cc1cc(-c2nccc3c2ccc2c(C#N)cccc23)c2oc3ccc4cnccc4c3c2c1 ; Cc1cc(-c2nccc3c2ccc2c(C(F)(F)F)cccc23)c2oc3ccc4cnccc4c3c2c1]

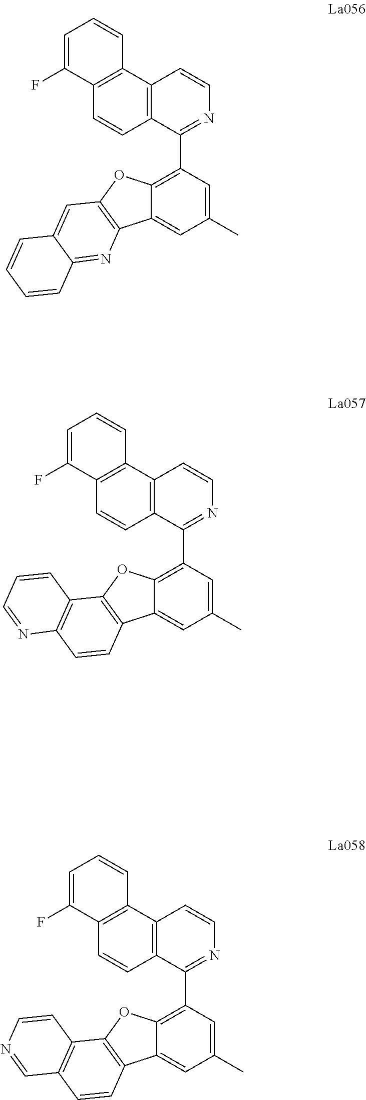 [SMILES: Cc1cc(-c2nccc3c2ccc2c(F)cccc23)c2oc3cc4ccccc4nc3c2c1 ; Cc1cc(-c2nccc3c2ccc2c(F)cccc23)c2oc3c4cccnc4ccc3c2c1 ; Cc1cc(-c2nccc3c2ccc2c(F)cccc23)c2oc3c4ccncc4ccc3c2c1]

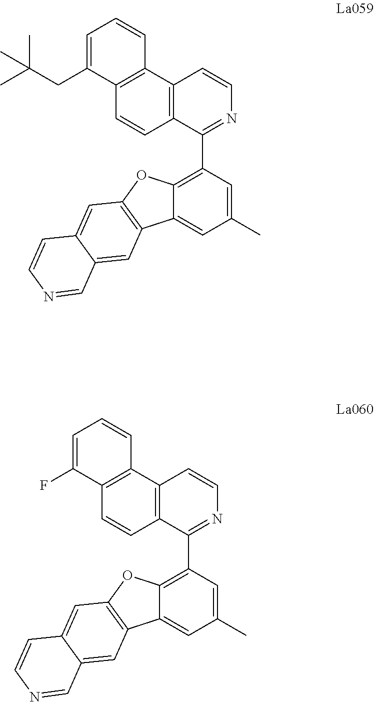 [SMILES: Cc1cc(-c2nccc3c2ccc2c(CC(C)(C)C)cccc23)c2oc3cc4ccncc4cc3c2c1 ; Cc1cc(-c2nccc3c2ccc2c(F)cccc23)c2oc3cc4ccncc4cc3c2c1]

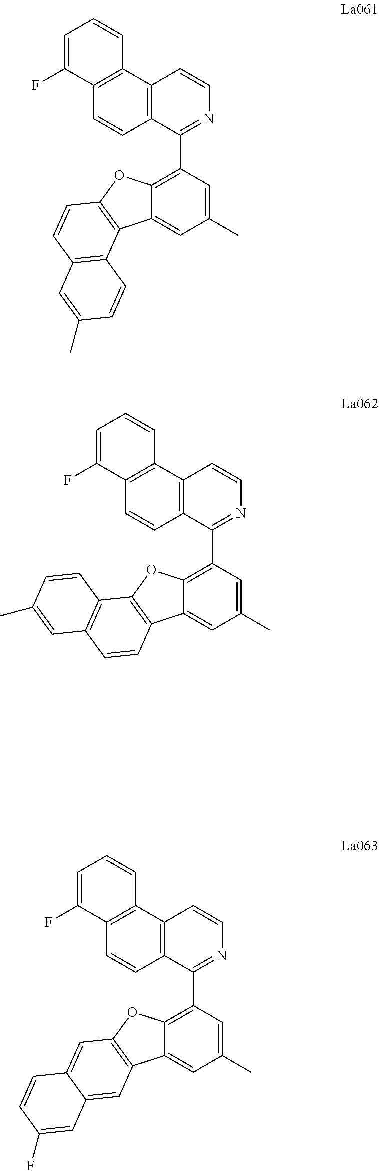

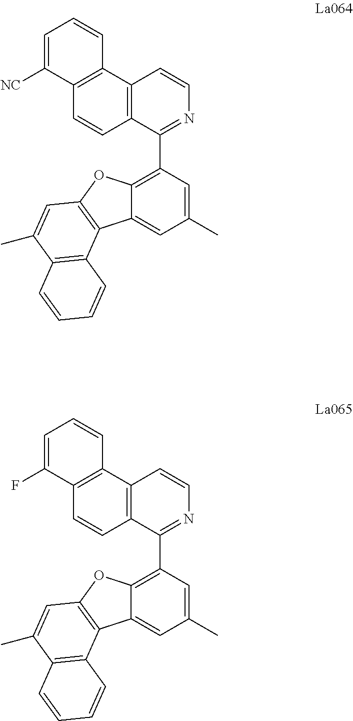

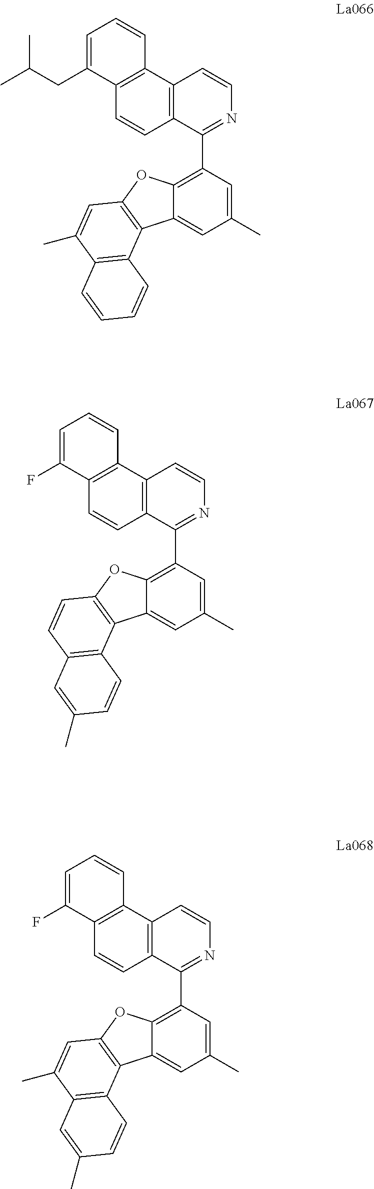

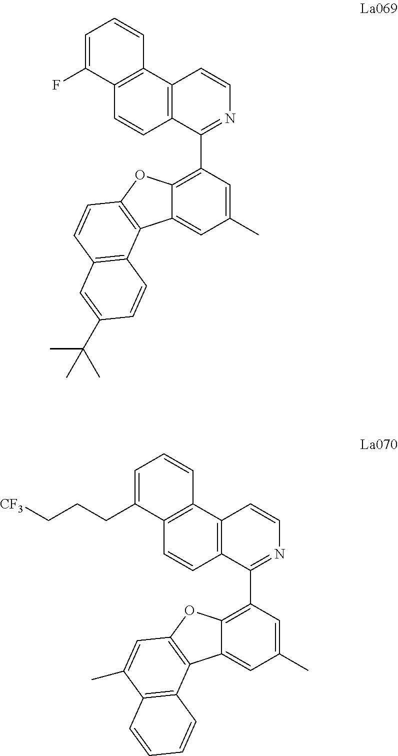 [SMILES: Cc1cc(-c2nccc3c2ccc2c(F)cccc23)c2oc3ccc4cc(C(C)(C)C)ccc4c3c2c1 ; Cc1cc(-c2nccc3c2ccc2c(CCCC(F)(F)F)cccc23)c2oc3cc(C)c4ccccc4c3c2c1]

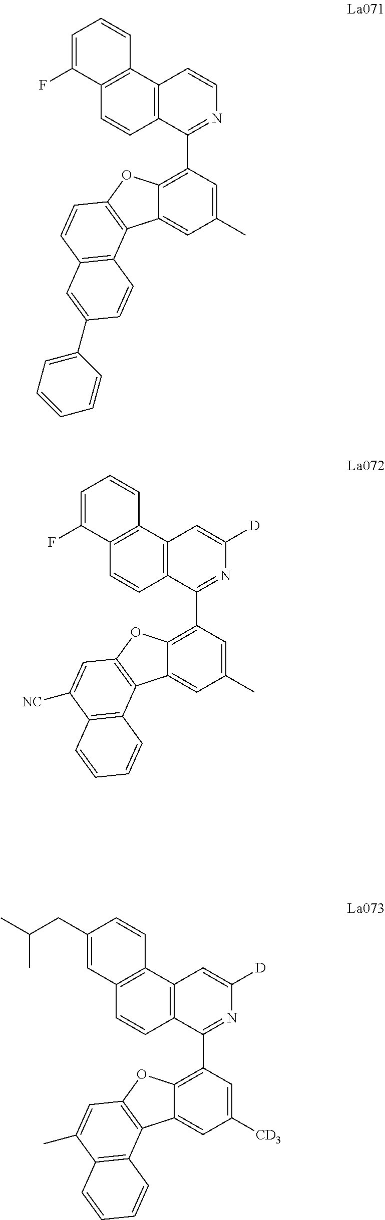

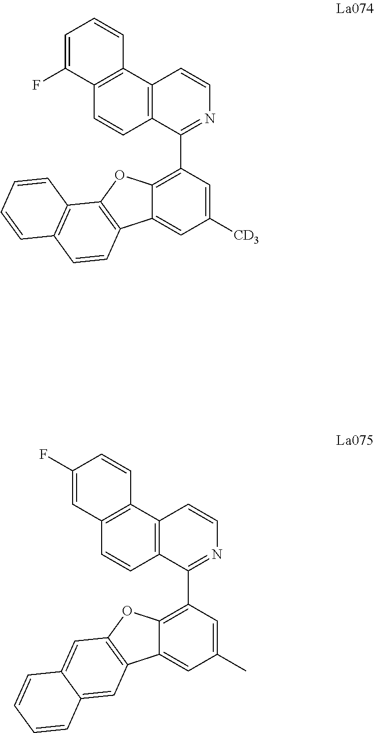 [SMILES: [2H]C([2H])([2H])c1cc(-c2nccc3c2ccc2c(F)cccc23)c2oc3c4ccccc4ccc3c2c1 ; Cc1cc(-c2nccc3c2ccc2cc(F)ccc23)c2oc3cc4ccccc4cc3c2c1]

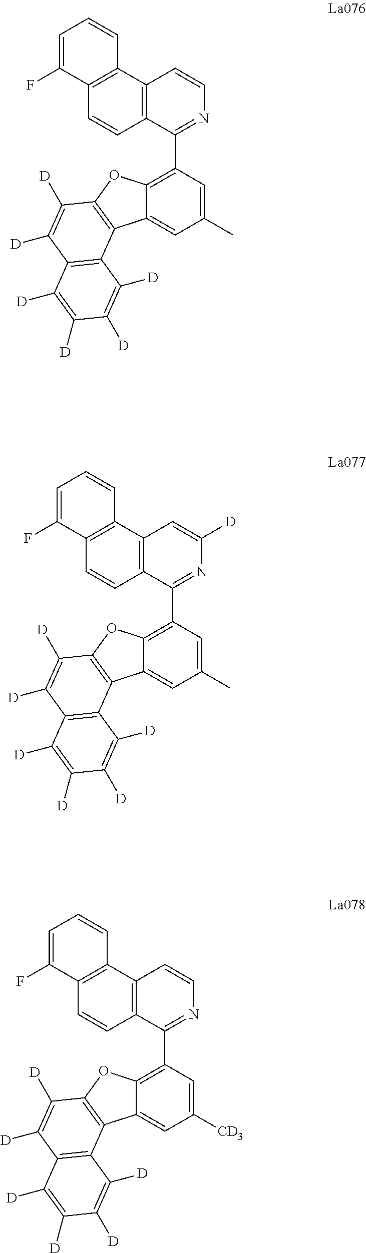 [SMILES: [2H]c1c([2H])c([2H])c2c(c1[2H])c([2H])c([2H])c1oc3c(-c4nccc5c4ccc4c(F)cccc45)cc(C)cc3c12 ; [2H]c1cc2c(ccc3c(F)cccc32)c(-c2cc(C)cc3c2oc2c([2H])c([2H])c4c([2H])c([2H])c([2H])c([2H])c4c23)n1 ; [2H]c1c([2H])c([2H])c2c(c1[2H])c([2H])c([2H])c1oc3c(-c4nccc5c4ccc4c(F)cccc45)cc(C([2H])([2H])[2H])cc3c12]

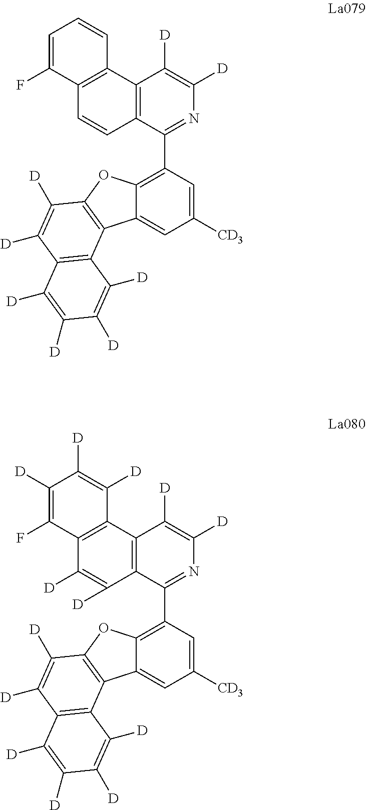 [SMILES: [2H]c1nc(-c2cc(C([2H])([2H])[2H])cc3c2oc2c([2H])c([2H])c4c([2H])c([2H])c([2H])c([2H])c4c23)c2ccc3c(F)cccc3c2c1[2H] ; [2H]c1nc(-c2cc(C([2H])([2H])[2H])cc3c2oc2c([2H])c([2H])c4c([2H])c([2H])c([2H])c([2H])c4c23)c2c([2H])c([2H])c3c(F)c([2H])c([2H])c([2H])c3c2c1[2H]]

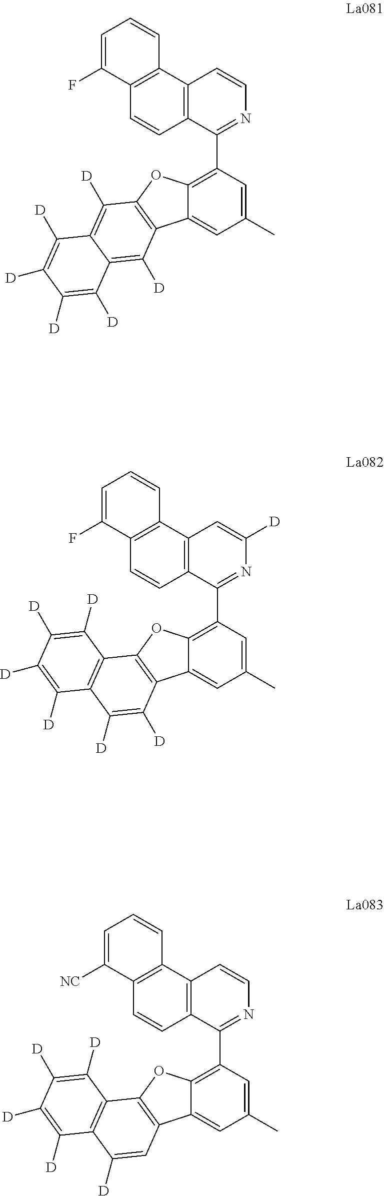 [SMILES: [2H]c1c([2H])c([2H])c2c([2H])c3c(oc4c(-c5nccc6c5ccc5c(F)cccc56)cc(C)cc43)c([2H])c2c1[2H] ; [2H]c1cc2c(ccc3c(F)cccc32)c(-c2cc(C)cc3c2oc2c4c([2H])c([2H])c([2H])c([2H])c4c([2H])c([2H])c32)n1 ; [2H]c1c([2H])c([2H])c2c(c([2H])cc3c4cc(C)cc(-c5nccc6c5ccc5c(C#N)cccc56)c4oc32)c1[2H]]

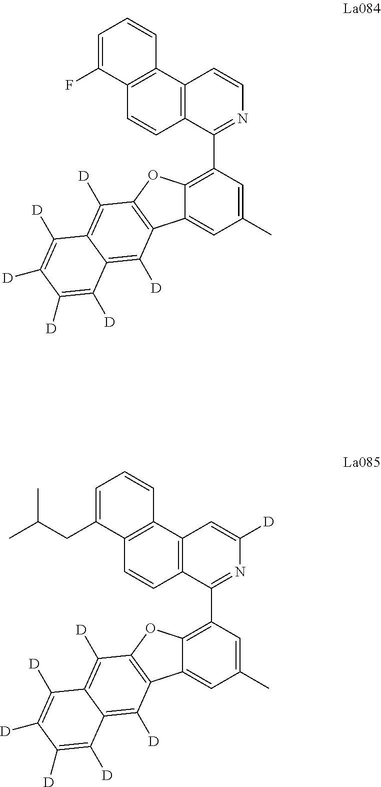 [SMILES: [2H]c1c([2H])c([2H])c2c([2H])c3c(oc4c(-c5nccc6c5ccc5c(F)cccc56)cc(C)cc43)c([2H])c2c1[2H] ; [2H]c1cc2c(ccc3c(CC(C)C)cccc32)c(-c2cc(C)cc3c2oc2c([2H])c4c([2H])c([2H])c([2H])c([2H])c4c([2H])c23)n1]

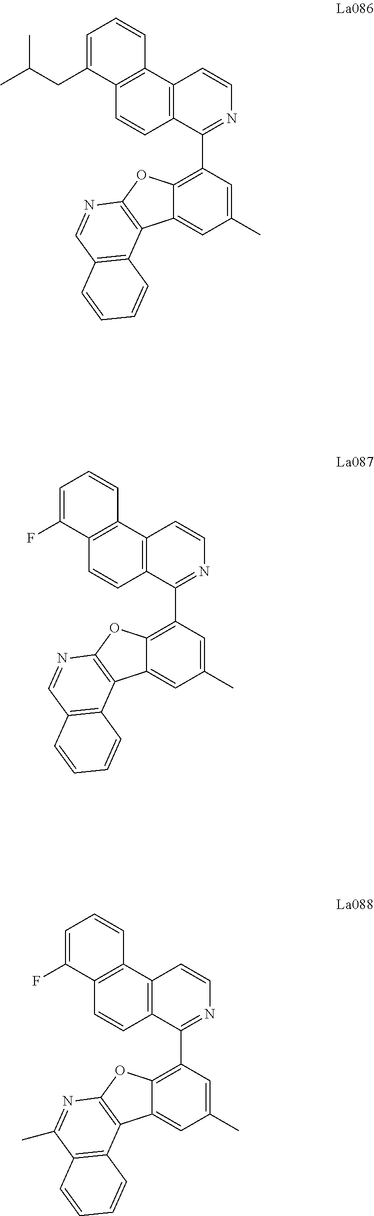

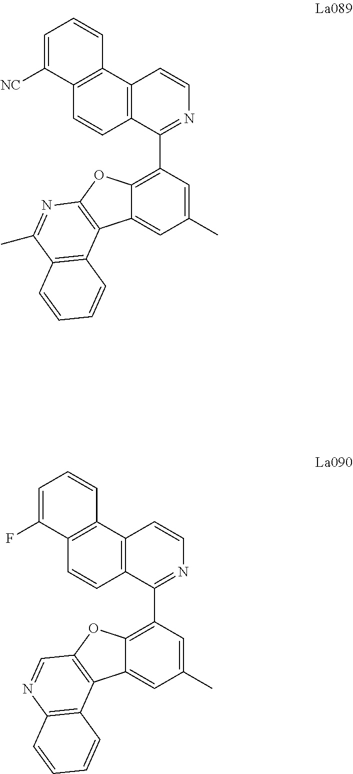

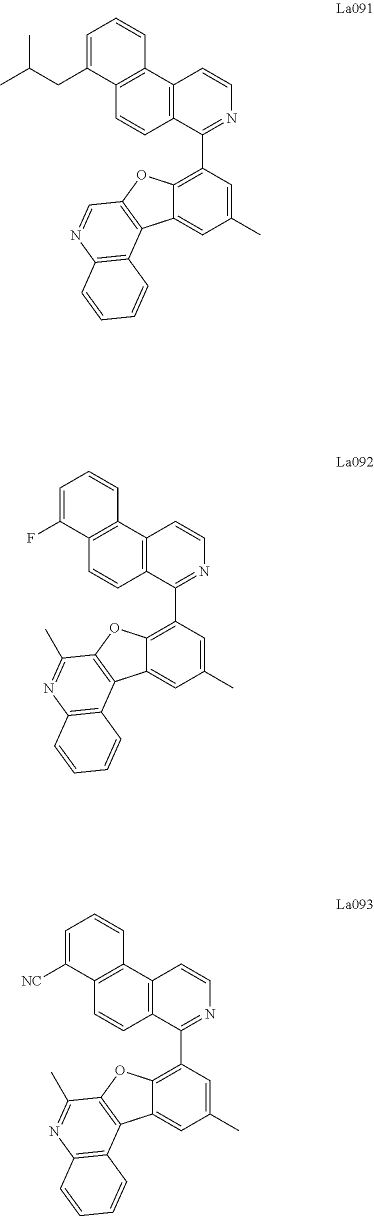 [SMILES: Cc1cc(-c2nccc3c2ccc2c(CC(C)C)cccc23)c2oc3cnc4ccccc4c3c2c1 ; Cc1cc(-c2nccc3c2ccc2c(F)cccc23)c2oc3c(C)nc4ccccc4c3c2c1 ; Cc1cc(-c2nccc3c2ccc2c(C#N)cccc23)c2oc3c(C)nc4ccccc4c3c2c1]

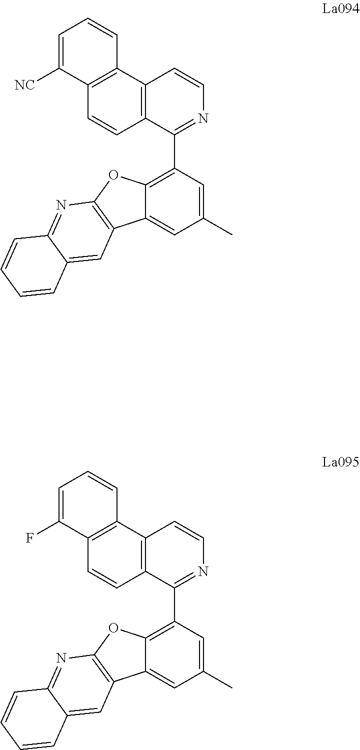 [SMILES: Cc1cc(-c2nccc3c2ccc2c(C#N)cccc23)c2oc3nc4ccccc4cc3c2c1 ; Cc1cc(-c2nccc3c2ccc2c(F)cccc23)c2oc3nc4ccccc4cc3c2c1]

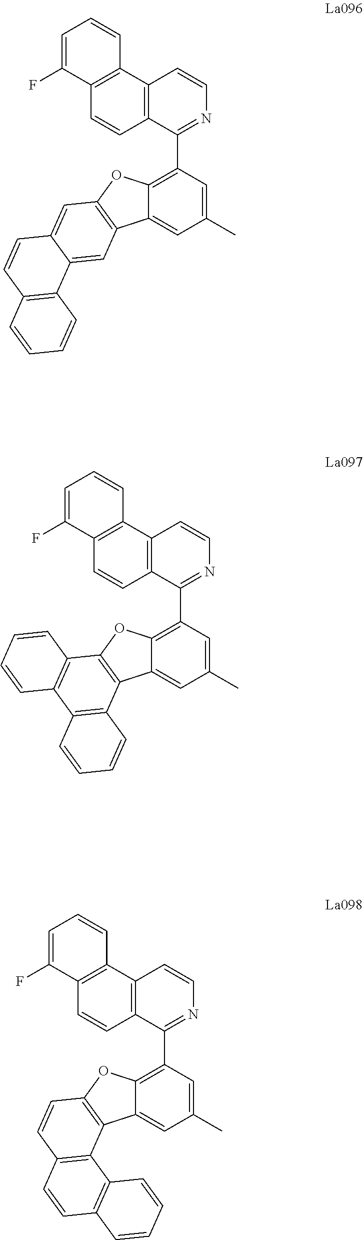 [SMILES: Cc1cc(-c2nccc3c2ccc2c(F)cccc23)c2oc3cc4ccc5ccccc5c4cc3c2c1 ; Cc1cc(-c2nccc3c2ccc2c(F)cccc23)c2oc3c4ccccc4c4ccccc4c3c2c1 ; Cc1cc(-c2nccc3c2ccc2c(F)cccc23)c2oc3ccc4ccc5ccccc5c4c3c2c1]

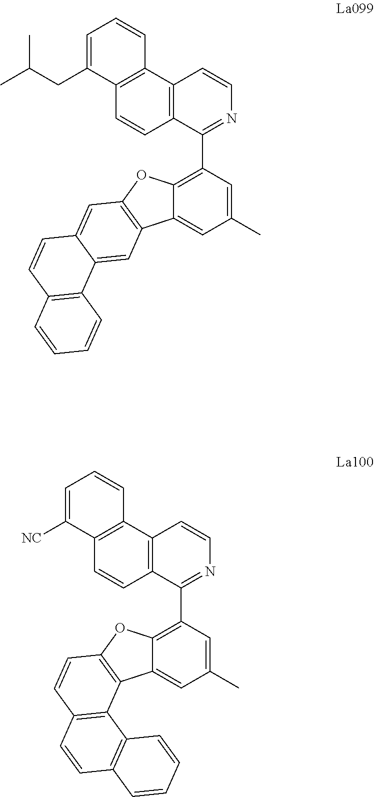 [SMILES: Cc1cc(-c2nccc3c2ccc2c(CC(C)C)cccc23)c2oc3cc4ccc5ccccc5c4cc3c2c1 ; Cc1cc(-c2nccc3c2ccc2c(C#N)cccc23)c2oc3ccc4ccc5ccccc5c4c3c2c1]

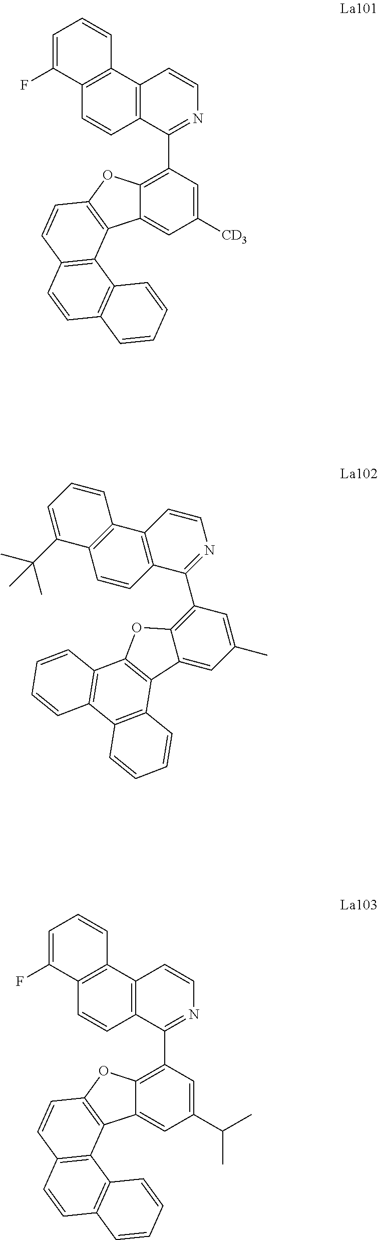 [SMILES: [2H]C([2H])([2H])c1cc(-c2nccc3c2ccc2c(F)cccc23)c2oc3ccc4ccc5ccccc5c4c3c2c1 ; Cc1cc(-c2nccc3c2ccc2c(C(C)(C)C)cccc23)c2oc3c4ccccc4c4ccccc4c3c2c1 ; CC(C)c1cc(-c2nccc3c2ccc2c(F)cccc23)c2oc3ccc4ccc5ccccc5c4c3c2c1]

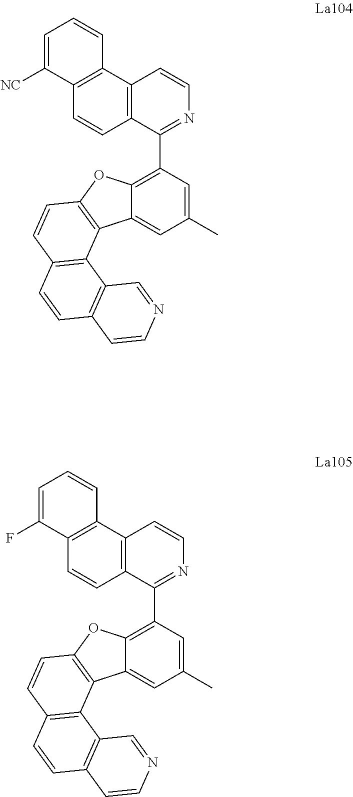 [SMILES: Cc1cc(-c2nccc3c2ccc2c(C#N)cccc23)c2oc3ccc4ccc5ccncc5c4c3c2c1 ; Cc1cc(-c2nccc3c2ccc2c(F)cccc23)c2oc3ccc4ccc5ccncc5c4c3c2c1]

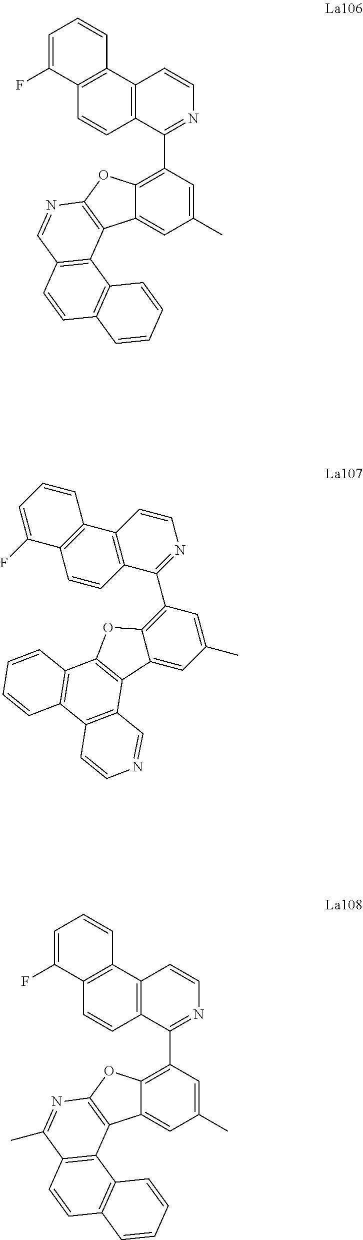

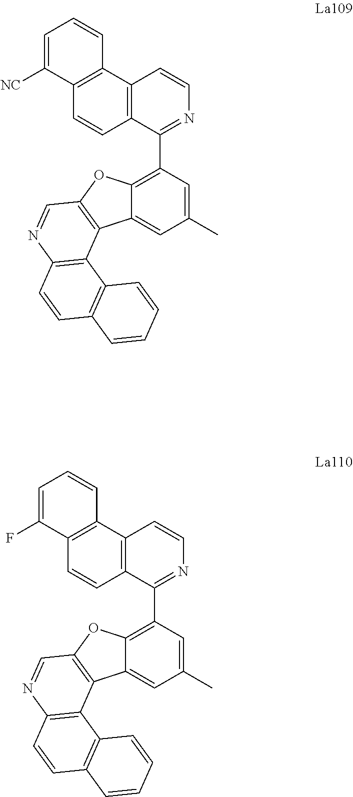 [SMILES: Cc1cc(-c2nccc3c2ccc2c(C#N)cccc23)c2oc3cnc4ccc5ccccc5c4c3c2c1 ; Cc1cc(-c2nccc3c2ccc2c(F)cccc23)c2oc3cnc4ccc5ccccc5c4c3c2c1]

According to a second aspect of the present disclosure, an organic electroluminescent device is provided. The organic electroluminescent device includes a cathode, an anode, and an organic layer arranged between the cathode and the anode; wherein at least one layer of the organic layer includes the metal iridium complex.

In some embodiments, the organic layer is a light-emitting layer.

In some embodiments, the metal iridium complex serves as a red light-emitting doping material in the light-emitting layer.

In some embodiments, the light-emitting layer further includes a host compound, and an amount of the metal complex is 1% by weight to 30% by weight of a total weight of the light-emitting layer; in some embodiments, the metal complex is 3% by weight to 13% by weight of the total weight of the light-emitting layer. The host compound includes a first host compound, or includes a first host compound and a second host compound.

In some embodiments, a weight ratio of the first host compound to the second host compound is 8: 2 to 2:8, for example 5:2 to 2:5, for example 3:2 to 2:3.

In some embodiments, the first host compound and/or the second host compound includes at least one chemical group comprising: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and a combination thereof.

According to a third aspect of the present disclosure, use of the aforementioned metal iridium compound in the semiconductor field is provided.

Specifically, use of the aforementioned metal iridium complex in the preparation of semiconductor devices is provided.

In some embodiments, the semiconductor device includes an optoelectronic device. Specifically, the semiconductor device includes the aforementioned organic electroluminescent device; the semiconductor device includes, but is not limited to, at least one of organic light-emitting cells, organic light-emitting field-effect transistors (e.g., organic light-emitting transistors (OLETs), such as organic light-emitting thin-film transistors (OLETFTs)), organic OLED displays (which may be organic light-emitting diode panels (AMOLEDs)), and organic light-emitting sensors (OLES).

### Definitions

Unless otherwise stated, the scientific and technical terms used herein have the meanings commonly understood by those skilled in the art. However, for a better understanding of the present disclosure, definitions of some terms are provided below. When the definitions of terms provided in the present disclosure differ from the meanings commonly understood by those skilled in the art, the definitions and interpretations provided in the present disclosure shall prevail.

As used herein, “Cn1-Cn2” in expressions such as “substituted or unsubstituted Cn1-Cn2 X group” means that a number of carbon atoms is n1 to n2 when the X group is not substituted, excluding the number of carbon atoms in the substituents when the group is substituted.

The term “and/or” means that the listed items are present or used individually or in combination. In practice, this term means that “at least one” or “one or more” of the listed items are used or present.

The term “multiple” means a quantity greater than or equal to 2, for example, 2, 3, 4, 5, 6, 7, 8, 9, 10, etc.

The term “halogen” refers to a fluorine (F), chlorine (C1), bromine (Br), or iodine (I) group.

The term “alkyl” refers to a linear or branched saturated hydrocarbon group. The number of carbon atoms can be 1 to 40, 1 to 30, 1 to 20, 1 to 12, 1 to 10, 1 to 6, or 1 to 4. Non-limiting examples of alkyl include methyl, ethyl, propyl, butyl, heptyl, and decyl, etc.

The term “cycloalkyl” refers to an alkyl group with a cyclic structure, which can include monocyclic, polycyclic, and spiroalkyl groups. Non-limiting examples of cycloalkyl include cyclopropyl, cyclobutyl, cyclopentyl, cyclohexyl, 1-adamantyl, 2-adamantyl, 1-norbornyl, and 2-norbornyl, etc. The number of carbon atoms in a cycloalkyl group can be 3 to 30, 3 to 20, 3 to 12, 3 to 10, or 3 to 6.

The term “azanaphthalene ring” or “azaphenanthrene ring” refers to a naphthalene ring or phenanthrene ring in which at least one carbon atom is replaced by a nitrogen atom, respectively. Non-limiting examples of azanaphthalene rings include quinoline ring, isoquinoline ring, quinazoline ring, 1,3,5-triazanaphthalene ring, and the like; non-limiting examples of azaphenanthrene rings include benzo[h]isoquinoline ring, benzo[f]isoquinoline ring, 6-benzo[f]quinoline ring, benzo[c]quinazoline ring, benzo[g]triazolophenanthrene ring, and the like.

The term “alkenyl” refers to a hydrocarbon containing at least one unsaturated carbon-carbon sp² double bond. Non-limiting examples of alkenyl include vinyl, propenyl, allyl, 1-butadienyl, 2-butadienyl, 1-hexatrienyl, 2-hexatrienyl, 3-hexatrienyl, and the like. The number of carbon atoms in alkenyl may be 2 to 40, 2 to 30, 2 to 20, 2 to 12, 2 to 10, 2 to 6, or 2 to 4.

The term “alkynyl” refers to a hydrocarbon containing at least one unsaturated carbon-carbon sp triple bond. Non-limiting examples of alkynyl include ethynyl (—C≡CH), propargyl (—CH₂C≡CH), and the like. The number of carbon atoms in alkynyl may be 2 to 40, 2 to 30, 2 to 20, 2 to 12, 2 to 10, 2 to 6, or 2 to 4.

The term “heteroalkyl” refers to an alkyl group in which at least one carbon atom is replaced by a non-carbon atom, excluding cases where the carbon atom serving as a linking site is replaced by a non-carbon atom (e.g., alkoxy, alkylsilane group). Non-limiting examples of heteroalkyl include mercaptomethylmethyl, methoxymethyl, ethoxymethyl, tert-butoxymethyl, N,N-dimethylmethyl, epoxybutyl, epoxypentyl, epoxyhexyl, and the like, preferably methoxymethyl and epoxypentyl. The number of carbon atoms in heteroalkyl may be 1 to 40, 1 to 30, 1 to 20, 1 to 12, 1 to 10, 1 to 6, or 1 to 4.

The term “heterocycloalkyl” refers to a cycloalkyl group in which at least one carbon atom is replaced by a non-carbon atom selected from at least one of O, S, N, P, B, Si, Ge, or Se. The number of carbon atoms in heterocycloalkyl may be 3 to 40, 3 to 30, 3 to 20, 3 to 12, 3 to 10, or 3 to 6. Non-limiting examples of heterocycloalkyl include epoxybutyl, epoxypentyl and epoxyhexyl.

The term “aryl” refers to an aromatic hydrocarbon group derived from removing one hydrogen atom from an aromatic ring compound, which may be a monocyclic aryl or polycyclic aryl group. In a polycyclic aryl group, at least one ring is an aromatic ring system. Multiple rings in a polycyclic aryl group may be connected to each other via a single bond or fused to each other. Non-limiting examples of aryl include phenyl, naphthyl, anthracenyl, phenanthrenyl, naphthacenyl, pyrenyl, peryl, chrysenyl, acenaphthyl, benzopyrenyl, benzo[c]phenanthrenyl, benzo[g]chrysenyl, fluorenyl, spirobifluorenyl, benzofluorenyl, dibenzofluorenyl, biphenyl, terphenyl, quaterphenyl, fluoranthenyl, and the like. The number of carbon atoms in aryl may be 6 to 30, 6 to 20, 6 to 18, 6 to 12, or 6 to 10.

The term “heteroaryl” refers to an aryl group in which at least one carbon atom is replaced by a non-carbon atom, excluding cases where the aryl group uses a non-carbon atom as a linking site (e.g., aryloxy, arylsilyl, arylamino), wherein the non-carbon atom may be O, S, N, Se, Si or Ge. Non-limiting examples of heteroaryl include pyrrolyl, pyrrolopyrrolyl, furopyrrolyl, thienopyrrolyl, pyridyl, pyrazolyl, pyrimidinyl, pyrazinyl, triazinyl, pyridazinyl, phenazinyl, phenothiazinyl, phenoxazinyl, indolyl, isoindolyl, imidazolyl, benzimidazolyl, triazolyl, tetrazolyl, furyl, benzofuryl, isobenzofuryl, dibenzofuryl, furofuryl, azadibenzofuryl, thienofuryl, diazadibenzofuryl, benzo[b]naphtho[1,2-d]furyl, quinolinyl, isoquinolinyl, quinoxalinyl, quinazolinyl, quinazolinonyl, carbazolyl, azacarbazolyl, diazacarbazolyl, phenanthridinyl, perimidinyl, acridinyl, dihydroacridinyl, phenanthrolinyl, oxazolinyl, oxazolyl, oxadiazolyl, benzisoxazolyl, thiazolyl, benzothiazolyl, benzisothiazolyl, pyrroloimidazolyl, furazanyl, thienyl, benzothienyl, dibenzothienyl, azadibenzothienyl, diazadibenzothienyl, thienothienyl, phthalazinyl, and the like. The number of carbon atoms in heteroaryl may be 3 to 30, 3 to 20, 3 to 18, 3 to 12, 3 to 10, or 3 to 6.

The term “alkoxy” refers to a group having an-O-alkyl group, i.e., an alkyl group as defined above is linked to the parent nucleus via an oxygen atom. Non-limiting examples of alkoxy include methoxy (—O—CH₃ or —OMe), ethoxy (—O—CH₂CH₃ or —OEt), and tert-butoxy (—O—C(CH₃) 3 or —OtBu), and the like.

The term “aryloxy” refers to a monovalent substituent represented by Ar—O—, wherein Ar is aryl as defined above. Non-limiting examples of aryloxy include phenoxy, naphthoxy, and biphenyloxy, and the like.

The term “aralkyl” refers to an alkyl group substituted with an aryl group, wherein “aryl” and “alkyl” are defined as previously described. Non-limiting examples of aralkyl groups include benzyl, phenethyl, phenylpropyl, tolylmethyl, and p-tolylmethyl, and the like. The number of carbon atoms in aralkyl may be 7 to 30, 7 to 20, 7 to 18, 7 to 12, or 7 to 10.

The term “alkylamino” refers to an amino group substituted with an alkyl group, wherein “alkyl” is defined as previously described. When alkylamino is C0 alkylamino, i.e., with 0 carbon atoms, it represents a —NH₂ group. Other non-limiting examples of alkylamino include methylamino, ethylamino, dimethylamino, triethylammonio, diisopropylamino, trimethylammonio, and the like. The number of carbon atoms in alkylamino may be 0 to 20, 0 to 12, 0 to 10, 0 to 6, or 0 to 4.

Unless specifically limited, the groups such as “alkyl”, “heteroalkyl”, “alkenyl”, “alkynyl”, “cycloalkyl”, “heterocycloalkyl”, “aryl”, “heteroaryl”, “aralkyl”, “alkoxy”, “aryloxy”, “alkylsilyl”, “arylsilyl”, “alkylamino”, “alkylboryl”, and “alkylsilane group” described in the present disclosure may be substituted or unsubstituted.

The term “substituted” in “substituted or unsubstituted” means that one or more hydrogen atoms are replaced by other atoms or functional groups (i.e., substituents), and unless otherwise limited by definition, also includes replacement of one or more hydrogen atoms by a group formed by linking two or more of the aforementioned substituents.

The term “maximum number of substitutions” refers to the maximum number of hydrogen atoms contained in the group when no substituents other than hydrogen are present.

The term “any two are connected” means that any two of them are directly connected via a chemical bond.

The following examples are merely for illustrative purposes and should not be construed as limiting the scope of the present disclosure.

The raw materials and solvents used in the synthesis of the compounds in the present disclosure were all purchased from suppliers well-known to those skilled in the art, such as Alfa and Acros.

### Synthesis of Compound Ir(La006)₂(Lb005)

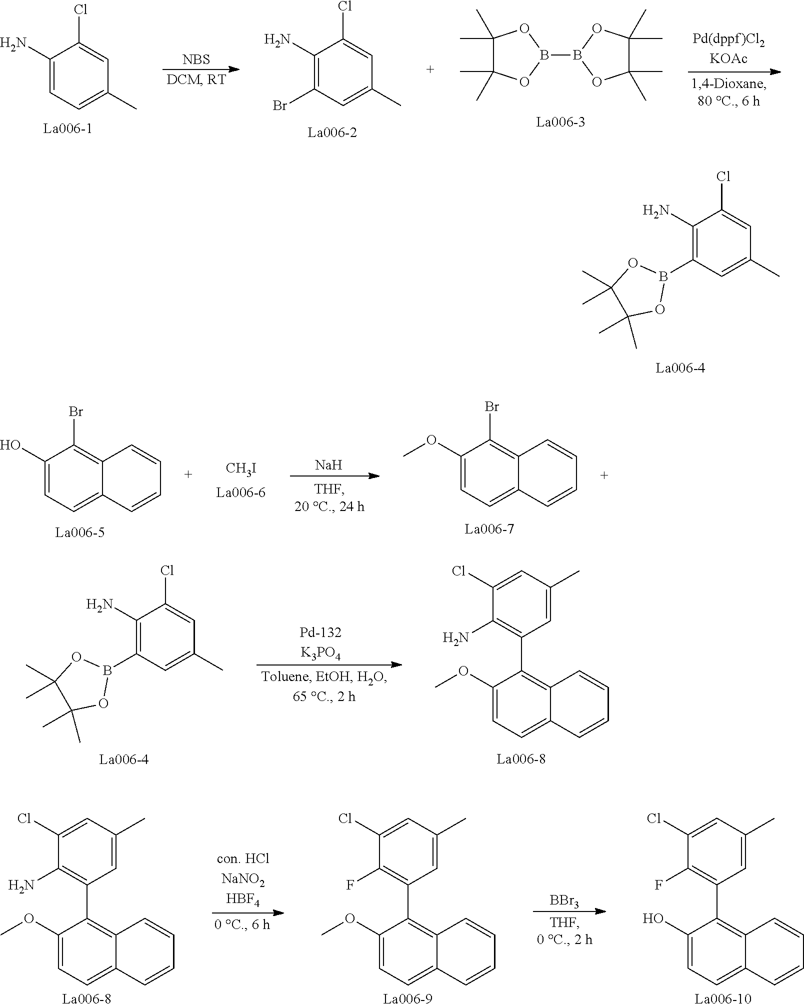

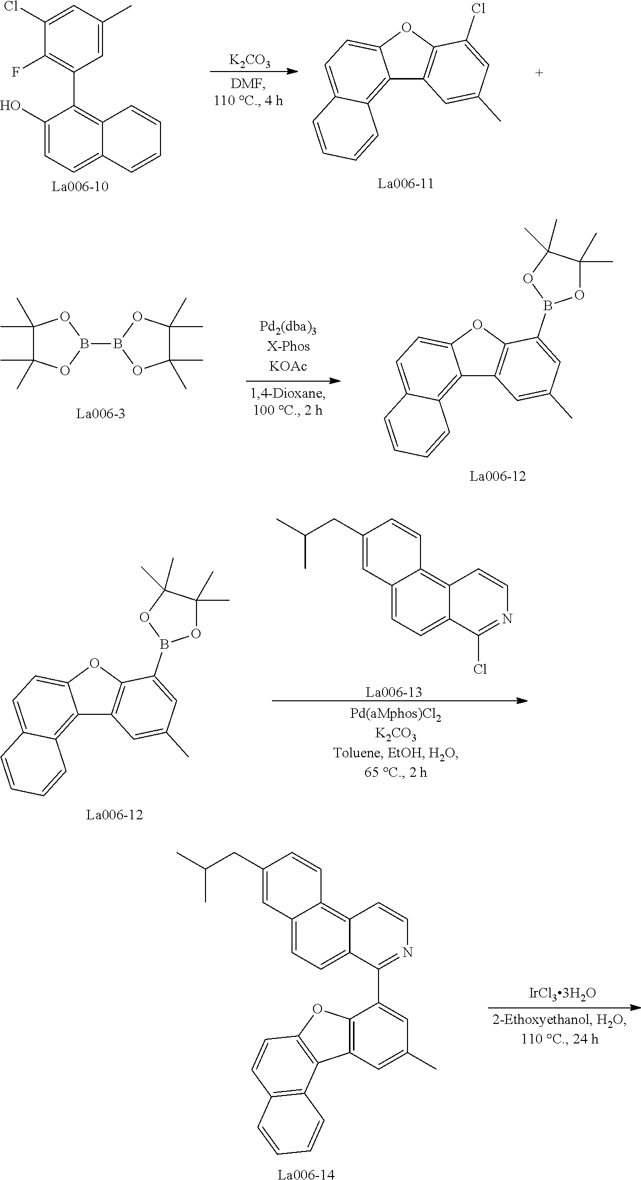

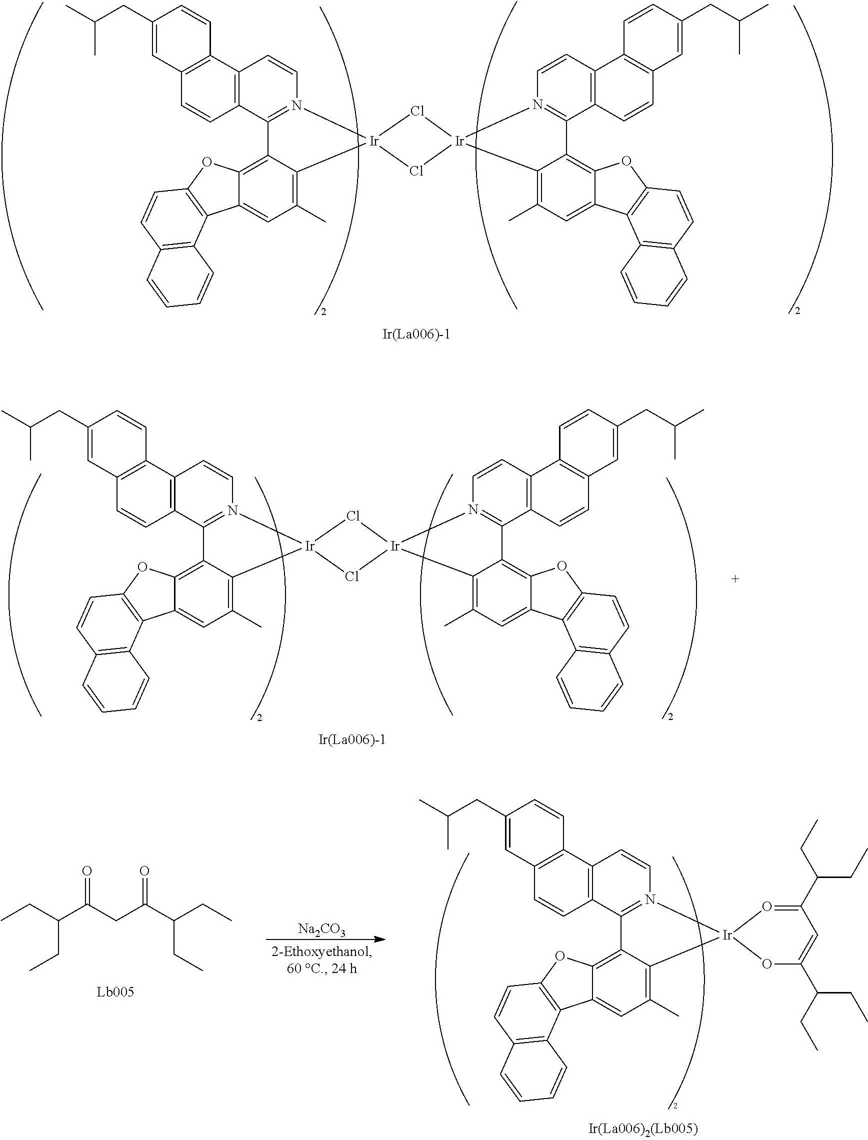

### Synthesis of Compound La006-2

Compound La006-1 (40.00 g, 282.49 mmol) was added to a 1000 mL three-necked round-bottom flask, and dissolved in 300 mL of dichloromethane under stirring. N-bromosuccinimide (NBS, 16.07 g, 282.49 mmol) was dissolved in dichloromethane (150 mL) and then added dropwise to the La006-1 in dichloromethane. The reaction was carried out at room temperature for 4 hours. The reaction was monitored by TLC (ethyl acetate:n-hexane=1:15 as a developing solvent), which showed that the compound La006-1 was consumed completely.

After completion of the reaction, a portion of the solvent was removed by concentration under reduced pressure. Deionized water (300 mL each) was added for washing for three times. After liquid separation, a sediment was loaded onto a silica gel column using a dry packing method, and then purified by silica gel column chromatography (200-300 mesh silica gel, ethyl acetate:n-hexane=1:15 as an eluent). After elution, the product was concentrated under reduced pressure at 60° C. for 1 hour to obtain the target compound La006-2 (32.28 g, purity: 99.26%, yield: 51.82%), with a mass spectrum (MS): 219.95 (M+H).

### Synthesis of Compound La006-4

Compound La006-2 (32.00 g, 145.13 mmol), compound La006-3 (36.85 g, 145.13 mmol), 1,1-bis(diphenylphosphine)diphenylferric palladium dichloride (Pd(dppf)Cl₂, 1.06 g, 1.45 mmol), potassium acetate (35.61 g, 362.82 mmol), and 1,4-dioxane (700 mL) were added to a 1000 mL three-necked round-bottom flask. The mixture was evacuated and displaced with nitrogen for three times, and then the system was heated to 80° C. and reacted for 6 hours. The reaction was monitored by TLC (ethyl acetate:n-hexane=1:15 as the developing solvent), which showed that the compound La006-2 was consumed completely.

The mixture was cooled to 60° C., concentrated under reduced pressure to remove the solvent, and ethyl acetate (500 mL) was added. A resulting mixture was washed three times with deionized water (300 mL×3). After liquid separation, a sediment was loaded onto a silica gel column using a dry packing method, and then purified by silica gel column chromatography (200-300 mesh silica gel, ethyl acetate: n-hexane=1:15 as the eluent). After elution, the product was concentrated under reduced pressure at 70° C. for 1 hour to obtain the target compound La006-4 (30.25 g, purity: 99.17%, yield: 77.90%), with a mass spectrum (MS): 268.12 (M+H).

### Synthesis of Compound La006-7

Compound La006-5 (40.00 g, 179.32 mmol), sodium hydride (8.61 g, 358.63 mmol), and tetrahydrofuran (500 mL) were added to a 1000 mL three-necked round-bottom flask. The mixture was evacuated and displaced with nitrogen for three times. Then, compound La006-6 (25.45 g, 179.32 mmol) was added dropwise to the reaction mixture at 0° C. After the addition was complete, the mixture was heated to 20° C. and stirred for 24 hours. The reaction was monitored by TLC (ethyl acetate:n-hexane=1:10 as the developing solvent), which showed that the compound La006-5 was consumed completely.

After completion of the reaction, deionized water (200 mL) and ethyl acetate (500 mL) were added. After liquid separation, a sediment was loaded onto a silica gel column using a dry packing method, and then purified by silica gel column chromatography (200-300 mesh silica gel, ethyl acetate:n-hexane=1:10 as the eluent). After elution, the product was concentrated under reduced pressure at 50° C. for 1 hour to obtain the target compound La006-7 (27.52 g, purity: 99.34%, yield: 64.73%), with a mass spectrum (MS): 236.98 (M+H).

### Synthesis of Compound La006-8

Compound La006-7 (26.00 g, 109.66 mmol), compound La006-4 (29.34 g, 109.66 mmol), dichlorodi-tert-butyl-(4-dimethylaminophenyl) phosphine palladium (Pd-132, 0.78 g, 1.10 mmol), potassium phosphate (58.19 g, 274.15 mmol), toluene (450 mL), ethanol (90 mL), and water (90 mL) were added to a 1000 mL three-necked round-bottom flask. The mixture was evacuated and displaced with nitrogen for three times. The system was then heated to 65° C. and reacted for 2 hours. The reaction was monitored by TLC (ethyl acetate:n-hexane=1:5 as the developing solvent), which showed that the compound La006-7 was consumed completely.

The mixture was cooled to 60° C., concentrated under reduced pressure to remove the solvent, and ethyl acetate (500 mL) was added. A resulting mixture was washed three times with deionized water (300 mL×3). After liquid separation, a sediment was loaded onto a silica gel column using dry packing method, and then purified by silica gel column chromatography (200-300 mesh silica gel, ethyl acetate: n-hexane=1:15 as the eluent). After elution, the product was concentrated under reduced pressure at 70° C. for 1 hour to obtain the target compound La006-8 (24.12 g, purity: 99.42%, yield: 73.86%), with a mass spectrum (MS): 298.09 (M+H).

### Synthesis of Compound La006-9

Compound La006-8 (24.00 g, 80.60 mmol) and concentrated hydrochloric acid (37%, 240 mL) were added to a 1000 mL three-necked round-bottom flask. The system was cooled to 0-5° C., and an aqueous solution of sodium nitrite (7.23 g, 104.77 mmol) was added dropwise. After the addition was complete, the mixture was stirred at this temperature for 30 min to obtain a diazonium salt solution. Tetrafluoroboric acid (45%, 120 mL) solution was then added dropwise to the diazonium salt solution. After the addition was complete, the mixture was stirred at this temperature for another 0.5 h. The reaction was monitored by TLC (ethyl acetate:n-hexane=1:15 as the developing solvent), which showed that the compound La006-8 was consumed completely.

After completion of the reaction, the mixture was directly suction-filtered, and the filter cake was dried at 60° C. for 2 hours to obtain the target compound La006-9 (15.26 g, purity: 99.24%, yield: 62.95%), with a mass spectrum (MS): 301.07 (M+H).

### Synthesis of Compound La006-10

Compound La006-9 (15.00 g, 49.87 mmol) was dissolved in tetrahydrofuran (150 mL), a resulting mixture was cooled to 0° C., and stirred for 10 min. Boron tribromide (1 M, 149.62 mL) was slowly added dropwise. After the addition was complete, the mixture was stirred at this temperature for 1 hour. The reaction was monitored by TLC (ethyl acetate:n-hexane=1:15 as the developing solvent), which showed that the compound La006-9 was consumed completely.

The reaction mixture was heated to room temperature, and deionized water (150 mL) and ethyl acetate (300 mL) were added. After liquid separation, a sediment was loaded onto a silica gel column using a dry packing method, and then purified by silica gel column chromatography (200-300 mesh silica gel, ethyl acetate:n-hexane=1:15 as the eluent). After elution, the product was concentrated under reduced pressure at 60° C. for 1 hour to obtain the target compound La006-10 (9.12 g, purity: 99.50%, yield: 63.77%), with a mass spectrum (MS): 287.06 (M+H).

### Synthesis of Compound La006-11

Compound La006-10 (9.00 g, 31.39 mmol), potassium carbonate (10.85 g, 78.47 mmol), and N,N-dimethylformamide (DMF, 200 mL) were added to a 500 mL three-necked round-bottom flask. The mixture was evacuated and displaced with nitrogen for three times, and then the system was heated to 110° C. and reacted for 4 hours. The reaction was monitored by TLC (ethyl acetate:n-hexane=1:10 as the developing solvent), which showed that the compound La006-10 was consumed completely.

The reaction mixture was cooled to room temperature, and ethyl acetate (200 mL) was added. A resulting mixture was washed three times with deionized water (300 mL×3). After liquid separation, a sediment was loaded onto a silica gel column using dry packing method, and then purified by silica gel column chromatography (200-300 mesh silica gel, ethyl acetate:n-hexane=1:10 as the eluent). After elution, the product was concentrated under reduced pressure at 70° C. for 1 hour to obtain the target compound La006-11 (6.03 g, purity: 99.52%, yield: 72.03%), with a mass spectrum (MS): 267.05 (M+H).

### Synthesis of Compound La006-12

The target compound La006-12 (6.34 g, purity: 99.15%, yield: 78.67%) with a mass spectrum (MS): 359.17 (M+H) was obtained according to the synthesis and purification method for compound La006-4, only the corresponding raw materials were changed.

### Synthesis of Compound La006-14

Compounds La006-12 (6.00 g, 16.75 mmol), La006-13 (4.52 g, 16.75 mmol), bis(4-dimethylaminophenyl di-tert-butylphosphine) palladium dichloride (Pd(aMpjos)Cl₂, 0.12 g, 0.17 mmol), potassium carbonate (5.79 g, 41.87 mmol), toluene (150 mL), ethanol (30 mL), and deionized water (30 mL) were added to a 500 mL three-necked flask. The mixture was evacuated and displaced with nitrogen for three times, and then stirred at 65° C. for 2 hours under nitrogen atmosphere. The reaction was monitored by TLC (ethyl acetate:n-hexane=1:10 as the developing solvent), which showed that compound La006-12 was consumed completely.

The reaction mixture was cooled to room temperature, concentrated under reduced pressure to remove the organic solvent, and then ethyl acetate (300 mL) was added. A resulting mixture was washed with deionized water (3×150 mL). After liquid separation, the organic phase was concentrated, and then purified by silica gel column chromatography (200-300 mesh silica gel, eluent:ethyl acetate:n-hexane=1:15). After concentration, the target compound La006-14 (5.84 g, purity: 99.72%, yield: 74.89%) was obtained, with a mass spectrum (MS): 466.21 (M+H).

### Synthesis of Compound Ir(La006)-1

Compound La006-14 (5.50 g, 11.81 mmol) and iridium trichloride trihydrate (1.49 g, 4.22 mmol) were added to a 500 mL three-necked round-bottom flask. Ethylene glycol ether (150 mL) and deionized water (50 mL) were added, and the mixture was evacuated and displaced with nitrogen for three times, then heated to 110° C. and refluxed under stirring for 24 hours.

After the reaction mixture was cooled to room temperature, methanol (100 mL) was added, and a resulting mixture was stirred at room temperature for 1 hour, and then suction-filtered. The filter cake was washed with methanol (50 mL) and dried under vacuum at 80° C. to obtain compound Ir(La006)-1 (7.16 g, yield: 73.35%), which was used directly in the next step without purification.

### Synthesis of Compound Ir(La006)₂(Lb005)

Compound Ir(La006)-1 (7.00 g, 3.03 mmol), Lb005 (3.21 g, 15.13 mmol), sodium carbonate (3.21 g, 30.25 mmol), and 2-ethoxyethanol (100 mL) were added to a 250 mL single-necked round-bottom flask. The mixture was evacuated and displaced with nitrogen for three times, and stirred at 60° C. for 24 hours. The reaction was monitored by TLC (methanol:dichloromethane=2:100 as the developing solvent), which showed that the compound Ir(La006)-1 was consumed completely.

After the reaction mixture was cooled to room temperature, methanol (120 mL) was added, and a resulting mixture was stirred at room temperature for 2 hours, and then suction-filtered. The filter cake was dissolved in dichloromethane (150 mL) and then filtered through 300-400 mesh silica gel (50 g). The filtrate was washed with deionized water (3×80 mL) and concentrated at 60° C. to obtain a red solid. The solid was recrystallized twice with toluene and methanol to obtain a red solid, which was the crude compound Ir(La006)₂(Lb005) (2.08 g, purity: 99.82%, yield: 51.59%). 2.08 g of crude Ir(La006)₂(Lb005) was sublimated and purified to obtain sublimated pure Ir(La006)₂(Lb005) (1.45 g, purity: 99.70%, yield: 69.71%), with a mass spectrum (MS): 1333.54 (M+H).

¹H NMR (400 MHz, CDCl₃) δ 8.58 (s, 2H), 8.54 (dd, J=14.5, 3.4 Hz, 2H), 8.48 (d, J=15.0 Hz, 2H), 8.02-7.96 (m, 2H), 7.92 (d, J=14.9 Hz, 2H), 7.67-7.48 (m, 12H), 7.29 (dd, J=15.0, 2.9 Hz, 2H), 7.02 (t, J=3.0 Hz, 2H), 6.95 (dd, J=14.9, 3.0 Hz, 2H), 5.87 (d, J=2.0 Hz, 1H), 3.57 (d, J=8.3 Hz, 1H), 2.54 (d, J=13.8 Hz, 4H), 2.45-2.38 (m, 1H), 2.29 (s, 6H), 1.82 (dd, J=13.3, 12.1 Hz, 2H), 1.38-1.28 (m, 4H), 1.27-1.19 (m, 4H), 0.97-0.91 (m, 12H), 0.87 (d, J=12.5 Hz, 12H).

### Synthesis of Compound Ir(La014)₂(Lb005)

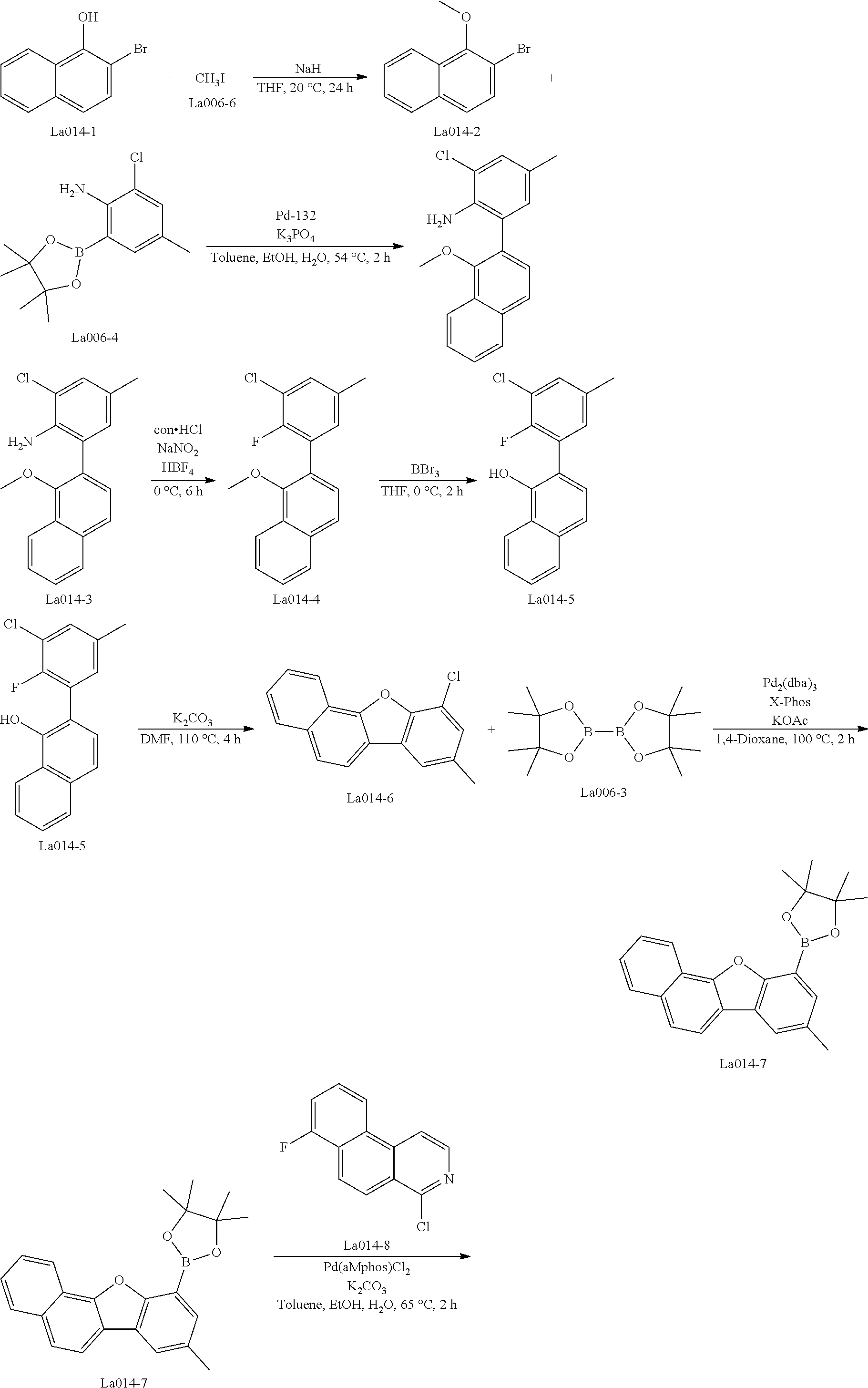

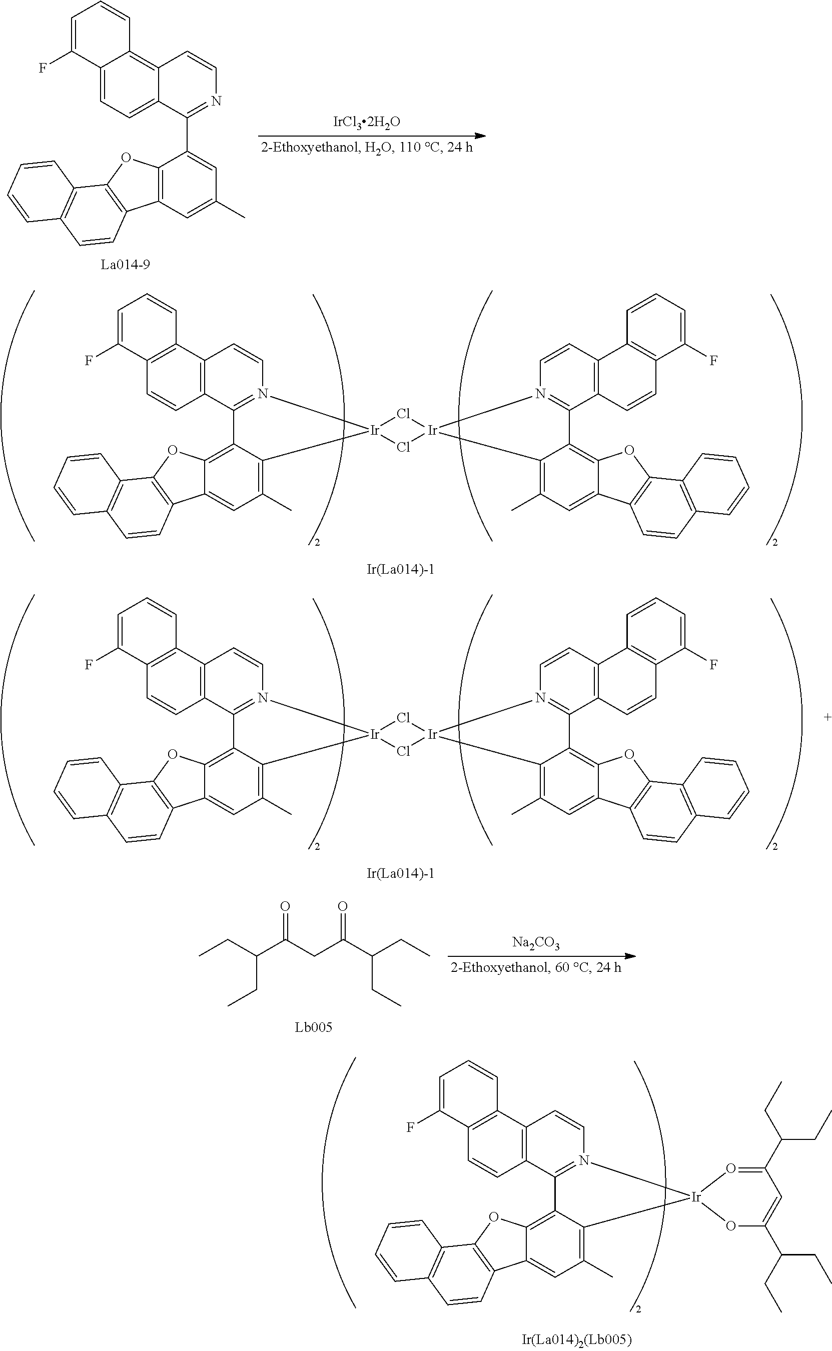

### Synthesis of Compound La014-2

The target compound La014-2 (29.65 g, purity: 99.40%, yield: 69.74%) with a mass spectrum (MS): 236.98 (M+H) was obtained according to the synthesis and purification method for compound La006-7, only the corresponding raw materials were changed.

### Synthesis of Compound La014-3

The target compound La014-3 (27.62 g, purity: 99.27%, yield: 75.83%) with a mass spectrum (MS): 298.09 (M+H) was obtained according to the synthesis and purification method for compound La006-8, only the corresponding raw materials were changed.

### Synthesis of Compound La014-4

The target compound La014-4 (15.98 g, purity: 99.35%, yield: 57.53%) with a mass spectrum (MS): 301.07 (M+H) was obtained according to the synthesis and purification method for compound La006-9, only the corresponding raw materials were changed.

### Synthesis of Compound La014-5

The target compound La014-5 (9.76 g, purity: 99.52%, yield: 66.05%) with a mass spectrum (MS): 287.06 (M+H) was obtained according to the synthesis and purification method for compound La006-10, only the corresponding raw materials were changed.

### Synthesis of Compound La014-6

The target compound La014-6 (6.53 g, purity: 99.61%, yield: 73.89%) with a mass spectrum (MS): 267.05 (M+H) was obtained according to the synthesis and purification method for compound La006-11, only the corresponding raw materials were changed.

### Synthesis of Compound La014-7

The target compound La014-7 (6.82 g, purity: 99.19%, yield: 78.12%) with a mass spectrum (MS): 359.17 (M+H) was obtained according to the synthesis and purification method for compound La006-4, only the corresponding raw materials were changed.

### Synthesis of Compound La014-9

The target compound La014-9 (5.82 g, purity: 99.57%, yield: 71.73%) with a mass spectrum (MS):

428.14 (M+H) was obtained according to the synthesis and purification method for compound La006-14, only the corresponding raw materials were changed.

### Synthesis of Compound Ir(La014)-1

The target compound Ir(La014)-1 (6.76 g, yield: 68.07%) was obtained according to the synthesis and purification method for compound Ir(La006)-1, only the corresponding raw materials were changed. The target compound Ir(La014)-1 was used directly in the next step without purification.

### Synthesis of Compound Ir(La014)₂(Lb005)

The crude target compound Ir(La014)₂(Lb005) (2.17 g, purity: 99.85%, yield: 57.42%) was obtained according to the synthesis and purification method for compound Ir(La006)₂(Lb005), only the corresponding raw materials were changed. Then 2.17 g of crude compound Ir(La014)₂(Lb005) was sublimated and purified to obtain sublimated pure compound Ir(La014)₂(Lb005) (1.42 g, purity: 99.75%, yield: 65.43%), with a mass spectrum (MS): 1257.39 (M+H).

¹H NMR (400 MHz, CDCl₃) δ 8.70 (dd, J=14.9, 3.0 Hz, 2H), 8.45 (d, J=15.0 Hz, 2H), 7.91-7.86 (m, 4H), 7.84-7.78 (m, 4H), 7.55 (dd, J=15.0, 10.4 Hz, 4H), 7.50-7.42 (m, 6H), 7.39-7.31 (m, 2H), 7.20 (dd, J=14.9, 3.0 Hz, 2H), 7.14-7.06 (m, 2H), 5.61 (d, J=2.0 Hz, 1H), 2.87-2.82 (m, 1H), 2.28 (s, 7H), 1.36-1.19 (m, 8H), 0.97-0.90 (m, 12H).

### Synthesis of Compound Ir(La017)2(Lb005)

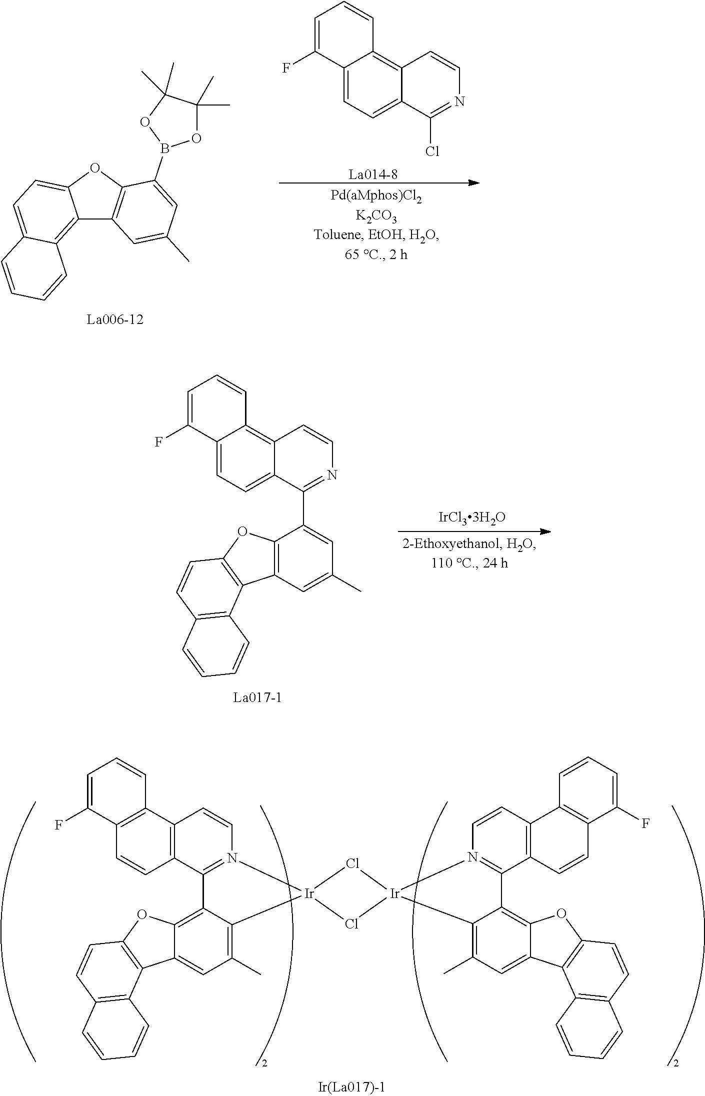

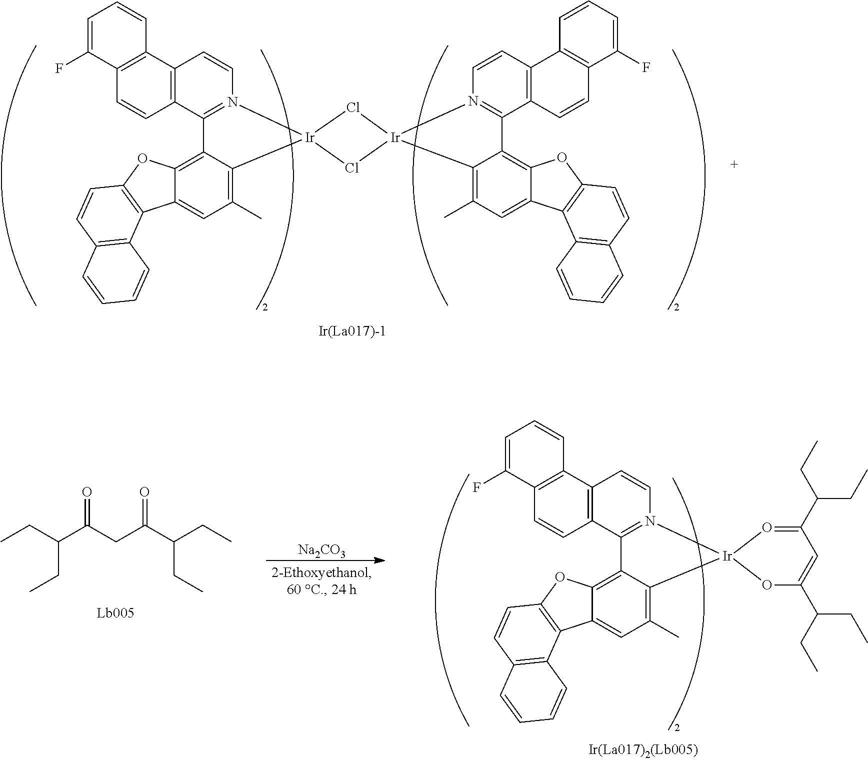

### Synthesis of Compound La017-1

The target compound La017-1 (11.74 g, purity: 99.49%, yield: 65.59%) with a mass spectrum (MS): 428.14 (M+H) was obtained according to the synthesis and purification method for compound La006-14, only the corresponding raw materials were changed.

### Synthesis of Compound Ir(La017)-1

The target compound Ir(La017)-1 (14.28 g, yield: 68.77%) was obtained according to the synthesis and purification method for compound Ir(La006)-1, only the corresponding raw materials were changed. The target compound Ir(La017)-1 was used directly in the next step without purification.

### Synthesis of Compound Ir(La017)₂(Lb005)

The crude target compound Ir(La017)₂(Lb005) (3.97 g, purity: 99.79%, yield: 48.78%) was obtained according to the synthesis and purification method for compound Ir(La006)₂(Lb005), only the corresponding raw materials were changed. 3.97 g of crude compound Ir(La017)₂(Lb005) was sublimated and purified to obtain sublimated pure compound Ir(La017)₂(Lb005) (2.73 g, purity: 99.80%, yield: 68.76%), with a mass spectrum (MS): 1257.39 (M+H).

¹H NMR (400 MHz, CDCl₃) δ 8.88 (dd, J=14.9, 3.0 Hz, 2H), 8.51 (dd, J=14.5, 3.4 Hz, 2H), 8.45 (d, J=15.0 Hz, 2H), 8.19 (s, 2H), 7.98 (t, J=3.3 Hz, 1H), 7.95 (d, J=3.3 Hz, 1H), 7.90 (d, J=15.0 Hz, 2H), 7.63-7.45 (m, 10H), 7.40-7.31 (m, 2H), 7.27 (dd, J=15.0, 2.9 Hz, 2H), 7.15-7.06 (m, 2H), 4.58 (d, J=1.8 Hz, 1H), 3.21-3.10 (m, 1H), 2.61-2.48 (m, 1H), 2.28 (s, 6H), 1.37-1.18 (m, 8H), 0.99-0.88 (m, 12H).

### Synthesis of Compound Ir(La017)₂(Lb007)

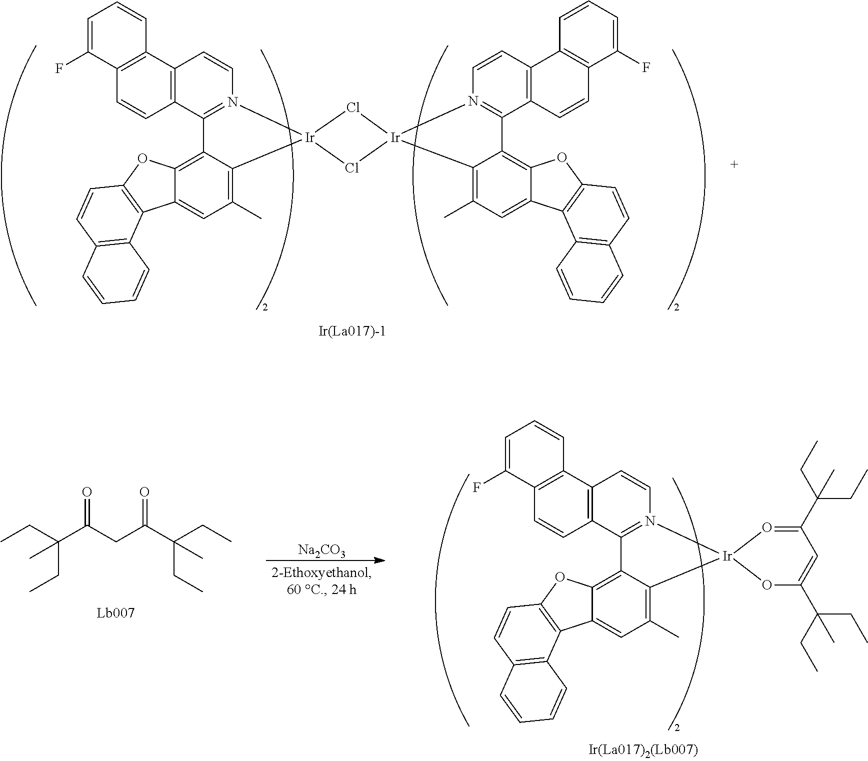

### Synthesis of Compound Ir(La017)₂(Lb007)

The crude target compound Ir(La017)₂(Lb007) (3.09 g, purity: 99.82%, yield: 63.28%) was obtained according to the synthesis and purification method for compound Ir(La006)₂(Lb005), only the corresponding raw materials were changed. 3.09 g of crude compound Ir(La017)₂(Lb007) was sublimated and purified to obtain sublimated pure compound Ir(La017)₂(Lb007) (1.84 g, purity: 99.85%, yield: 59.54%), with a mass spectrum (MS): 1285.42 (M+H).

1HNMR (400 MHz, Chloroform-d) δ 8.89 (s, 1H), 8.87 (d, 1H), 8.61 (s, 1H), 8.60 (s, 1H), 8.57 (s, 1H), 8.55 (s, 1H), 8.51 (s, 1H), 8.49 (s, 1H), 8.25 (s, 1H), 8.23 (s, 1H), 8.11 (s, 1H), 8.10 (s, 1H), 7.99 (s, 1H), 7.97 (s, 1H), 7.85 (s, 2H), 7.84 (s, 1H), 7.82 (s, 1H), 7.72 (s, 2H), 7.69 (s, 2H), 7.67 (s, 1H), 7.61-7.57 (m, 3H), 7.50-7.44 (m, 5H), 5.10 (s, 1H), 1.75 (s, 6H), 1.20-1.08 (m, 4H), 0.98 (dd, J=13.9, 6.7 Hz, 4H), 0.63 (s, 6H), 0.11 (t, J=7.3 Hz, 6H), 0.06 (t, J=7.4 Hz, 6H).

### Synthesis of Compound Ir(La022)₂(Lb005)

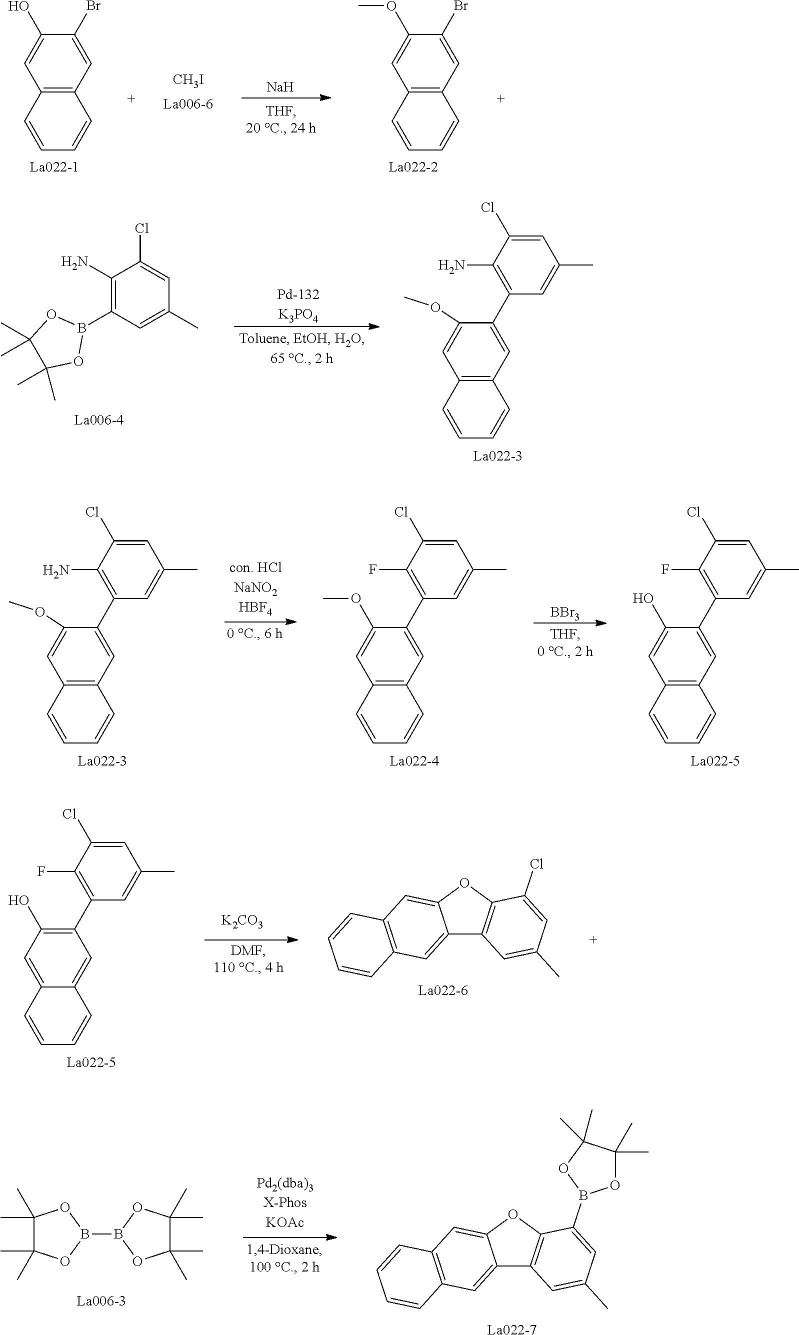

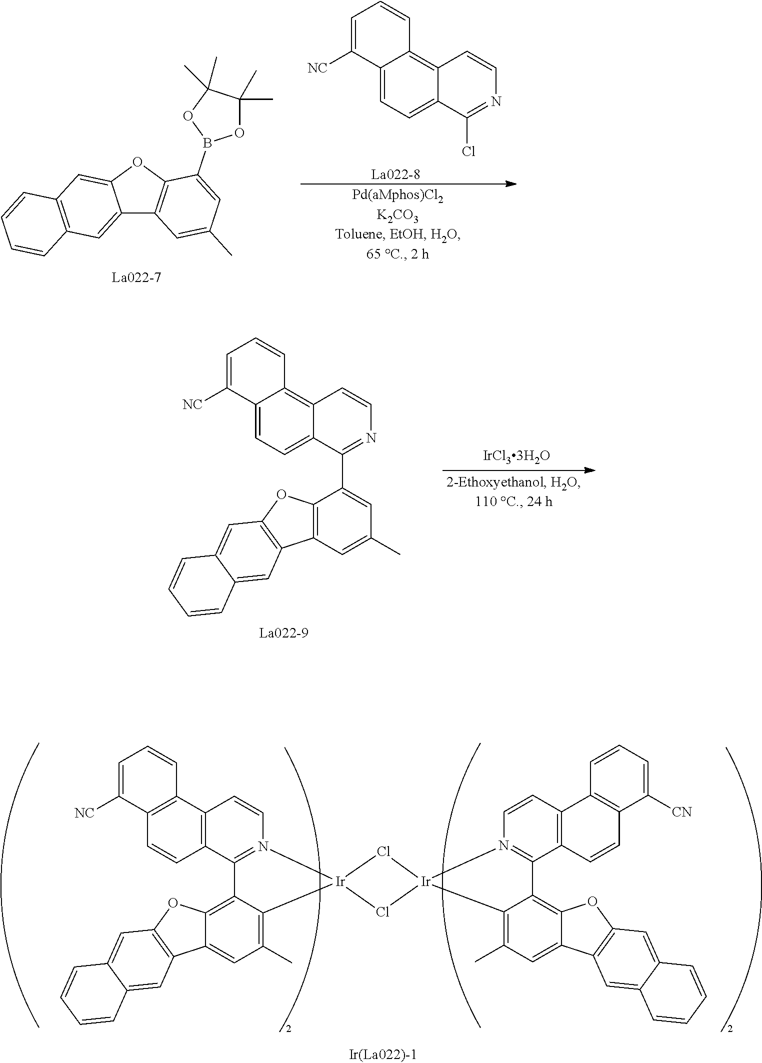

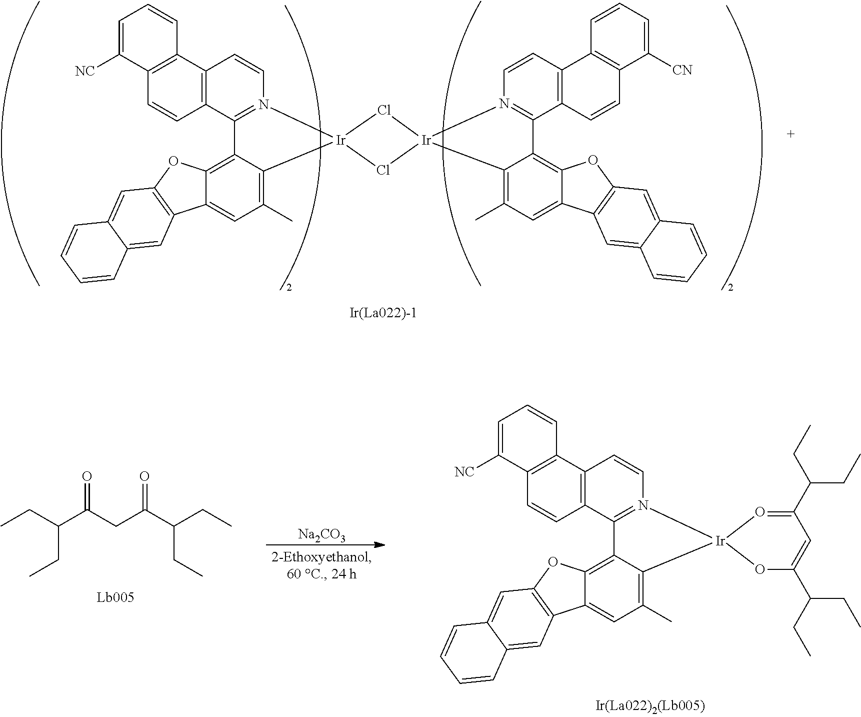

### Synthesis of Compound La022-2

The target compound La022-2 (31.75 g, purity: 99.27%, yield: 74.68%) with a mass spectrum (MS): 236.98 (M+H) was obtained according to the synthesis and purification method for compound La006-7, only the corresponding raw materials were changed.

### Synthesis of Compound La022-3

The target compound La022-3 (25.94 g, purity: 99.51%, yield: 65.57%) with a mass spectrum (MS): 298.09 (M+H) was obtained according to the synthesis and purification method for compound La006-8, only the corresponding raw materials were changed.

### Synthesis of Compound La022-4

The target compound La022-4 (17.04 g, purity: 99.22%, yield: 65.14%) with a mass spectrum (MS): 301.07 (M+H) was obtained according to the synthesis and purification method for compound La006-9, only the corresponding raw materials were changed.

### Synthesis of Compound La022-5

The target compound La022-5 (11.69 g, purity: 99.71%, yield: 72.13%) with a mass spectrum (MS):

287.06 (M+H) was obtained according to the synthesis and purification method for compound La006-10, only the corresponding raw materials were changed.

### Synthesis of Compound La022-6

The target compound La022-6 (8.11 g, purity: 99.46%, yield: 75.81%) with a mass spectrum (MS): 267.05 (M+H) was obtained according to the synthesis and purification method for compound La006-11, only the corresponding raw materials were changed.

### Synthesis of Compound La022-7

The target compound La022-7 (8.51 g, purity: 99.35%, yield: 79.20%) with a mass spectrum (MS): 359.17 (M+H) was obtained according to the synthesis and purification method for compound La006-4, only the corresponding raw materials were changed.

### Synthesis of Compound La022-9

The target compound La022-9 (7.22 g, purity: 99.78%, yield: 70.03%) with a mass spectrum (MS): 435.14 (M+H) was obtained according to the synthesis and purification method for compound La006-14, only the corresponding raw materials were changed.

### Synthesis of Compound Ir(La022)-1

The target compound Ir(La022)-1 (9.35 g, yield: 74.23%) was obtained according to the synthesis and purification method for compound Ir(La006)-1, only the corresponding raw materials were changed. The target compound Ir(La022)-1 was used directly in the next step without purification.

### Synthesis of Compound Ir(La022)₂(Lb005)

The crude target compound Ir(La022)₂(Lb005) (2.92 g, purity: 99.83%, yield: 55.91%) was obtained according to the synthesis and purification method for compound Ir(La006)₂(Lb005), only the corresponding raw materials were changed. 2.92 g of crude compound Ir(La022)₂(Lb005) was sublimated and purified to obtain sublimated pure compound Ir(La022)₂(Lb005) (1.89 g, purity: 99.83%, yield: 65.01%), with a mass spectrum (MS): 1271.4 (M+H).

¹H NMR (400 MHz, CDCl₃) δ 9.18 (dd, J=14.9, 3.0 Hz, 2H), 8.46 (d, J=15.0 Hz, 2H), 8.31 (d, J=3.0 Hz, 1H), 8.29-8.22 (m, 3H), 7.95-7.80 (m, 10H), 7.77-7.69 (m, 2H), 7.57-7.43 (m, 8H), 5.44 (d, J=2.0 Hz, 1H), 3.07-2.87 (m, 2H), 2.28 (s, 6H), 1.36-1.19 (m, 8H), 0.97-0.90 (m, 12H).

### Synthesis of Compound Ir(La038)₂(Lb005)

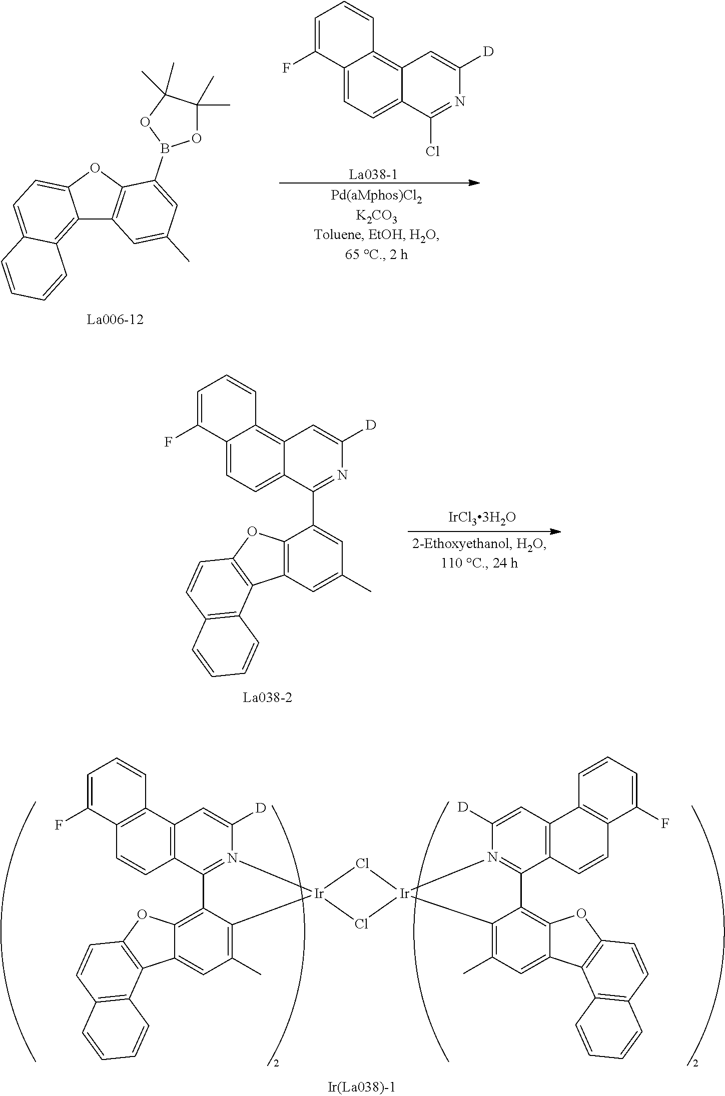

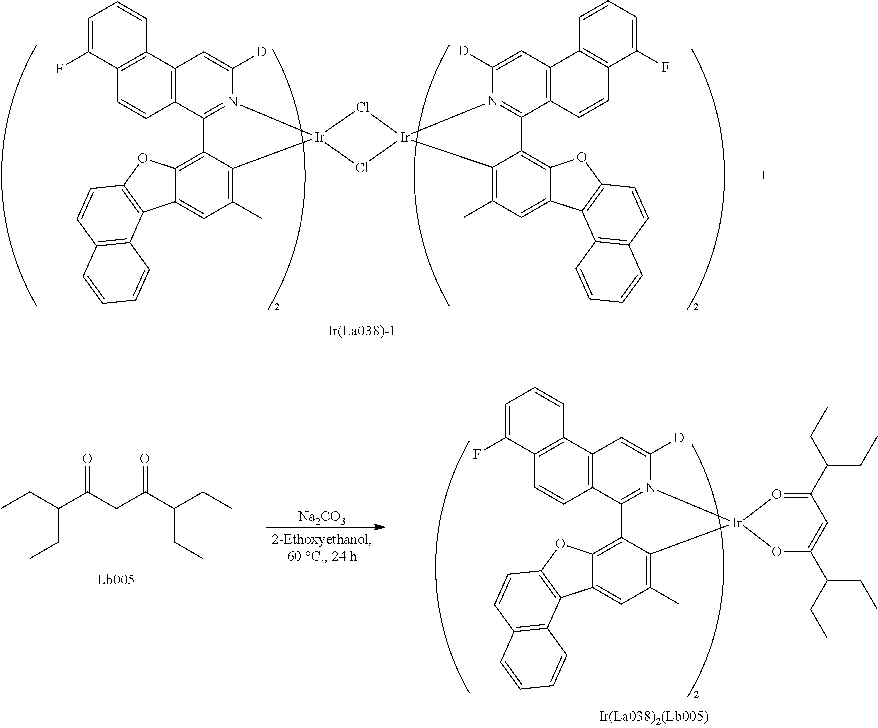

### Synthesis of Compound La038-2

The target compound La038-2 (12.58 g, purity: 99.71%, yield: 70.12%) with a mass spectrum (MS): 429.14 (M+H) was obtained according to the synthesis and purification method for compound La006-14, only the corresponding raw materials were changed.

### Synthesis of Compound Ir(La038)-1

The target compound Ir(La038)-1 (16.47 g, yield: 73.01%) was obtained according to the synthesis and purification method for compound Ir(La006)-1, only the corresponding raw materials were changed. The target compound Ir(La038)-1 was used directly in the next step without purification.

### Synthesis of Compound Ir(La038)₂(Lb005)

The crude target compound Ir(La038)₂(Lb005) (4.83 g, purity: 99.90%, yield: 51.94%) was obtained according to the synthesis and purification method for compound Ir(La006)₂(Lb005), only the corresponding raw materials were changed. 4.83 g of crude compound Ir(La038)₂(Lb005) was sublimated and purified to obtain sublimated pure compound Ir(La038)₂(Lb005) (3.17 g, purity: 99.90%, yield: 65.63%), with a mass spectrum (MS): 1259.40 (M+H).

¹H NMR (400 MHz, CDCl₃) δ 8.78-8.71 (m, 4H), 8.54 (dd, J=14.6, 3.4 Hz, 2H), 8.44 (s, 2H), 8.02-7.97 (m, 2H), 7.92 (d, J=15.1 Hz, 2H), 7.65-7.48 (m, 8H), 7.43-7.34 (m, 2H), 7.29 (dd, J=15.0, 2.9 Hz, 2H), 7.17-7.09 (m, 2H), 5.78 (d, J=1.8 Hz, 1H), 3.46-3.30 (m, 1H), 2.49-2.37 (m, 1H), 2.29 (s, 6H), 1.36-1.19 (m, 8H), 0.97-0.91 (m, 12H).

### Synthesis of Compound Ir(La038)₂(Lb031)

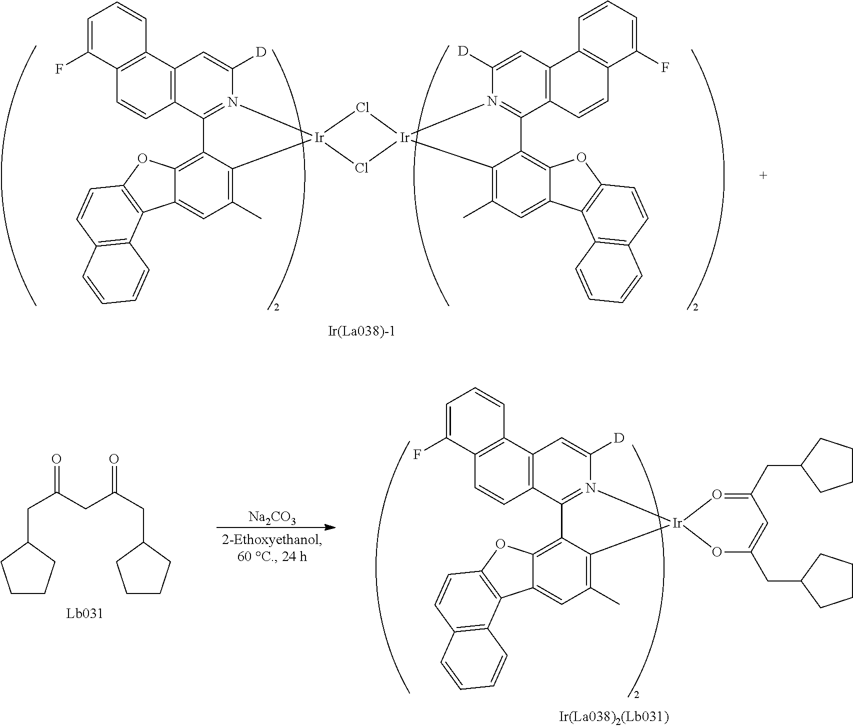

### Synthesis of Compound Ir(La038)₂(Lb031)

The crude target compound Ir(La038)₂(Lb031) (4.16 g, purity: 99.87%, yield: 67.53%) was obtained according to the synthesis and purification method for compound Ir(La006)₂(Lb005), only the corresponding raw materials were changed. 4.16 g of crude compound Ir(La038)₂(Lb031) was sublimated and purified to obtain sublimated pure compound Ir(La038)₂(Lb031) (2.59 g, purity: 99.82%, yield: 62.25%), with a mass spectrum (MS): 1283.40 (M+H).

¹H NMR (400 MHz, CDCl₃) δ 8.74 (dd, J=14.9, 3.0 Hz, 2H), 8.54 (dd, J=14.5, 3.4 Hz, 2H), 8.34 (s, 2H), 8.18 (s, 2H), 8.02-7.96 (m, 2H), 7.92 (d, J=15.0 Hz, 2H), 7.65-7.57 (m, 2H), 7.57-7.46 (m, 6H), 7.43-7.33 (m, 2H), 7.29 (dd, J=15.0, 2.9 Hz, 2H), 7.17-7.09 (m, 2H), 5.66 (t, J=2.0 Hz, 1H), 3.04 (d, J=11.6 Hz, 2H), 2.29 (s, 6H), 2.01 (dd, J=12.3, 2.0 Hz, 2H), 1.97-1.48 (m, 18H).

### Synthesis of Compound Ir(La050)₂(Lb005)

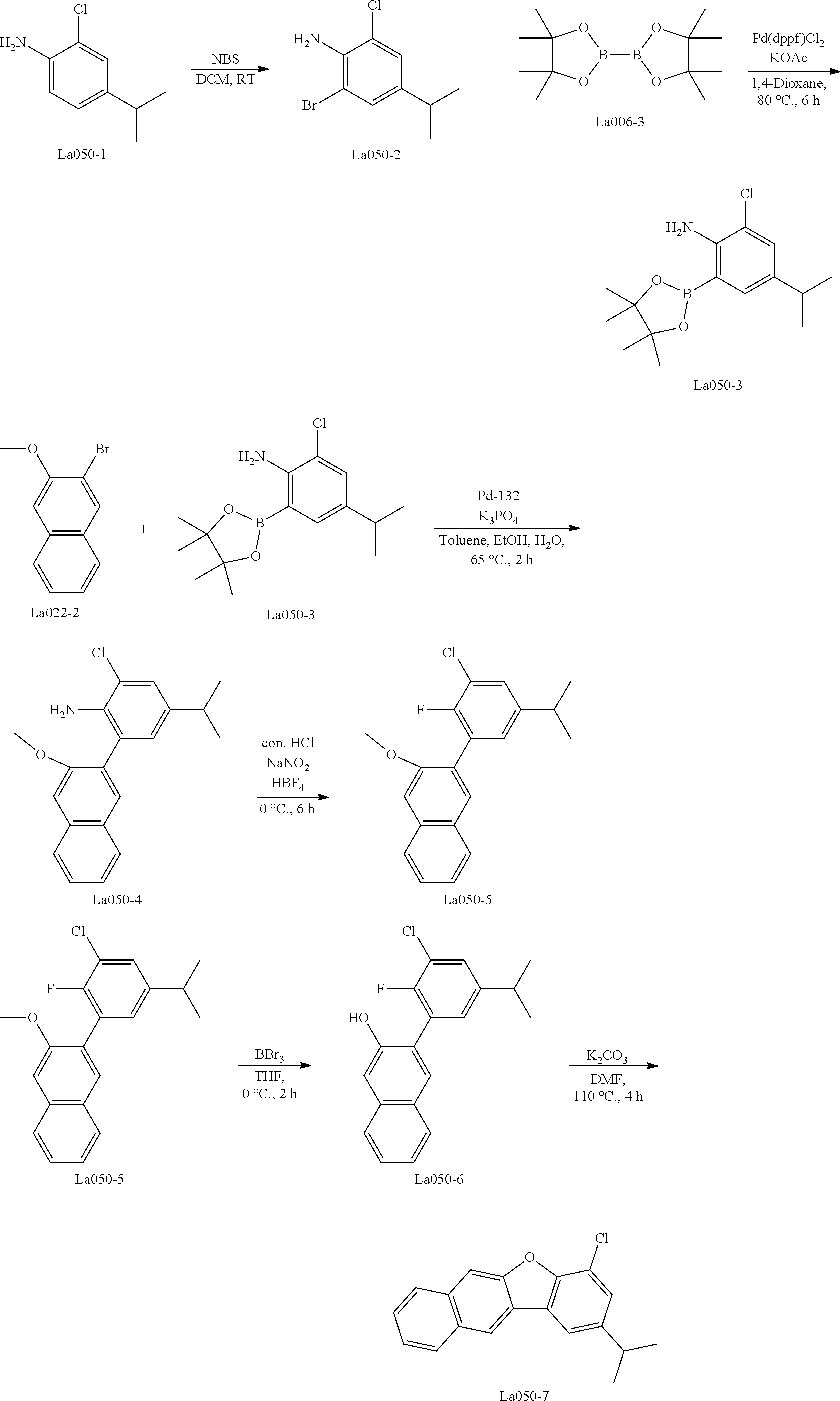

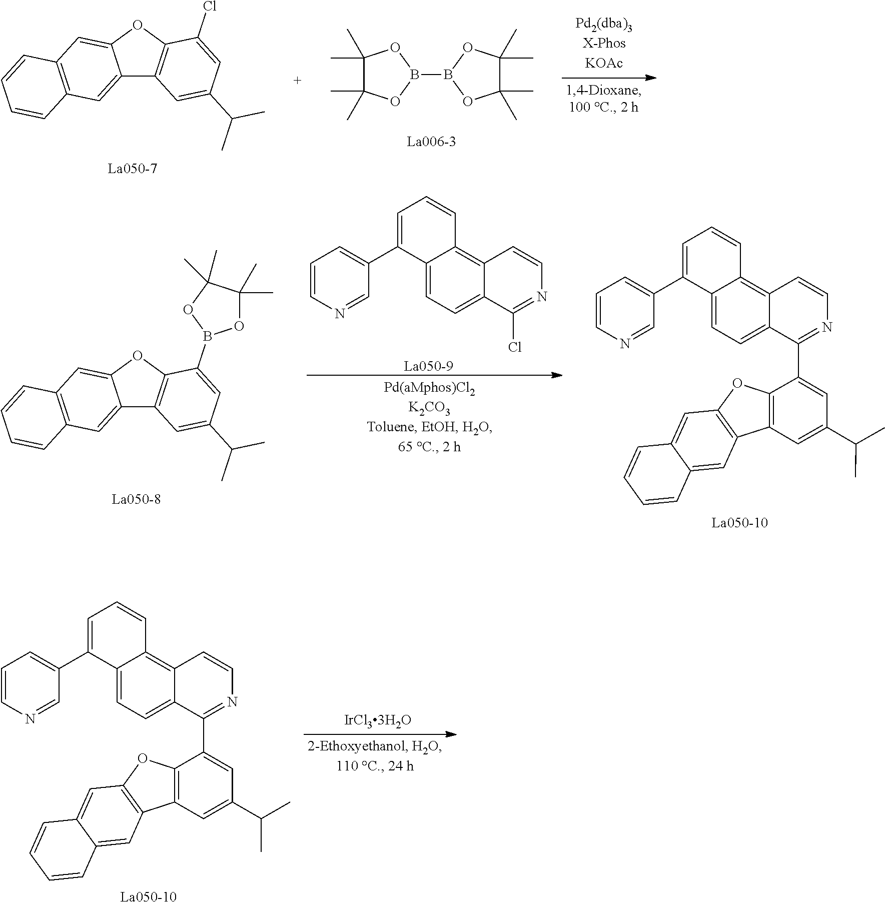

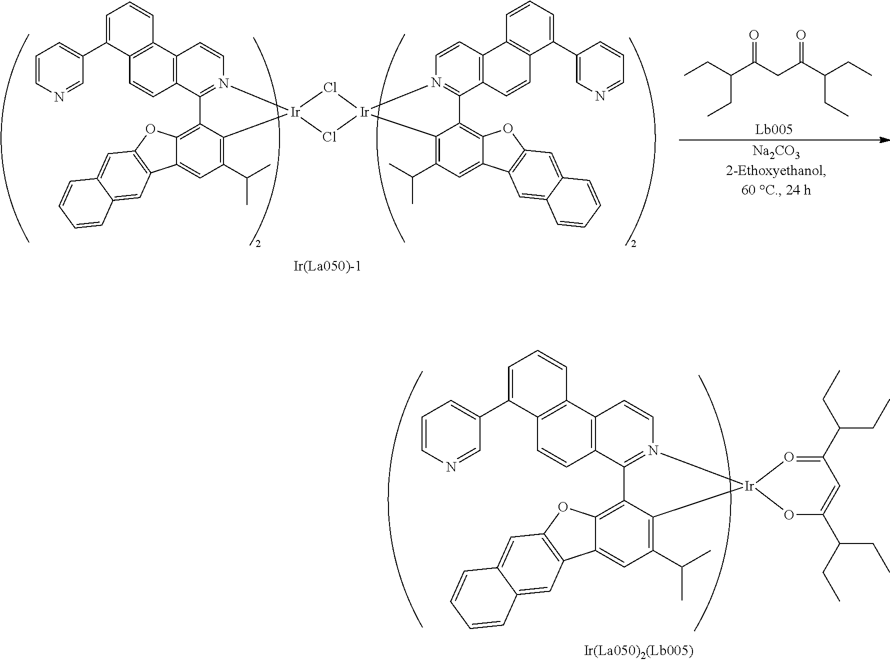

### Synthesis of Compound La050-2

The target compound La050-2 (55.28 g, purity: 99.43%, yield: 75.47%) with a mass spectrum (MS): 247.98 (M+H) was obtained according to the synthesis and purification method for compound La006-2, only the corresponding raw materials were changed.

### Synthesis of Compound La050-3

The target compound La050-3 (51.07 g, purity: 99.20%, yield: 78.07%) with a mass spectrum (MS): 296.15 (M+H) was obtained according to the synthesis and purification method for compound La006-4, only the corresponding raw materials were changed.

### Synthesis of Compound La050-4

The target compound La050-4 (36.29 g, purity: 99.18%, yield: 66.02%) with a mass spectrum (MS): 326.12 (M+H) was obtained according to the synthesis and purification method for compound La006-8, only the corresponding raw materials were changed.

### Synthesis of Compound La050-5

The target compound La050-5 (22.76 g, purity: 99.31%, yield: 62.65%) with a mass spectrum (MS): 329.10 (M+H) was obtained according to the synthesis and purification method for compound La006-9, only the corresponding raw materials were changed.

### Synthesis of Compound La050-6

The target compound La050-6 (14.93 g, purity: 99.44%, yield: 69.31%) with a mass spectrum (MS):

315.09 (M+H) was obtained according to the synthesis and purification method for compound La006-10, only the corresponding raw materials were changed.

### Synthesis of Compound La050-7

The target compound La050-7 (10.08 g, purity: 99.26%, yield: 74.24%) with a mass spectrum (MS): 295.08 (M+H) was obtained according to the synthesis and purification method for compound La006-11, only the corresponding raw materials were changed.

### Synthesis of Compound La050-8

The target compound La050-8 (9.76 g, purity: 99.35%, yield: 74.48%) with a mass spectrum (MS): 387.21 (M+H) was obtained according to the synthesis and purification method for compound La006-4, only the corresponding raw materials were changed.

### Synthesis of Compound La050-10

The target compound La050-10 (9.32 g, purity: 99.62%, yield: 73.64%) with a mass spectrum (MS): 515.20 (M+H) was obtained according to the synthesis and purification method for compound La006-14, only the corresponding raw materials were changed.

### Synthesis of Compound Ir(La050)-1

The target compound Ir(La050)-1 (11.64 g, yield: 74.25%) was obtained according to the synthesis and purification method for compound Ir(La006)-1, only the corresponding raw materials were changed. The target compound Ir(La050)-1 was used directly in the next step without purification.

### Synthesis of Compound Ir(La050)₂(Lb005)

The crude target compound Ir(La050)₂(Lb005) (3.61 g, purity: 99.76%, yield: 55.07%) was obtained according to the synthesis and purification method for compound Ir(La006)₂(Lb005), only the corresponding raw materials were changed. 3.61 g of crude compound Ir(La050)₂(Lb005) was sublimated and purified to obtain sublimated pure compound Ir(La050)₂(Lb005) (2.11 g, purity: 99.80%, yield: 58.44%), with a mass spectrum (MS): 1431.53 (M+H).

¹H NMR (400 MHz, CDCl₃) δ 9.27-9.21 (m, 2H), 9.07 (dd, J=15.0, 2.9 Hz, 2H), 8.95 (dd, J=15.0, 2.9 Hz, 2H), 8.73-8.67 (m, 2H), 8.53-8.45 (m, 4H), 8.36-8.25 (m, 4H), 8.08 (d, J=3.1 Hz, 2H), 8.00 (t, J=15.0 Hz, 2H), 7.92 (d, J=14.9 Hz, 2H), 7.86-7.71 (m, 6H), 7.57 (d, J=15.0 Hz, 2H), 7.52-7.42 (m, 6H), 5.13 (d, J=2.0 Hz, 1H), 2.96-2.78 (m, 2H), 2.28 (s, 2H), 1.35-1.14 (m, 20H), 0.98-0.90 (m, 12H).

### Synthesis of Compound Ir(La055)₂(Lb005)

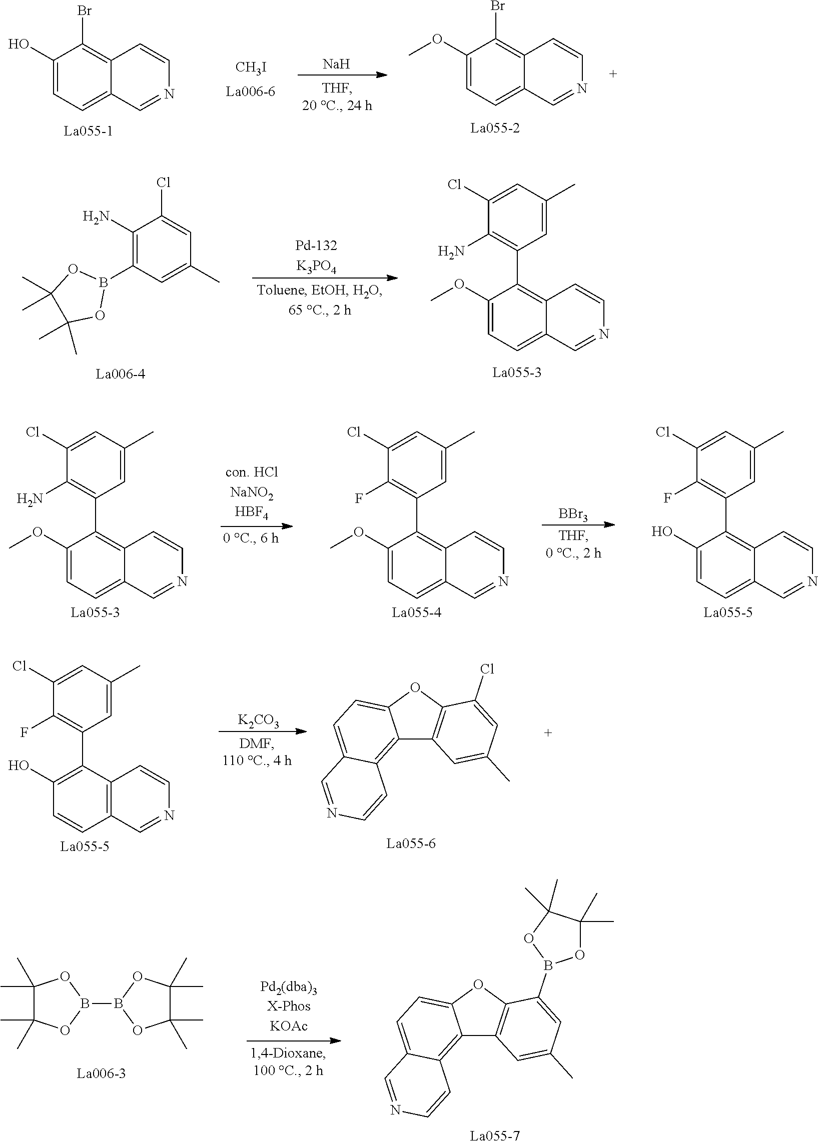

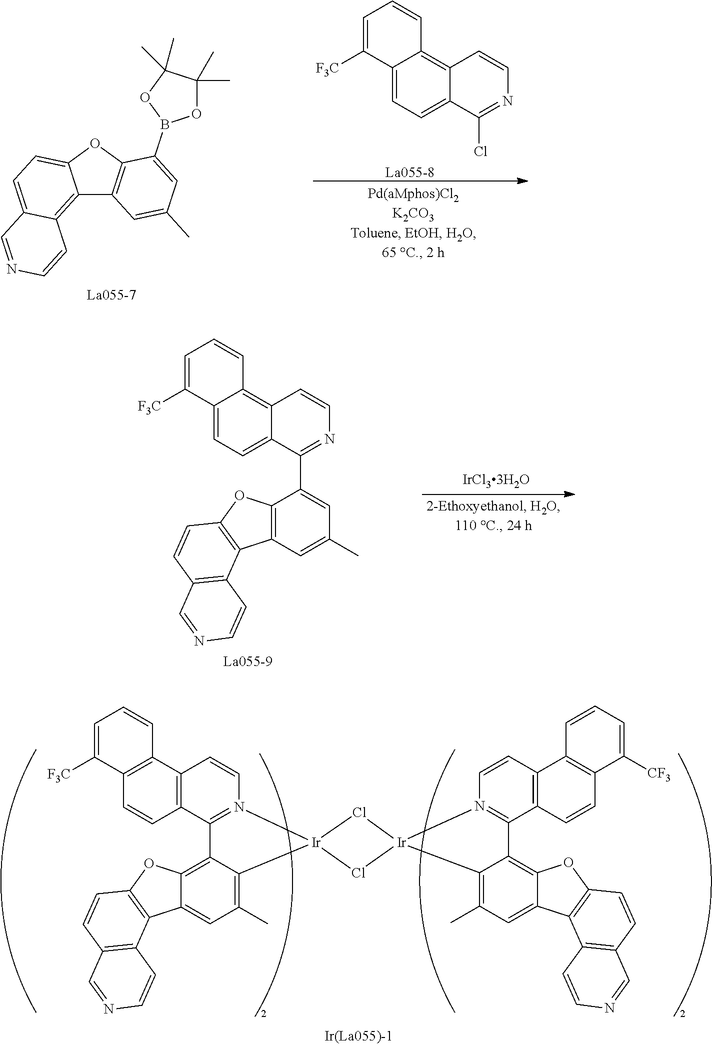

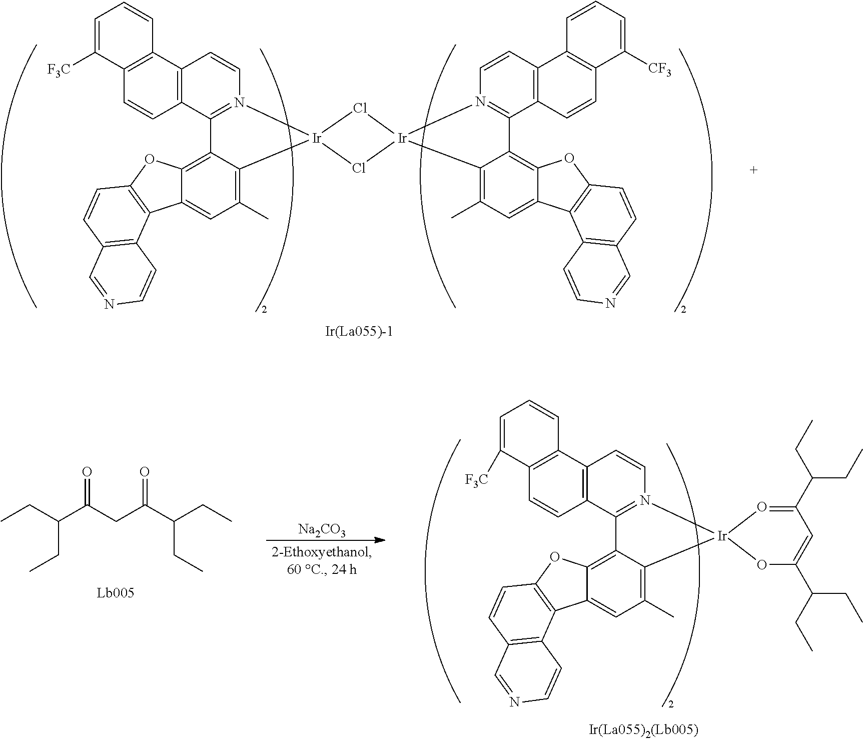

### Synthesis of Compound La055-2

The target compound La055-2 (27.15 g, purity: 99.35%, yield: 63.88%) with a mass spectrum (MS): 237.98 (M+H) was obtained according to the synthesis and purification method for compound La006-7, only the corresponding raw materials were changed.

### Synthesis of Compound La055-3

The target compound La055-3 (23.70, purity: 99.47%, yield: 69.95%) with a mass spectrum (MS): 299.09 (M+H) was obtained according to the synthesis and purification method for compound La006-8, only the corresponding raw materials were changed.

### Synthesis of Compound La055-4

The target compound La055-4 (15.24 g, purity: 99.28%, yield: 64.21%) with a mass spectrum (MS): 302.07 (M+H) was obtained according to the synthesis and purification method for compound La006-9, only the corresponding raw materials were changed.

### Synthesis of Compound La055-5

The target compound La055-5 (10.95 g, purity: 99.39%, yield: 76.56%) with a mass spectrum (MS):

288.05 (M+H) was obtained according to the synthesis and purification method for compound La006-10, only the corresponding raw materials were changed.

### Synthesis of Compound La055-6

The target compound La055-6 (7.72 g, purity: 99.65%, yield: 76.12%) with a mass spectrum (MS): 268.05 (M+H) was obtained according to the synthesis and purification method for compound La006-11, only the corresponding raw materials were changed.

### Synthesis of Compound La055-7

The target compound La055-7 (7.96 g, purity: 99.27%, yield: 79.09%) with a mass spectrum (MS): 360.17 (M+H) was obtained according to the synthesis and purification method for compound La006-4, only the corresponding raw materials were changed.

### Synthesis of Compound La055-9

The target compound La055-9 (7.81 g, purity: 99.32%, yield: 74.22%) with a mass spectrum (MS): 479.13 (M+H) was obtained according to the synthesis and purification method for compound La006-14, only the corresponding raw materials were changed.

### Synthesis of Ir(La055)-1

The target compound Ir(La055)-1 (8.78 g, yield: 66.31%) was obtained according to the synthesis and purification method for compound Ir(La006)-1, only the corresponding raw materials were changed. The target compound Ir(La055)-1 was used directly in the next step without purification.

### Synthesis of Ir(La055)₂(Lb005)

The crude target compound Ir(La055)₂(Lb005) (2.29 g, purity: 99.82%, yield: 46.91%) was obtained according to the synthesis and purification method for compound Ir(La006)₂(Lb005), only the corresponding raw materials were changed. 2.29 g of crude compound Ir(La055)₂(Lb005) was sublimated and purified to obtain sublimated pure compound Ir(La055)₂(Lb005) (1.31 g, purity: 99.77%, yield: 57.20%), with a mass spectrum (MS): 1359.38 (M+H).

¹H NMR (400 MHz, CDCl₃) δ 9.73 (d, J=15.0 Hz, 2H), 9.28-9.22 (m, 2H), 8.98 (dd, J=14.8, 3.1 Hz, 2H), 8.56-8.43 (m, 4H), 8.23 (s, 2H), 8.00-7.86 (m, 4H), 7.66-7.43 (m, 10H), 6.05 (d, J=2.0 Hz, 1H), 3.00 (d, J=1.9 Hz, 1H), 2.62-2.49 (m, 1H), 2.29 (s, 6H), 1.37-1.19 (m, 8H), 0.98-0.89 (m, 12H).

### Synthesis of Compound Ir(La065)₂(Lb005)

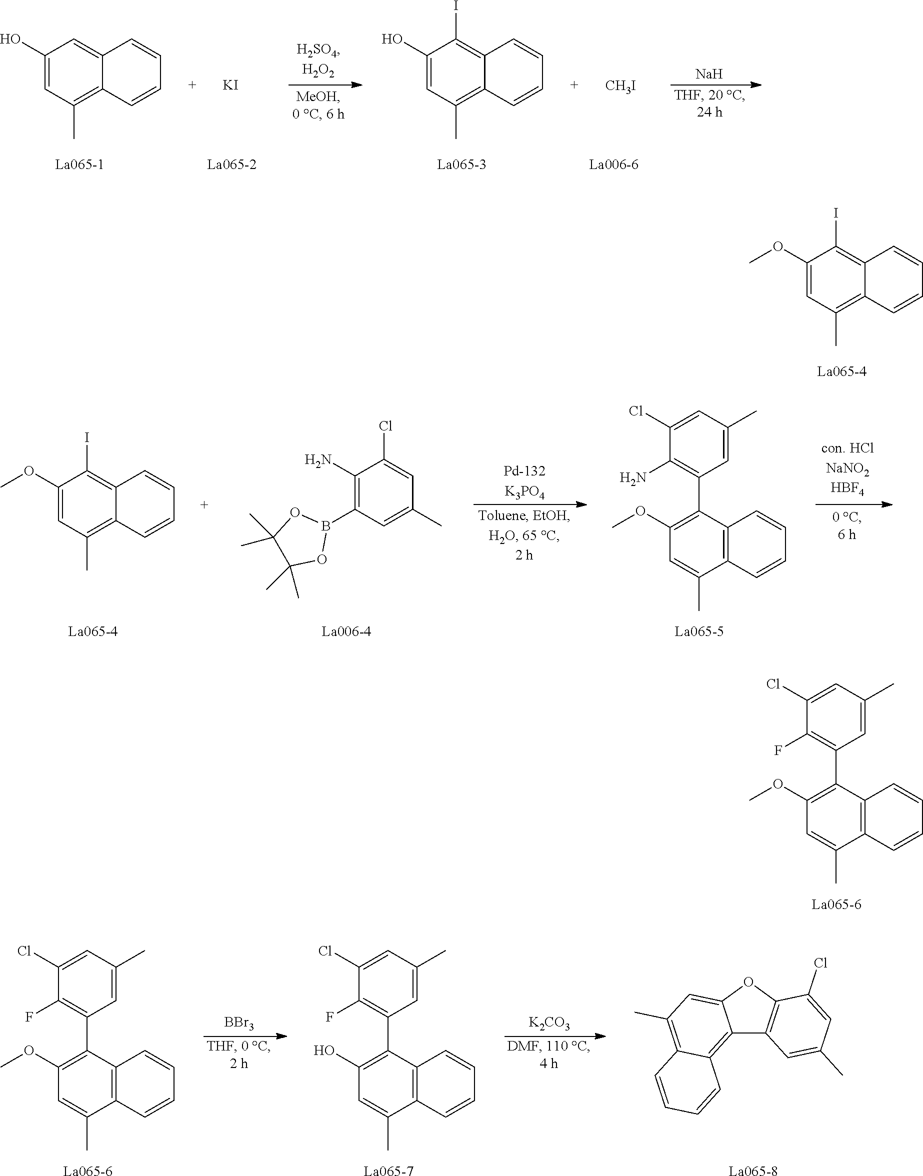

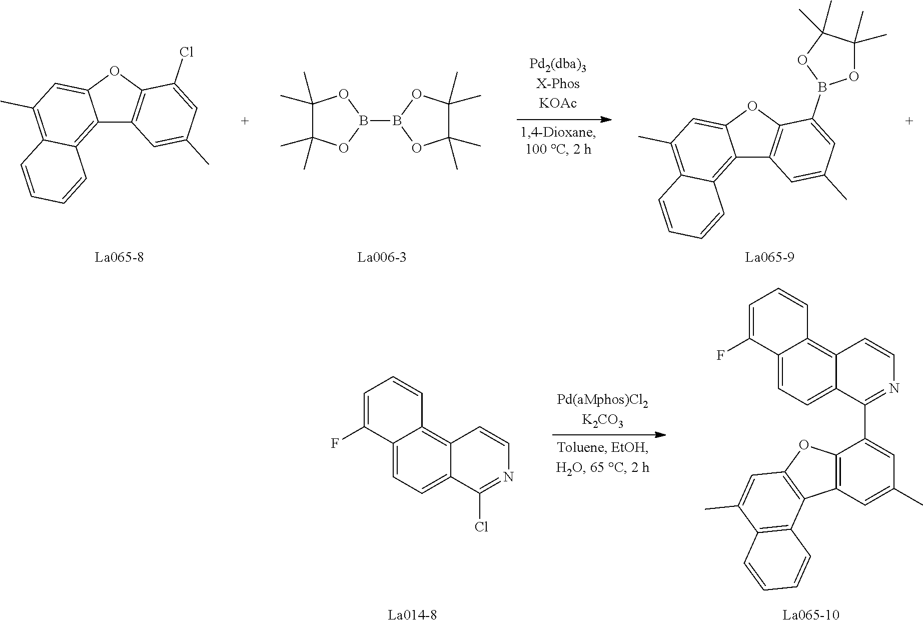

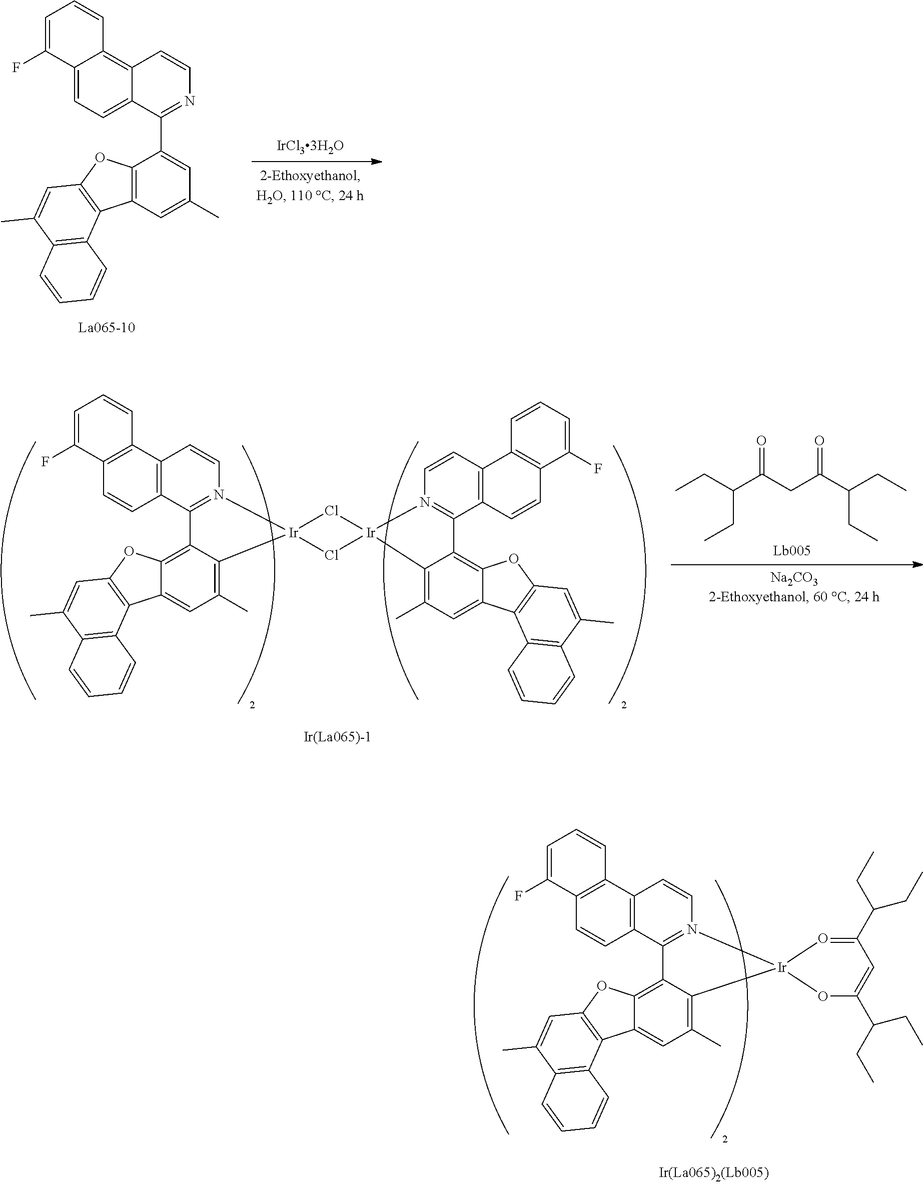

### Synthesis of Compound La065-3

Compounds La065-1 (30.00 g, 189.63 mmol), La065-2 (34.63 g, 208.60 mmol), concentrated sulfuric acid (98%, 15.47 mL), and methanol (500 mL) were added to a 1000 mL three-necked round-bottom flask. The system was cooled to 0° C., and hydrogen peroxide (30%, 28.54 mL) was added dropwise. After the addition was complete, a reaction was performed at this temperature for 6 hours. The reaction was monitored by TLC (ethyl acetate:n-hexane=1:15 as the developing solvent), which showed that the compound La065-1 was consumed completely.

After completion of the reaction, sodium bisulfite aqueous solution was added to adjust the pH to neutral, ethyl acetate (500 mL) was added, and the mixture was extracted and separated. A sediment was loaded onto a silica gel column using a dry packing method, and then purified by silica gel column chromatography (200-300 mesh silica gel, ethyl acetate:n-hexane=1:15 as the eluent). After elution, the product was concentrated under reduced pressure at 70° C. for 1 hour to obtain the target compound La065-3 (34.42 g, purity: 99.28%, yield: 63.89%), with a mass spectrum (MS): 284.97 (M+H).

### Synthesis of Compound La065-4

The target compound La065-4 (25.76 g, purity: 99.42%, yield: 72.20%) with a mass spectrum (MS): 298.99 (M+H) was obtained according to the synthesis and purification method for compound La006-7, only the corresponding raw materials were changed.

### Synthesis of Compound La065-5

The target compound La065-5 (20.34 g, purity: 99.34%, yield: 76.26%) with a mass spectrum (MS): 312.11 (M+H) was obtained according to the synthesis and purification method for compound La006-8, only the corresponding raw materials were changed.

### Synthesis of Compound La065-6

The target compound La065-6 (14.73 g, purity: 99.30%, yield: 72.95%) with a mass spectrum (MS): 315.09 (M+H) was obtained according to the synthesis and purification method for compound La006-9, only the corresponding raw materials were changed.

### Synthesis of Compound La065-7

The target compound La065-7 (10.53 g, purity: 99.27%, yield: 76.01%) with a mass spectrum (MS): 301.07 (M+H) was obtained according to the synthesis and purification method for compound La006-10, only the corresponding raw materials were changed.

### Synthesis of Compound La065-8

The target compound La065-8 (7.34 g, purity: 99.65%, yield: 78.63%) with a mass spectrum (MS): 281.07 (M+H) was obtained according to the synthesis and purification method for compound La006-11, only the corresponding raw materials were changed.

### Synthesis of Compound La065-9

The target compound La065-9 (7.38 g, purity: 99.64%, yield: 79.51%) with a mass spectrum (MS): 373.19 (M+H) was obtained according to the synthesis and purification method for compound La006-4, only the corresponding raw materials were changed.

### Synthesis of Compound La065-10

The target compound La065-10 (6.49 g, purity: 99.52%, yield: 78.18%) with a mass spectrum (MS): 442.15 (M+H) was obtained according to the synthesis and purification method for compound La006-14, only the corresponding raw materials were changed.

### Synthesis of Compound Ir(La065)-1

The target compound Ir(La065)-1 (7.69 g, yield: 68.05%) was obtained according to the synthesis and purification method for compound Ir(La006)-1, only the corresponding raw materials were changed. The target compound Ir(La065)-1 was used directly in the next step without purification.

### Synthesis of Compound Ir(La065)₂(Lb005)

The crude target compound Ir(La065)₂(Lb005) (2.33 g, purity: 99.78%, yield: 54.55%) was obtained according to the synthesis and purification method for compound Ir(La006)₂(Lb005), only the corresponding raw materials were changed. 2.33 g of crude compound Ir(La065)₂(Lb005) was sublimated and purified to obtain sublimated pure compound Ir(La065)₂(Lb005) (1.17 g, purity: 99.70%, yield: 50.21%), with a mass spectrum (MS): 1285.42 (M+H).

¹H NMR (400 MHz, CDCl₃) δ 8.94 (dd, J=14.8, 3.1 Hz, 2H), 8.71 (dd, J=14.9, 3.0 Hz, 2H), 8.45 (d, J=14.8 Hz, 2H), 8.13 (s, 2H), 7.92-7.81 (m, 4H), 7.55 (d, J=15.0 Hz, 2H), 7.50-7.27 (m, 8H), 7.17-7.07 (m, 4H), 5.55 (d, J=1.8 Hz, 1H), 3.62-3.53 (m, 1H), 2.96 (s, 7H), 2.28 (s, 6H), 1.34-1.19 (m, 8H), 0.97-0.91 (m, 12H).

### Synthesis of Compound Ir(La071)₂(Lb043)

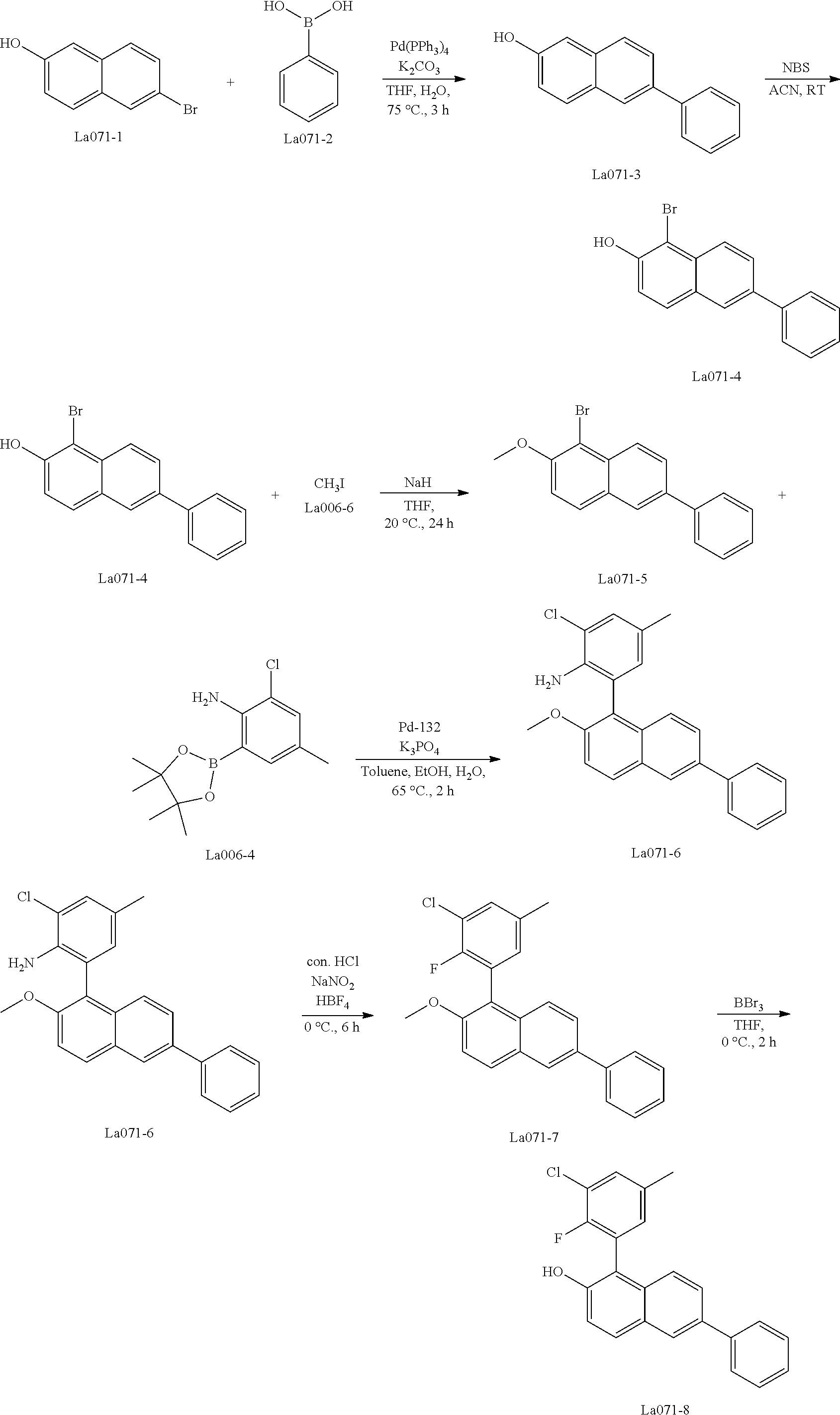

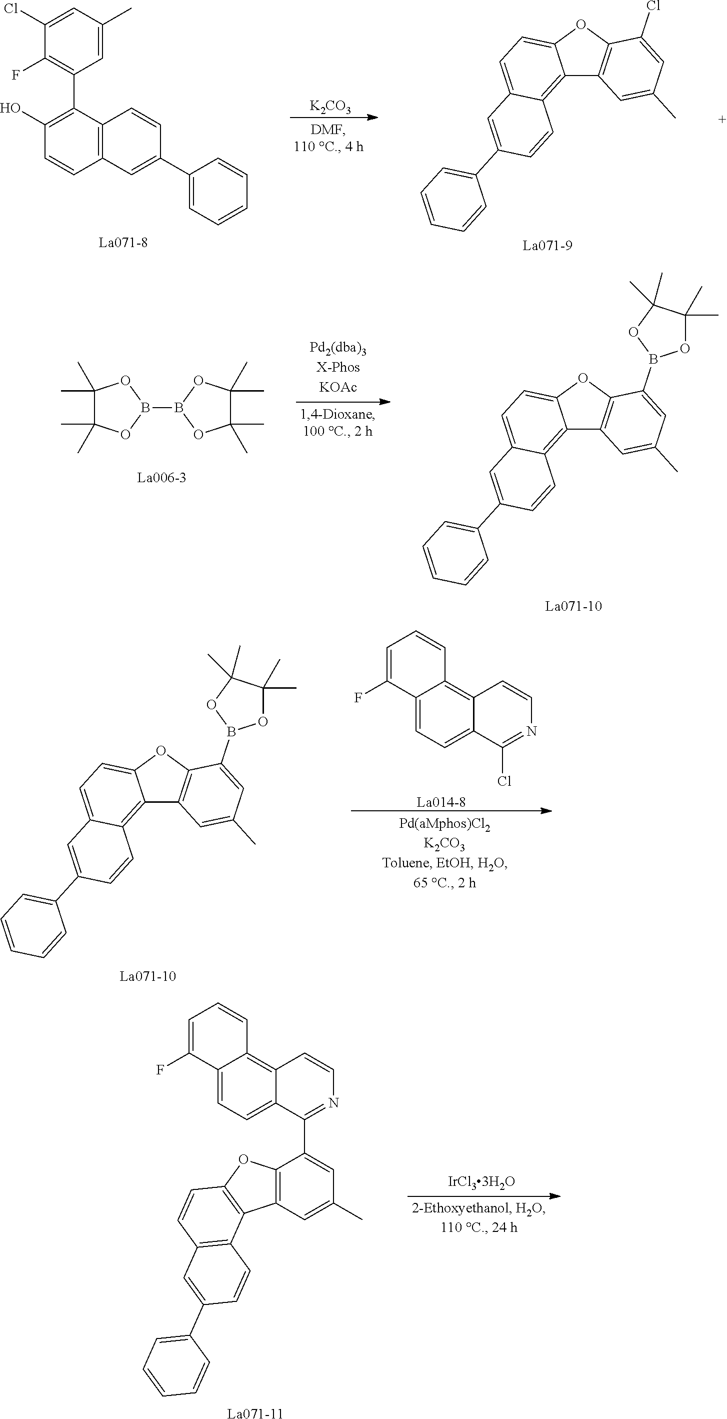

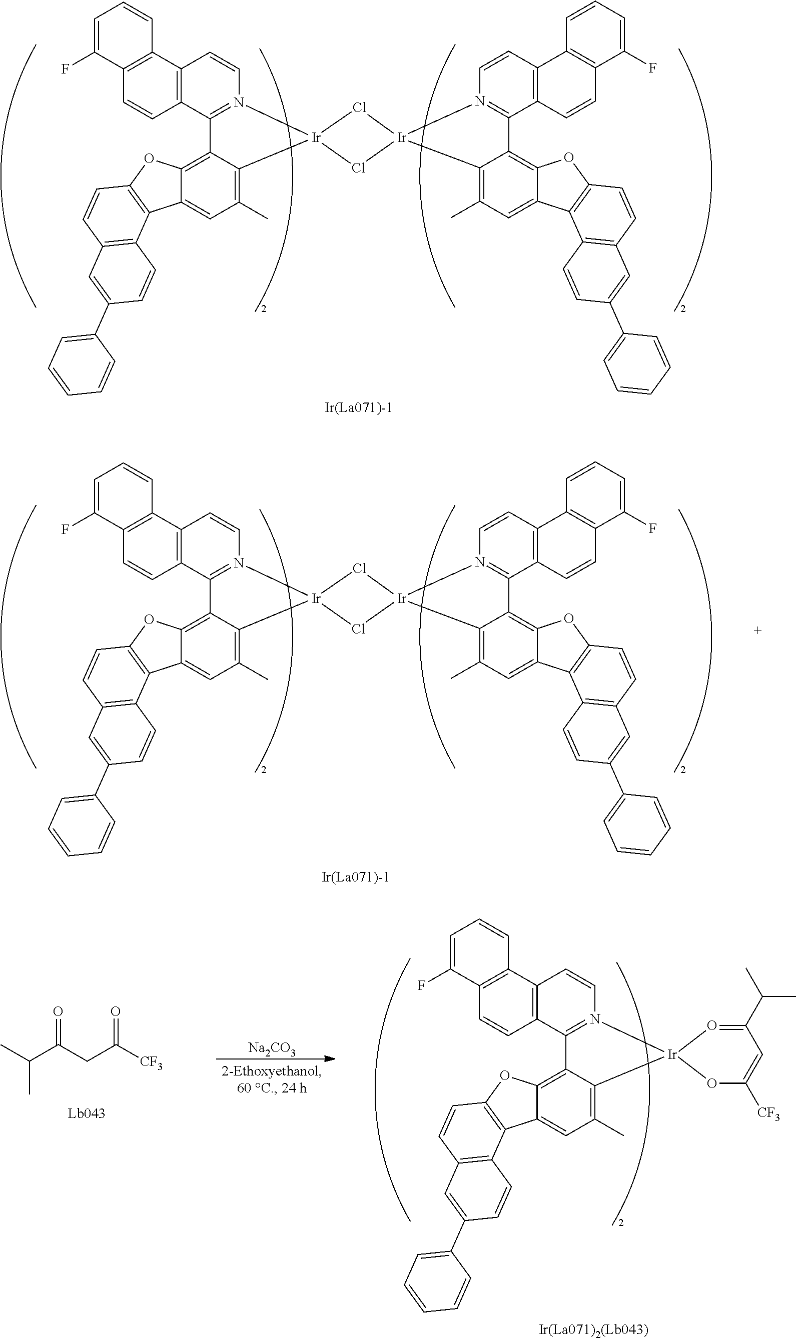

### Synthesis of Compound La071-3

The target compound La071-3 (22.19 g, purity: 99.28%, yield: 74.91%) with a mass spectrum (MS): 221.09 (M+H) was obtained according to the synthesis and purification method for compound La006-8, only the corresponding raw materials were changed; La006-7 was replaced with La071-1 and La006-4 was replaced with La071-2; such that bromine was reacted with boric acid.

### Synthesis of Compound La071-4

The target compound La071-4 (20.37 g, purity: 99.41%, yield: 68.17%) with a mass spectrum (MS): 299.00 (M+H) was obtained according to the synthesis and purification method for compound La006-2, only the corresponding raw materials were changed.

### Synthesis of Compound La071-5

The target compound La071-5 (15.52 g, purity: 99.62%, yield: 74.12%) with a mass spectrum (MS): 313.01 (M+H) was obtained according to the synthesis and purification method for compound La006-7, only the corresponding raw materials were changed.

### Synthesis of Compound La071-6

The target compound La071-6 (13.86 g, purity: 99.26%, yield: 77.40%) with a mass spectrum (MS): 374.12 (M+H) was obtained according to the synthesis and purification method for compound La006-8, only the corresponding raw materials were changed.

### Synthesis of Compound La071-7

The target compound La071-7 (8.85 g, purity: 99.13%, yield: 65.04%) with a mass spectrum (MS): 377.10 (M+H) was obtained according to the synthesis and purification method for compound La006-9, only the corresponding raw materials were changed.

### Synthesis of Compound La071-8

The target compound La071-8 (6.02 g, purity: 99.55%, yield: 73.56%) with a mass spectrum (MS):

363.09 (M+H) was obtained according to the synthesis and purification method for compound La006-10, only the corresponding raw materials were changed.

### Synthesis of Compound La071-9

The target compound La071-9 (4.15 g, purity: 99.46%, yield: 73.20%) with a mass spectrum (MS): 343.08 (M+H) was obtained according to the synthesis and purification method for compound La006-11, only the corresponding raw materials were changed.

### Synthesis of Compound La071-10

The target compound La071-10 (3.96 g, purity: 99.17%, yield: 78.14%) with a mass spectrum (MS): 435.21 (M+H) was obtained according to the synthesis and purification method for compound La006-4, only the corresponding raw materials were changed.

### Synthesis of Compound La071-11

The target compound La071-11 (3.51 g, purity: 99.39%, yield: 77.63%) with a mass spectrum (MS): 504.17 (M+H) was obtained according to the synthesis and purification method for compound La006-14, only the corresponding raw materials were changed.

### Synthesis of Compound Ir(La071)-1

The target compound Ir(La071)-1 (4.58 g, yield: 74.83%) was obtained according to the synthesis and purification method for compound Ir(La006)-1, only the corresponding raw materials were changed. The target compound Ir(La071)-1 was used directly in the next step without purification.

### Synthesis of Compound Ir(La071)₂(Lb043)

The crude target compound Ir(La071)₂(Lb043) (1.36 g, purity: 99.77%, yield: 54.06%) was obtained according to the synthesis and purification method for compound Ir(La006)₂(Lb005), only the corresponding raw materials were changed. 1.36 g of crude compound Ir(La071)₂(Lb043) was sublimated and purified to obtain sublimated pure compound Ir(La071)₂(Lb043) (0.88 g, purity: 99.78%, yield: 64.70%), with a mass spectrum (MS): 1379.33 (M+H).

¹H NMR (400 MHz, CDCl₃) δ 8.74 (dd, J=14.9, 3.0 Hz, 2H), 8.48 (d, J=15.0 Hz, 2H), 8.04 (d, J=15.0 Hz, 2H), 7.92 (d, J=15.0 Hz, 2H), 7.79-7.72 (m, 6H), 7.59-7.46 (m, 12H), 7.44-7.34 (m, 6H), 7.29 (dd, J=15.0, 2.9 Hz, 2H), 7.17-7.09 (m, 2H), 6.46 (s, 1H), 3.23-3.09 (m, 1H), 2.29 (s, 6H), 1.06 (d, J=12.8 Hz, 6H).

### Synthesis of Compound Ir(La082)₂(Lb005)

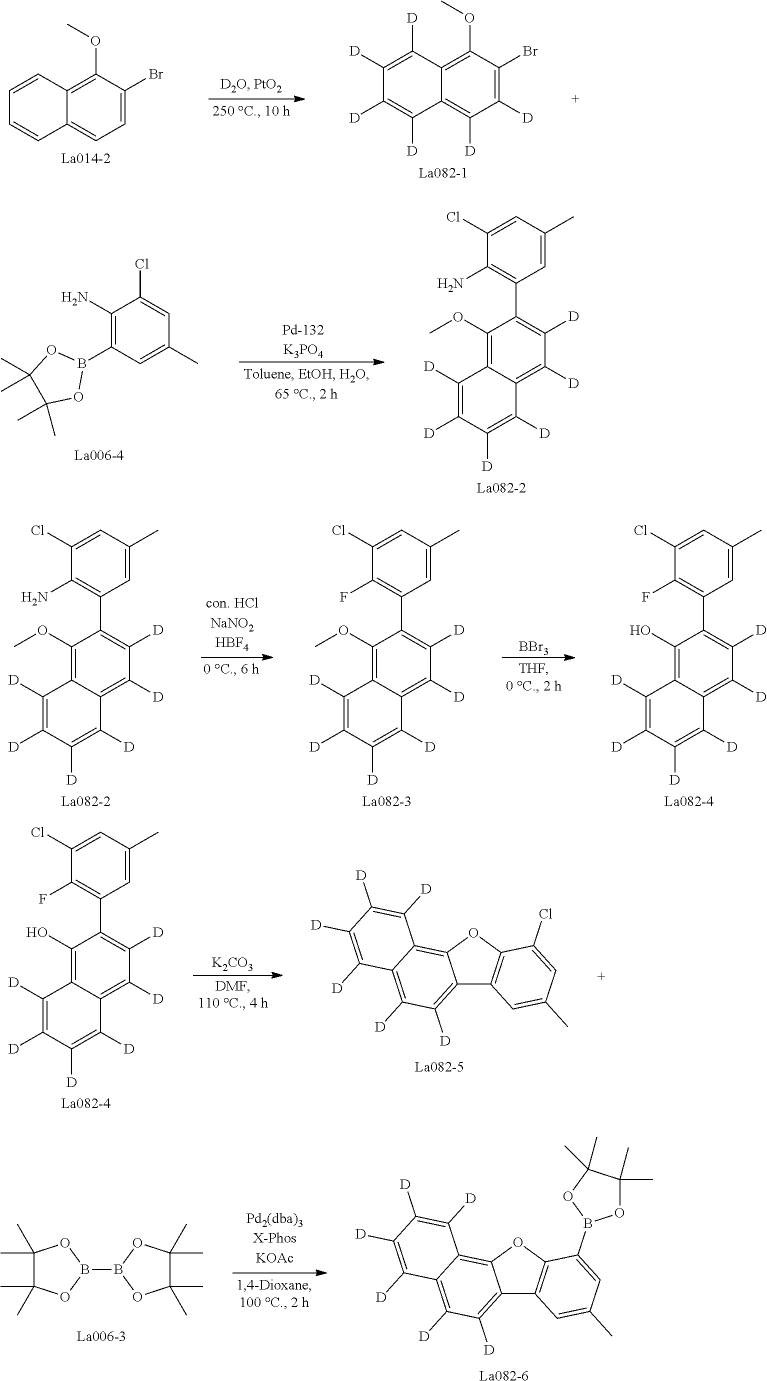

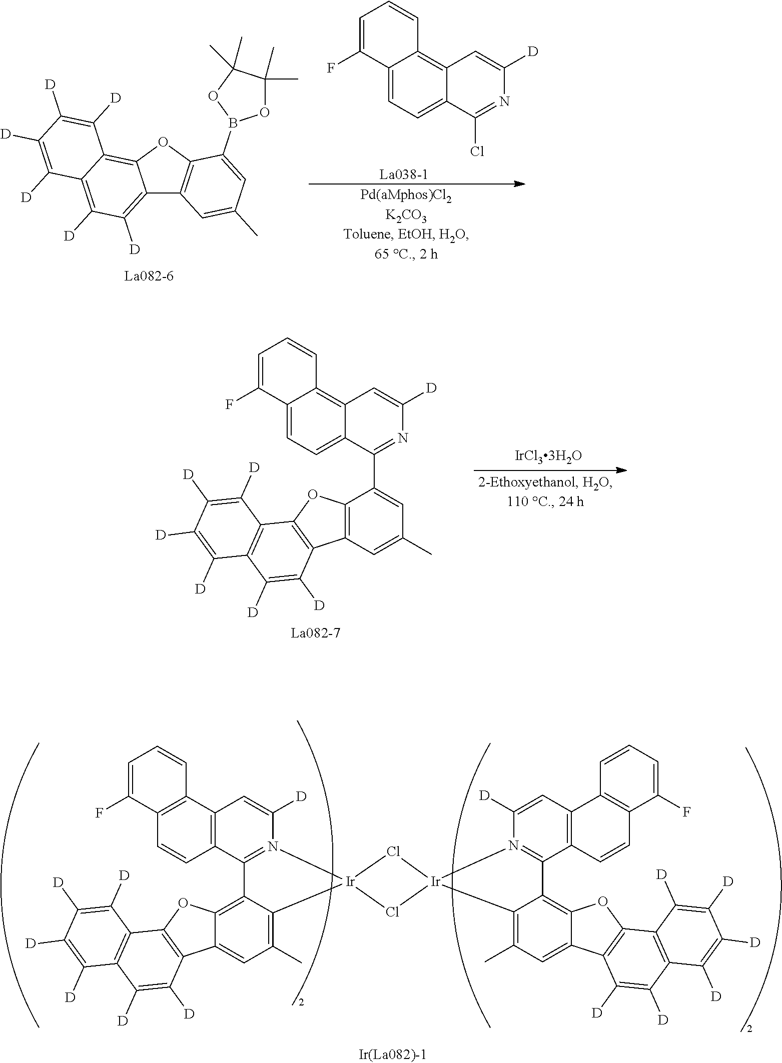

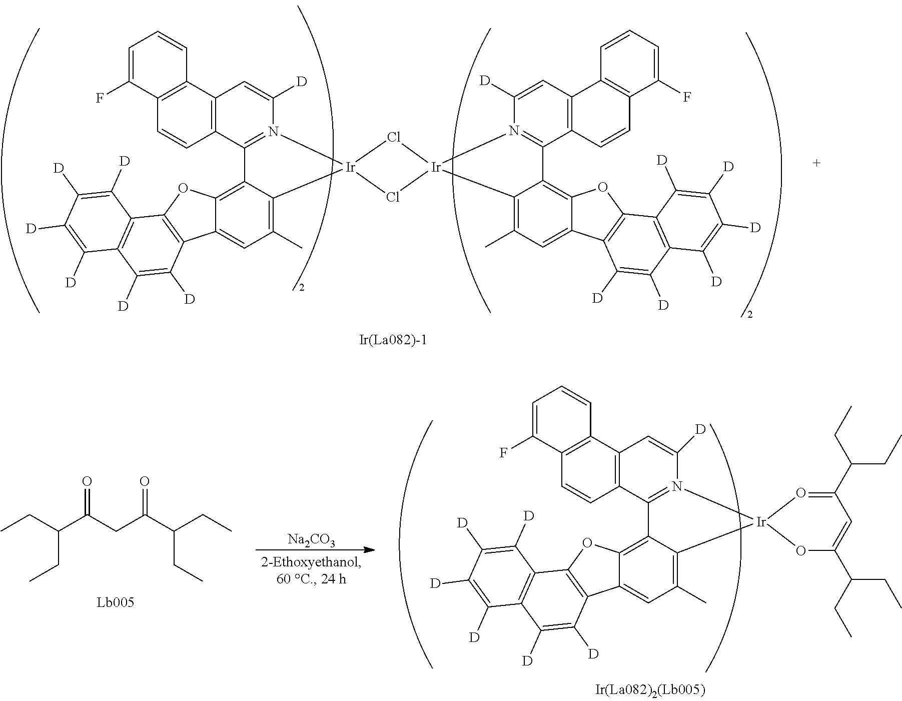

### Synthesis of Compound La082-1

Compound La014-2 (40.00 g, 168.71 mmol), platinum dioxide (3.83 g, 16.87 mmol), and heavy water (500 mL) were added to a 1000 mL pressure-resistant reactor. The mixture was evacuated and displaced with argon for three times, then heated to 250° C., and reacted for 20 hours.

After the reaction mixture was cooled to room temperature, dichloromethane (300 mL) was added, and the mixture was washed three times with deionized water (100 mL×3). After liquid separation, a sediment was loaded onto a silica gel column using a dry packing method, and then purified by silica gel column chromatography (200-300 mesh silica gel, hexane:ethyl acetate=15:1 as the eluent). After elution, the product was concentrated under reduced pressure at 60° C. for 1 hour to obtain the target compound La082-1 (30.07 g, purity: 99.47%, yield: 73.31%), with a mass spectrum (MS): 243.02 (M+H).

### Synthesis of Compound La082-2

The target compound La082-2 (25.42 g, purity: 99.54%, yield: 70.15%) with a mass spectrum (MS): 304.13 (M+H) was obtained according to the synthesis and purification method for compound La006-8, only the corresponding raw materials were changed.

### Synthesis of Compound La082-3

The target compound La082-3 (18.93 g, purity: 99.36%, yield: 74.99%) with a mass spectrum (MS): 307.11 (M+H) was obtained according to the synthesis and purification method for compound La006-9, only the corresponding raw materials were changed.

### Synthesis of Compound La082-4

The target compound La082-4 (12.36 g, purity: 99.28%, yield: 70.01%) with a mass spectrum (MS): 293.09 (M+H) was obtained according to the synthesis and purification method for compound La006-10, only the corresponding raw materials were changed.

### Synthesis of Compound La082-5

The target compound La082-5 (8.39 g, purity: 99.43%, yield: 75.04%) with a mass spectrum (MS): 273.09 (M+H) was obtained according to the synthesis and purification method for compound La006-11, only the corresponding raw materials were changed.

### Synthesis of Compound La082-6

The target compound La082-6 (8.23 g, purity: 99.47%, yield: 77.97%) with a mass spectrum (MS): 365.21 (M+H) was obtained according to the synthesis and purification method for compound La006-4, only the corresponding raw materials were changed.

### Synthesis of Compound La082-7

The target compound La082-7 (6.39 g, purity: 99.78%, yield: 66.96%) with a mass spectrum (MS): 435.18 (M+H) was obtained according to the synthesis and purification method for compound La006-14, only the corresponding raw materials were changed.

### Synthesis of Compound Ir(La082)-1

The target compound Ir(La082)-1 (7.56 g, yield: 70.02%) was obtained according to the synthesis and purification method for compound Ir(La006)-1, only the corresponding raw materials were changed. The target compound Ir(La082)-1 was used directly in the next step without purification.

### Synthesis of Compound Ir(La082)₂(Lb005)

The crude target compound Ir(La082)₂(Lb005) (1.94 g, purity: 99.75%, yield: 47.76%) was obtained according to the synthesis and purification method for compound Ir(La006)₂(Lb005), only the corresponding raw materials were changed. 1.94 g of crude compound Ir(La082)₂(Lb005) was sublimated and purified to obtain sublimated pure compound Ir(La082)₂(Lb005) (1.16 g, purity: 99.69%, yield: 59.79%), with a mass spectrum (MS): 1271.48 (M+H).

¹H NMR (400 MHz, CDCl₃) δ 8.74 (dd, J=14.9, 3.0 Hz, 2H), 8.63 (s, 2H), 7.95-7.89 (m, 4H), 7.50 (dd, J=15.0, 9.9 Hz, 2H), 7.43-7.33 (m, 2H), 7.17-7.09 (m, 2H), 5.64 (d, J=2.0 Hz, 1H), 3.36-3.26 (m, 1H), 2.51-2.42 (m, 1H), 2.29 (s, 6H), 1.35-1.19 (m, 8H), 0.97-0.91 (m, 12H).

### Synthesis of Compound Ir(La092)₂(Lb031)

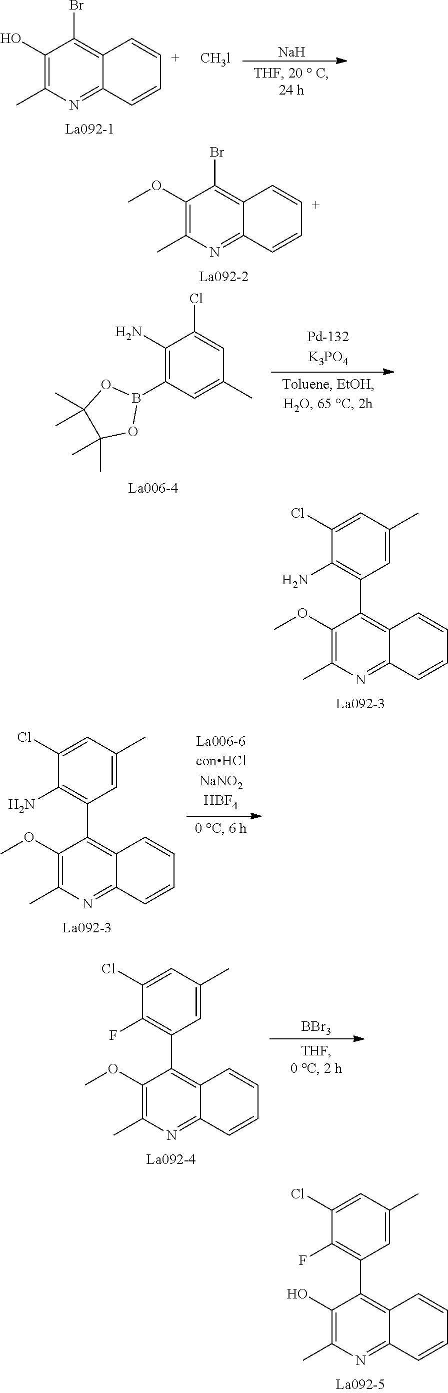

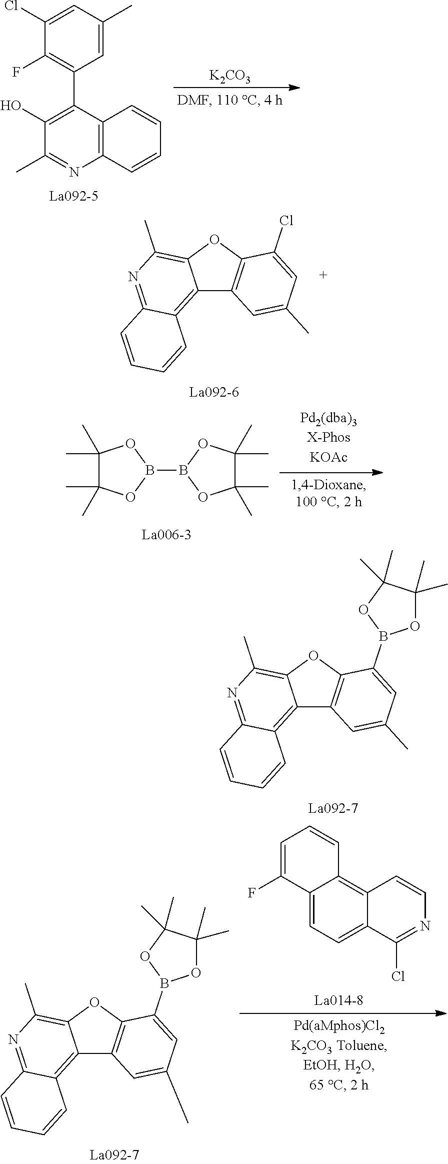

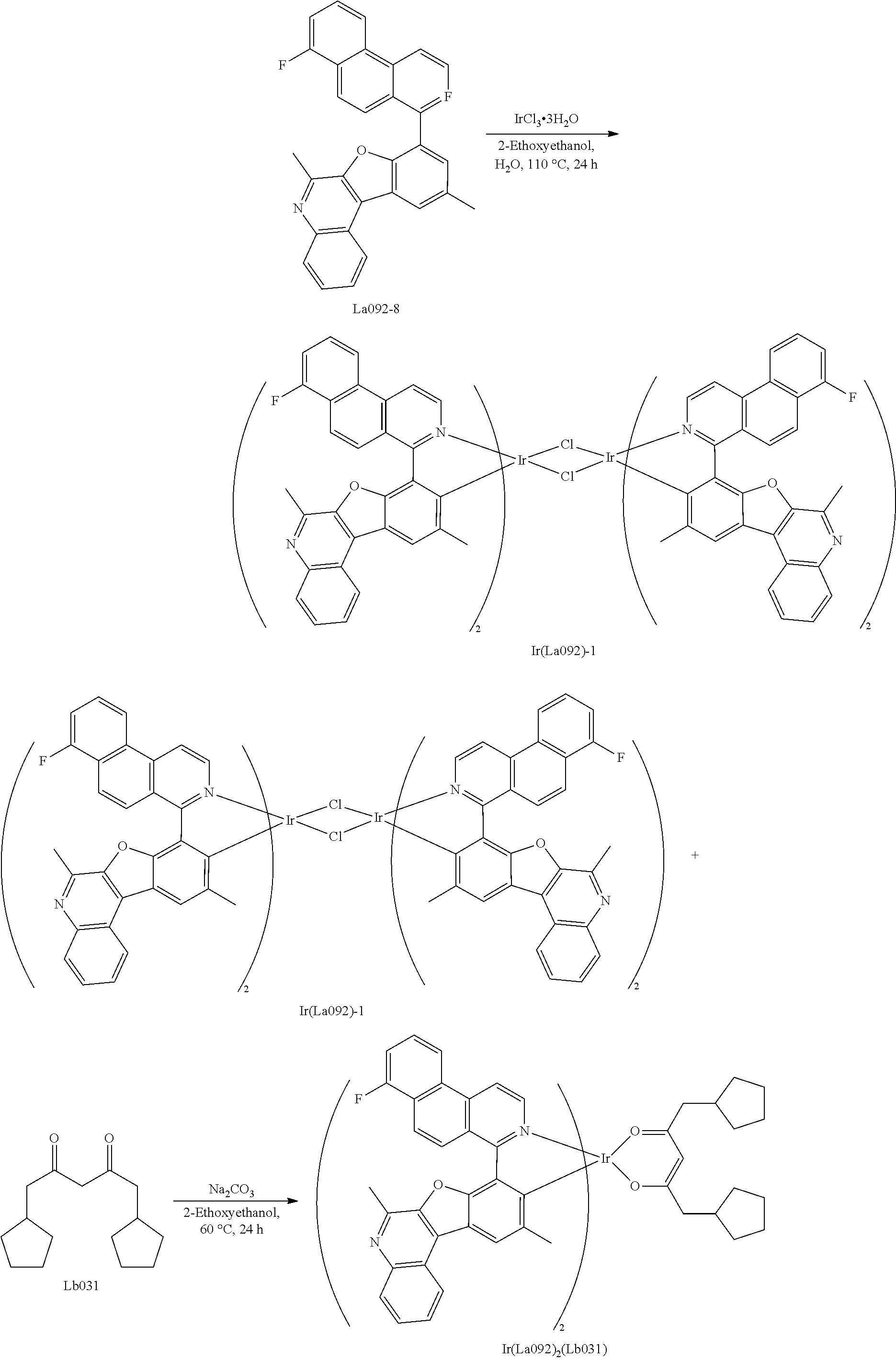

### Synthesis of Compound La092-2

The target compound La092-2 (27.96 g, purity: 99.23%, yield: 66.01%) with a mass spectrum (MS): 251.99 (M+H) was obtained according to the synthesis and purification method for compound La006-7, only the corresponding raw materials were changed.

### Synthesis of Compound La092-3

The target compound La092-3 (24.18 g, purity: 99.26%, yield: 72.18%) with a mass spectrum (MS): 313.10 (M+H) was obtained according to the synthesis and purification method for compound La006-8, only the corresponding raw materials were changed.

### Synthesis of Compound La092-4

The target compound La092-4 (18.42 g, purity: 99.19%, yield: 76.03%) with a mass spectrum (MS): 316.08 (M+H) was obtained according to the synthesis and purification method for compound La006-9, only the corresponding raw materials were changed.

### Synthesis of Compound La092-5

The target compound La092-5 (12.17 g, purity: 99.40%, yield: 70.75%) with a mass spectrum (MS): 302.07 (M+H) was obtained according to the synthesis and purification method for compound La006-10, only the corresponding raw materials were changed.

### Synthesis of Compound La092-6

The target compound La092-6 (8.05 g, purity: 99.61%, yield: 71.85%) with a mass spectrum (MS): 282.06 (M+H) was obtained according to the synthesis and purification method for compound La006-11, only the corresponding raw materials were changed.

### Synthesis of Compound La092-7

The target compound La092-7 (7.94 g, purity: 99.24%, yield: 74.91%) with a mass spectrum (MS): 374.18 (M+H) was obtained according to the synthesis and purification method for compound La006-4, only the corresponding raw materials were changed.

### Synthesis of Compound La092-8

The target compound La092-8 (6.41 g, purity: 99.59%, yield: 72.09%) with a mass spectrum (MS): 443.15 (M+H) was obtained according to the synthesis and purification method for compound La006-14, only the corresponding raw materials were changed.

### Synthesis of Compound Ir(La092)-1

The target compound Ir(La092)-1 (7.31 g, yield: 67.95%) was obtained according to the synthesis and purification method for compound Ir(La006)-1, only the corresponding raw materials were changed. The target compound Ir(La092)-1 was used directly in the next step without purification.

### Synthesis of Compound Ir(La092)₂(Lb031)

The crude target compound Ir(La092)₂(Lb031) (2.11 g, purity: 99.85%, yield: 51.09%) was obtained according to the synthesis and purification method for compound Ir(La006)₂(Lb005), only the corresponding raw materials were changed. 2.11 g of crude compound Ir(La092)₂(Lb031) was sublimated and purified to obtain sublimated pure compound Ir(La092)₂(Lb031) (1.24 g, purity: 99.80%, yield: 58.76%), with a mass spectrum (MS): 1311.41 (M+H).

¹H NMR (400 MHz, CDCl₃) δ 8.74 (dd, J=14.9, 3.0 Hz, 2H), 8.48 (d, J=15.0 Hz, 2H), 8.18 (s, 2H), 8.07 (dd, J=14.8, 3.1 Hz, 2H), 7.92 (d, J=15.0 Hz, 2H), 7.71 (dd, J=14.8, 3.2 Hz, 2H), 7.67-7.54 (m, 4H), 7.54-7.34 (m, 6H), 7.17-7.09 (m, 2H), 5.46 (t, J=2.0 Hz, 1H), 3.03 (d, J=13.5 Hz, 2H), 2.68 (s, 6H), 2.29 (s, 6H), 2.04 (dd, J=14.7, 2.0 Hz, 2H), 1.95-1.59 (m, 16H), 1.47-1.08 (m, 2H).

### Synthesis of Compound Ir(La098)₂(Lb005)

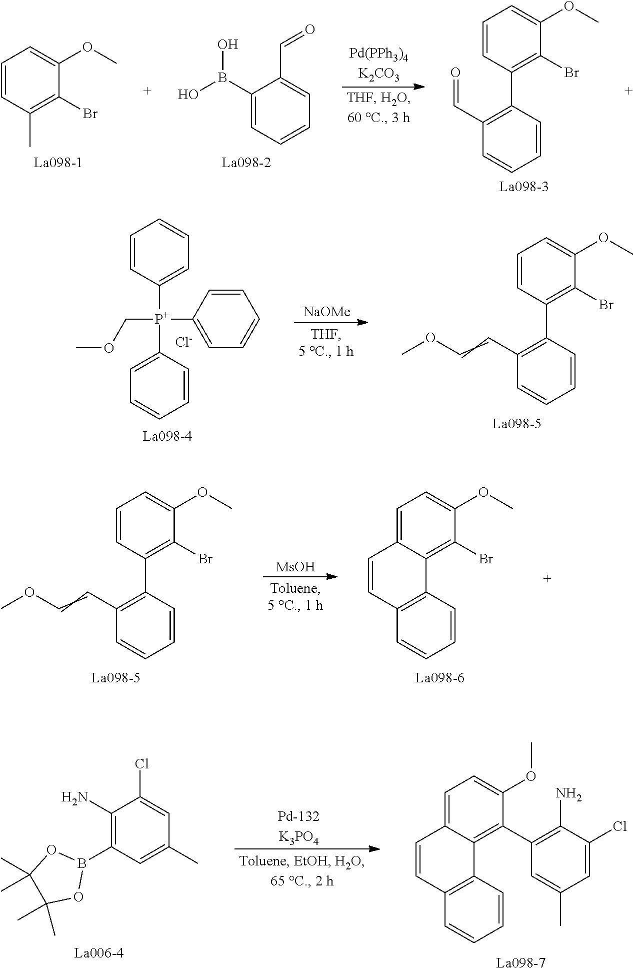

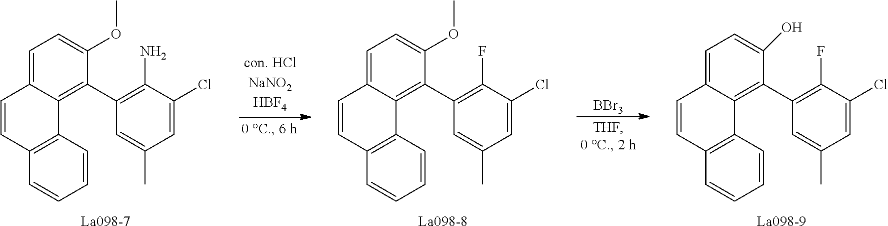

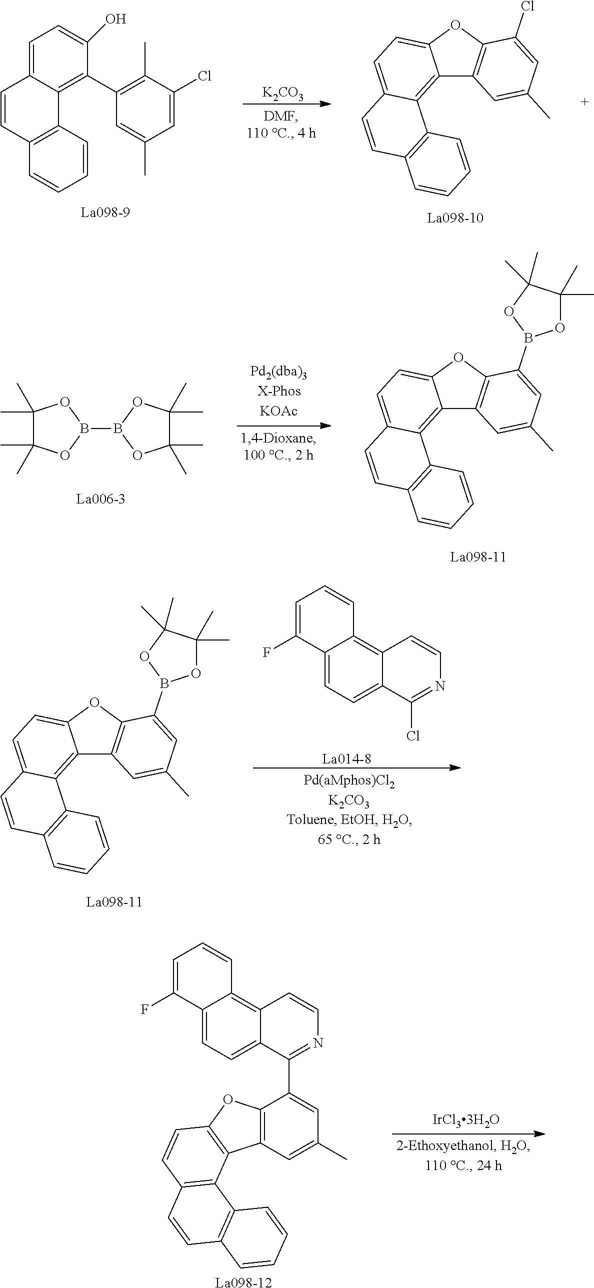

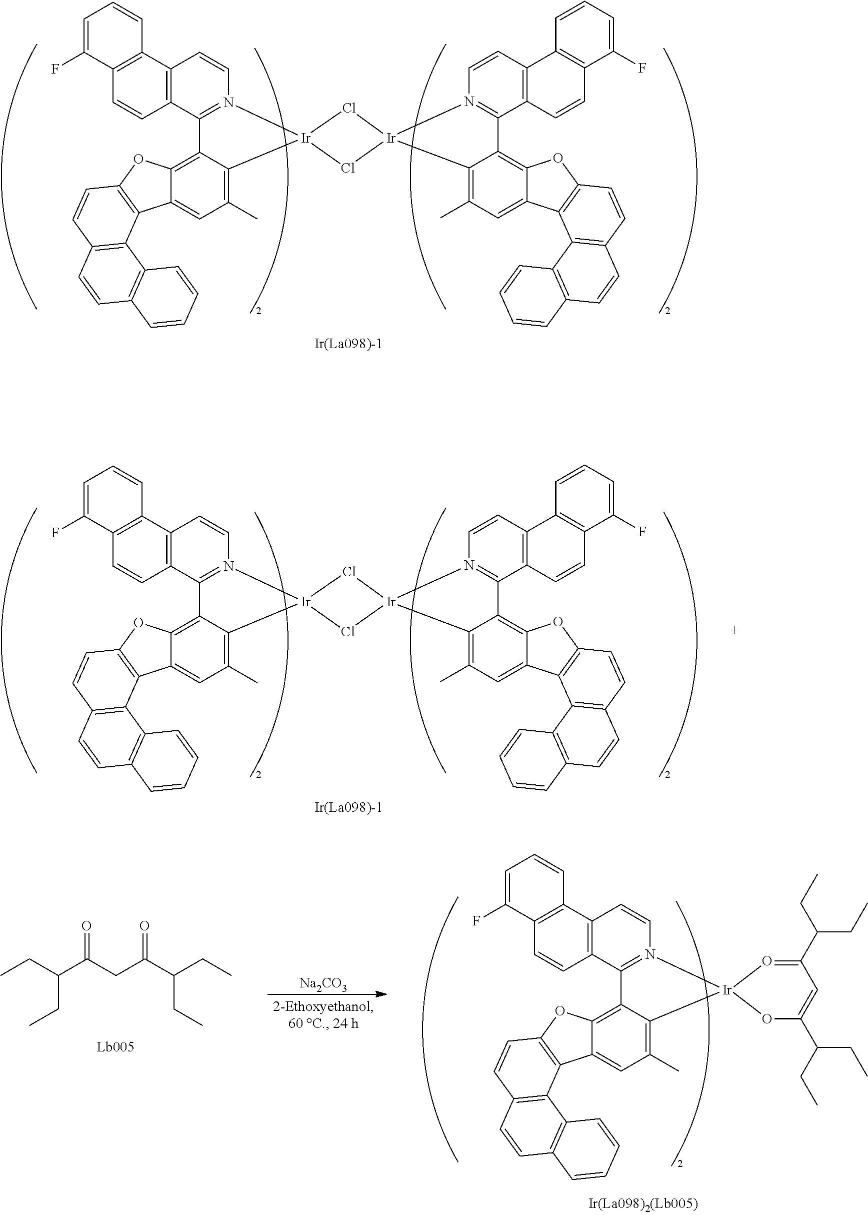

### Synthesis of Compound La098-3

The target compound La098-3 (27.16 g, purity: 99.62%, yield: 72.98%) with a mass spectrum (MS): 290.99 (M+H) was obtained according to the synthesis and purification method for compound La006-8, only the corresponding raw materials were changed.

### Synthesis of Compound La098-5

Compound La098-3 (27.00 g, 92.74 mmol), compound La098-4 (47.69 g, 139.11 mmol), and tetrahydrofuran (540 ml) were added to a 1000 ml three-necked round-bottom flask. The mixture was evacuated, and displaced with nitrogen for three times. The system was then cooled to 5° C., and sodium methoxide (10.02 g, 185.48 mmol) was added in a single batch. A reaction was performed at 5° C. for 1 hour. The reaction was monitored by TLC (ethyl acetate:n-hexane=1:10 as the developing solvent), which showed that the compound La098-3 was consumed completely.

Deionized water (500 mL) was added to the reaction mixture, and the solvent was removed by concentration under reduced pressure. Ethyl acetate (500 mL) was added for extraction. After liquid separation, a sediment was concentrated under reduced pressure at 70° C. for 1 hour to obtain a white solid, which was the compound La098-5 (26.38 g, yield: 89.12%), with a mass spectrum (MS): 319.03 (M+H). The obtained compound was used directly in the next step without purification.

### Synthesis of Compound La098-6

Compound La098-5 (26.00 g, 81.45 mmol) and toluene (260 mL) were added to a 500 mL three-necked round-bottom flask. The mixture was evacuated and displaced with nitrogen for three times. The system was then cooled to 5° C., and methanesulfonic acid (MsOH, 15.66 g, 162.91 mmol) was slowly added dropwise for 10 minutes. A reaction was performed at 5° C. for 1 hour. The reaction was monitored by TLC (ethyl acetate:n-hexane=1:15 as the developing solvent), which showed that the compound La098-5 was consumed completely.

Methanol (200 mL) was added to the reaction mixture, and a large amount of white solid precipitated. The solid (18 g) was collected by suction filtration, crystallized once using toluene (210 mL) and methanol (140 mL), suction-filtered, and the filter cake was vacuum dried at 80° C. for 1 hour to obtain a white solid, which was the compound La098-6 (16.58 g, purity: 99.43%, yield: 70.88%), with a mass spectrum (MS): 287.00 (M+H).

### Synthesis of Compound La098-7

The target compound La098-7 (14.36 g, purity: 99.35%, yield: 74.09%) with a mass spectrum (MS): 348.11 (M+H) was obtained according to the synthesis and purification method for compound La006-8, only the corresponding raw materials were changed.

### Synthesis of Compound La098-8

The target compound La098-8 (10.25 g, purity: 99.33%, yield: 72.59%) with a mass spectrum (MS): 351.09 (M+H) was obtained according to the synthesis and purification method for compound La006-9, only the corresponding raw materials were changed.

### Synthesis of Compound La098-9

The target compound La098-9 (7.40 g, purity: 99.27%, yield: 77.08%) with a mass spectrum (MS): 337.07 (M+H) was obtained according to the synthesis and purification method for compound La006-10, only the corresponding raw materials were changed.

### Synthesis of Compound La098-10

The target compound La098-10 (5.17 g, purity: 99.53%, yield: 78.52%) with a mass spectrum (MS): 317.07 (M+H) was obtained according to the synthesis and purification method for compound La006-11, only the corresponding raw materials were changed.

### Synthesis of Compound La098-11

The target compound La098-11 (5.20 g, purity: 99.38%, yield: 80.69%) with a mass spectrum (MS): 409.19 (M+H) was obtained according to the synthesis and purification method for compound La006-4, only the corresponding raw materials were changed.

### Synthesis of Compound La098-12

The target compound La098-12 (4.42 g, purity: 99.60%, yield: 75.58%) with a mass spectrum (MS): 478.15 (M+H) was obtained according to the synthesis and purification method for compound La006-14, only the corresponding raw materials were changed.

### Synthesis of Compound Ir(La098)-1

The target compound Ir(La098)-1 (5.45 g, yield: 73.47%) was obtained according to the synthesis and purification method for compound Ir(La006)-1, only the corresponding raw materials were changed. The target compound Ir(La098)-1 was used directly in the next step without purification.

### Synthesis of Compound Ir(La098)₂(Lb005)

The crude target compound Ir(La098)₂(Lb005) (1.59 g, purity: 99.78%, yield: 55.35%) was obtained according to the synthesis and purification method for compound Ir(La006)₂(Lb005), only the corresponding raw materials were changed. 1.59 g of crude compound Ir(La098)₂(Lb005) was sublimated and purified to obtain sublimated pure compound Ir(La098)₂(Lb005) (0.96 g, purity: 99.77%, yield: 60.37%), with a mass spectrum (MS): 1357.42 (M+H).

¹H NMR (400 MHz, CDCl₃) δ 9.02-8.95 (m, 2H), 8.74 (dd, J=14.9, 3.0 Hz, 2H), 8.65-8.58 (m, 2H), 8.48 (d, J=15.0 Hz, 2H), 8.24 (s, 2H), 8.14-8.05 (m, 4H), 7.95-7.86 (m, 4H), 7.78-7.72 (m, 2H), 7.72-7.60 (m, 4H), 7.57 (d, J=15.0 Hz, 2H), 7.50 (dd, J=15.0, 9.9 Hz, 2H), 7.43-7.33 (m, 2H), 7.17-7.08 (m, 2H), 6.84 (d, J=2.0 Hz, 1H), 2.45-2.32 (m, 1H), 2.29 (s, 6H), 1.64-1.56 (m, 1H), 1.35-1.18 (m, 8H), 0.98-0.91 (m, 12H).

### Synthesis of Compound Ir(La0105)₂(Lb017)

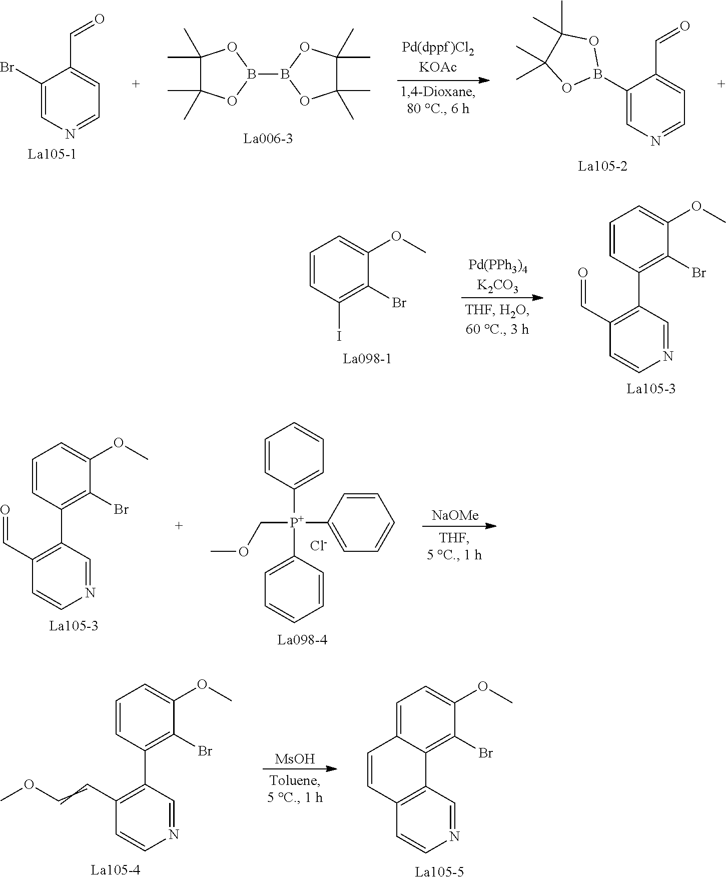

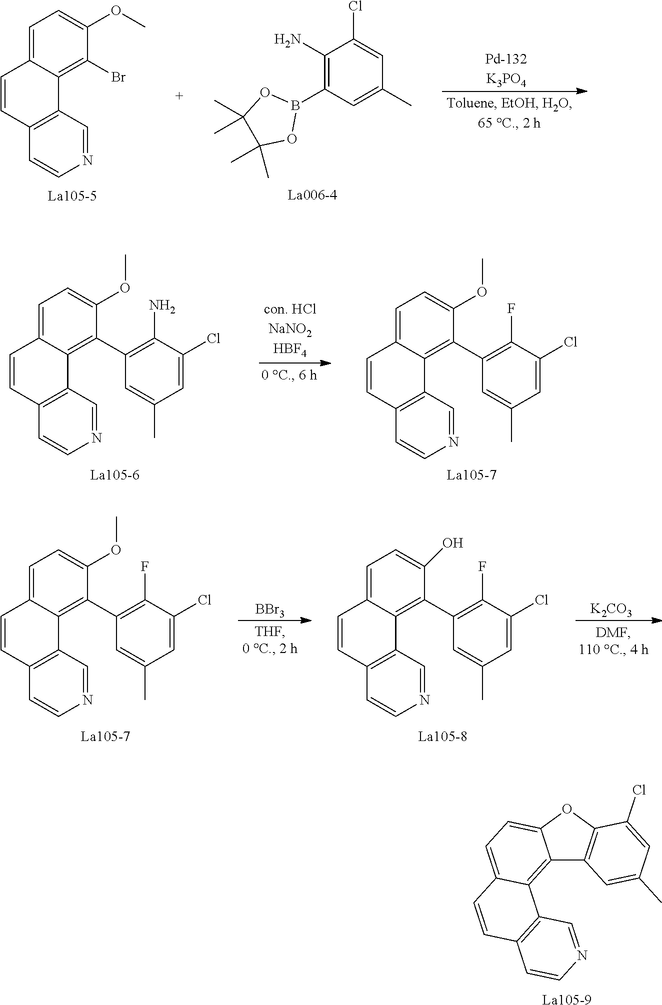

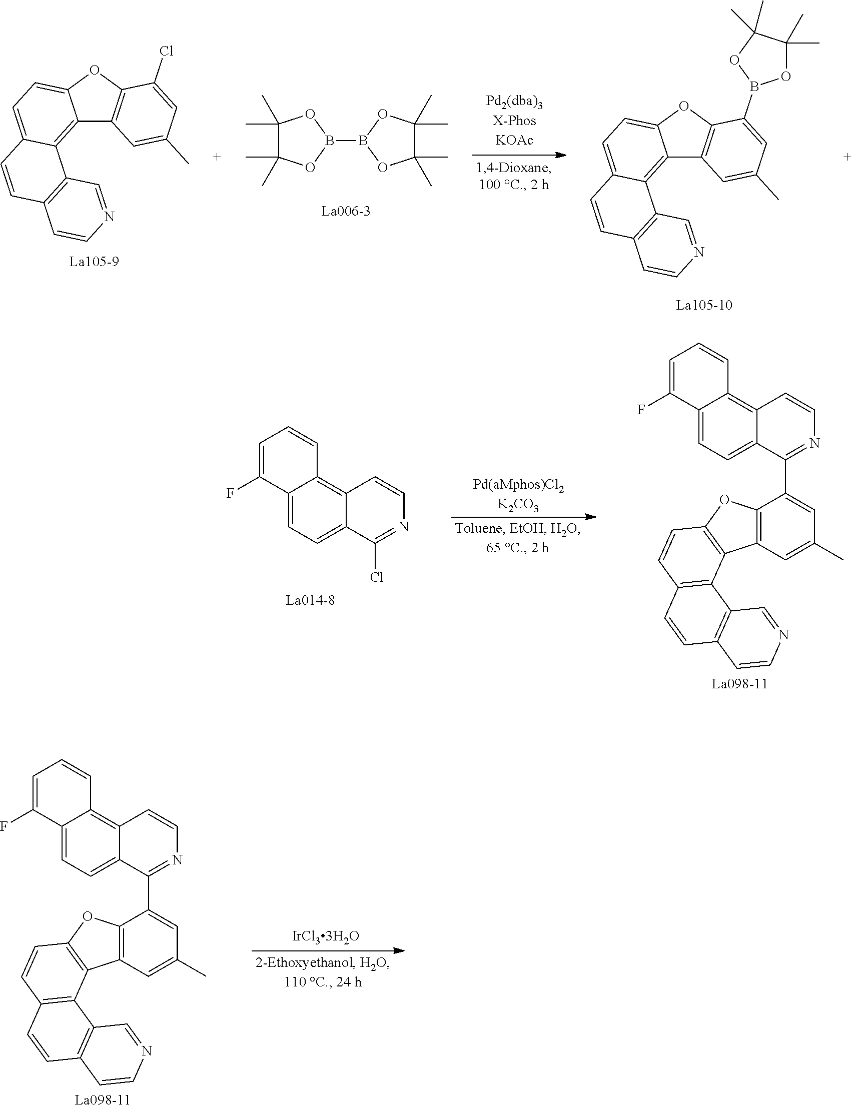

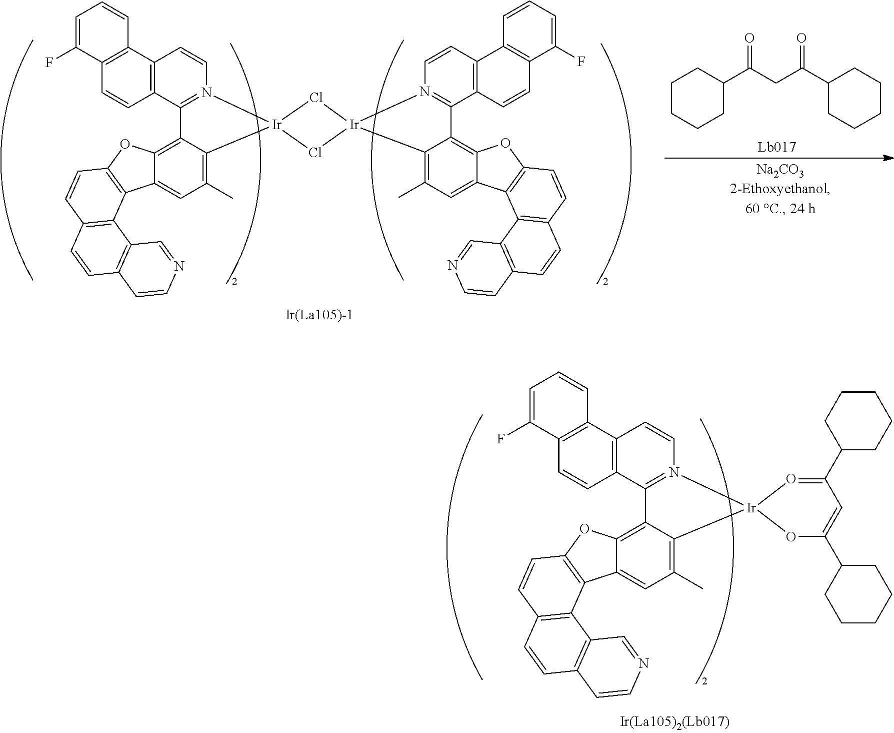

### Synthesis of Compound La105-2

The target compound La105-2 (32.18 g, purity: 99.18%, yield: 76.24%) with a mass spectrum (MS): 234.12 (M+H) was obtained according to the synthesis and purification method for compound La006-4, only the corresponding raw materials were changed.

### Synthesis of Compound La105-3

The target compound La105-3 (28.50 g, purity: 99.46%, yield: 71.06%) with a mass spectrum (MS): 291.97 (M+H) was obtained according to the synthesis and purification method for compound La006-8, only the corresponding raw materials were changed.

### Synthesis of Compound La105-4

The target compound La105-4 (27.68 g, purity: 99.41%, yield: 90.20%) with a mass spectrum (MS): 320.02 (M+H) was obtained according to the synthesis and purification method for compound La098-5, only the corresponding raw materials were changed.

### Synthesis of Compound La105-5

The target compound La105-5 (17.39 g, purity: 99.53%, yield: 70.27%) with a mass spectrum (MS): 287.98 (M+H) was obtained according to the synthesis and purification method for compound La098-6, only the corresponding raw materials were changed.

### Synthesis of Compound La105-6

The target compound La105-6 (15.31 g, purity: 99.27%, yield: 74.38%) with a mass spectrum (MS): 349.10 (M+H) was obtained according to the synthesis and purification method for compound La006-8, only the corresponding raw materials were changed.

### Synthesis of Compound La105-7

The target compound La105-7 (10.54 g, purity: 99.46%, yield: 69.67%) with a mass spectrum (MS): 352.07 (M+H) was obtained according to the synthesis and purification method for compound La006-9, only the corresponding raw materials were changed.

### Synthesis of Compound La105-8

The target compound La105-8 (7.69 g, purity: 99.44%, yield: 76.28%) with a mass spectrum (MS): 338.08 (M+H) was obtained according to the synthesis and purification method for compound La006-10, only the corresponding raw materials were changed.

### Synthesis of Compound La105-9

The target compound La105-9 (5.36 g, purity: 99.50%, yield: 75.97%) with a mass spectrum (MS): 318.07 (M+H) was obtained according to the synthesis and purification method for compound La006-11, only the corresponding raw materials were changed.

### Synthesis of Compound La105-10

The target compound La105-10 (5.26 g, purity: 99.56%, yield: 77.05%) with a mass spectrum (MS): 410.16 (M+H) was obtained according to the synthesis and purification method for compound La006-4, only the corresponding raw materials were changed.

### Synthesis of Compound La105-11

The target compound La105-11 (4.48 g, purity: 99.57%, yield: 73.69%) with a mass spectrum (MS): 479.15 (M+H) was obtained according to the synthesis and purification method for compound La006-14, only the corresponding raw materials were changed.

### Synthesis of Compound Ir(La105)-1

The target compound Ir(La105)-1 (5.55 g, yield: 74.28%) was obtained according to the synthesis and purification method for compound Ir(La006)-1, only the corresponding raw materials were changed. The target compound Ir(La105)-1 was used directly in the next step without purification.

### Synthesis of Compound Ir(La105)₂(Lb017)

The crude target compound Ir(La105)₂(Lb017) (1.86 g, purity: 99.80%, yield: 58.37%) was obtained according to the synthesis and purification method for compound Ir(La006)₂(Lb005), only the corresponding raw materials were changed. 1.86 g of crude compound Ir(La105)₂(Lb017) was sublimated and purified to obtain sublimated pure compound Ir(La105)₂(Lb017) (1.09 g, purity: 99.78%, yield: 58.60%), with a mass spectrum (MS): 1383.42 (M+H).

¹H NMR (400 MHz, CDCl₃) δ 9.52 (d, J=0.9 Hz, 2H), 8.75-8.72 (m, 2H), 8.59 (d, J=4.6 Hz, 2H), 8.22 (d, J=9.7 Hz, 2H), 8.16-8.04 (m, 6H), 8.03-7.97 (m, 4H), 7.92 (d, J=4.6 Hz, 2H), 7.87 (s, 2H), 7.84-7.79 (m, 2H), 7.67 (d, J=7.1 Hz, 2H), 7.58 (t, J=7.6 Hz, 2H), 7.26 (dd, J=7.7, 1.2 Hz, 2H), 5.70 (d, J=1.8 Hz, 1H), 2.60-2.55 (m, 2H), 2.37 (s, 6H), 1.82 (d, J=5.4 Hz, 4H), 1.70-1.55 (m, 10H), 1.43-1.34 (m, 6H).

### Example of Use: Manufacturing of Organic Electroluminescent Device

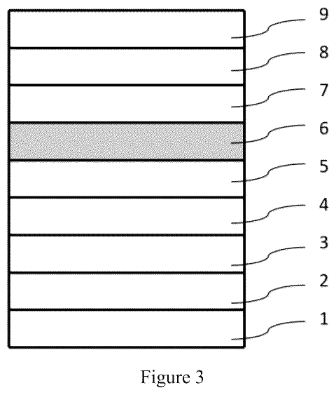

As shown in FIG. 3, the organic electroluminescent device included a glass substrate 1, an anode 2, a hole injection layer 3, a hole transport layer 4 (HTL), an electron blocking layer 5 (EBL), a light-emitting layer 6, an electron transport layer 7, an electron injection layer 8, and a cathode 9, which were stacked together.

A glass substrate 1 with a transparent indium tin oxide (ITO) (anode 2, indium tin oxide, 100 nm thick) electrode on its surface was provided, wherein the glass substrate 1 had a dimension of 50 mmx 50 mm×1.0 mm.

The glass substrate 1 was ultrasonically cleaned in ethanol for 10 minutes, then dried at 150° C., and then treated with N₂ Plasma for 30 minutes.

The cleaned glass substrate was mounted on a substrate support of a vacuum evaporation apparatus. Compound NDP-9 and Compound HTM 1 were co-evaporated on the surface of the anode 2 side to form a hole injection layer 3 with a thickness of 10 nm, wherein a weight ratio of Compound NDP-9 to Compound HTM 1 was 97:3.

Compound HTM 1 was evaporated on the surface of the hole injection layer 3 to form a hole transport layer 4 with a thickness of 60 nm.

Compound HTM 2 is evaporated on the surface of the hole transport layer 4 to form an electron blocking layer 5 with a thickness of 10 nm.

A light-emitting layer 6 with a thickness of 40 nm was formed by co-evaporation in a dual-host manner on the surface of the electron blocking layer 5; wherein a ratio of the host material to the red light dopant material was 97%: 3% by weight, the dual host materials were H1 and H2 (weight ratio of 1:1) respectively, and the red light dopant materials were the compound of the present disclosure and Comparative Compounds 1-3, respectively.

An electron transport material (ETL material) and LiQ were co-evaporated onto the surface of the light-emitting layer 6 to form an electron transport layer 7 with a thickness of 35 nm, wherein a weight ratio of ETL to LiQ was 50:50.

LiQ was evaporated onto the surface of the electron transport layer 7 to form an electron injection layer 8 with a thickness of 1 nm.

Mg and Ag (weight ratio of 1:9) were co-evaporated onto the surface of the electron injection layer 8 to form a cathode 9 with a thickness of 100 nm, thus an organic electroluminescent device was manufactured.

The structural formulas of NDP-9, HTM1, HTM2, host material H1, host material H2, ETL material, LiQ, and comparative compounds 1-3 are shown below:

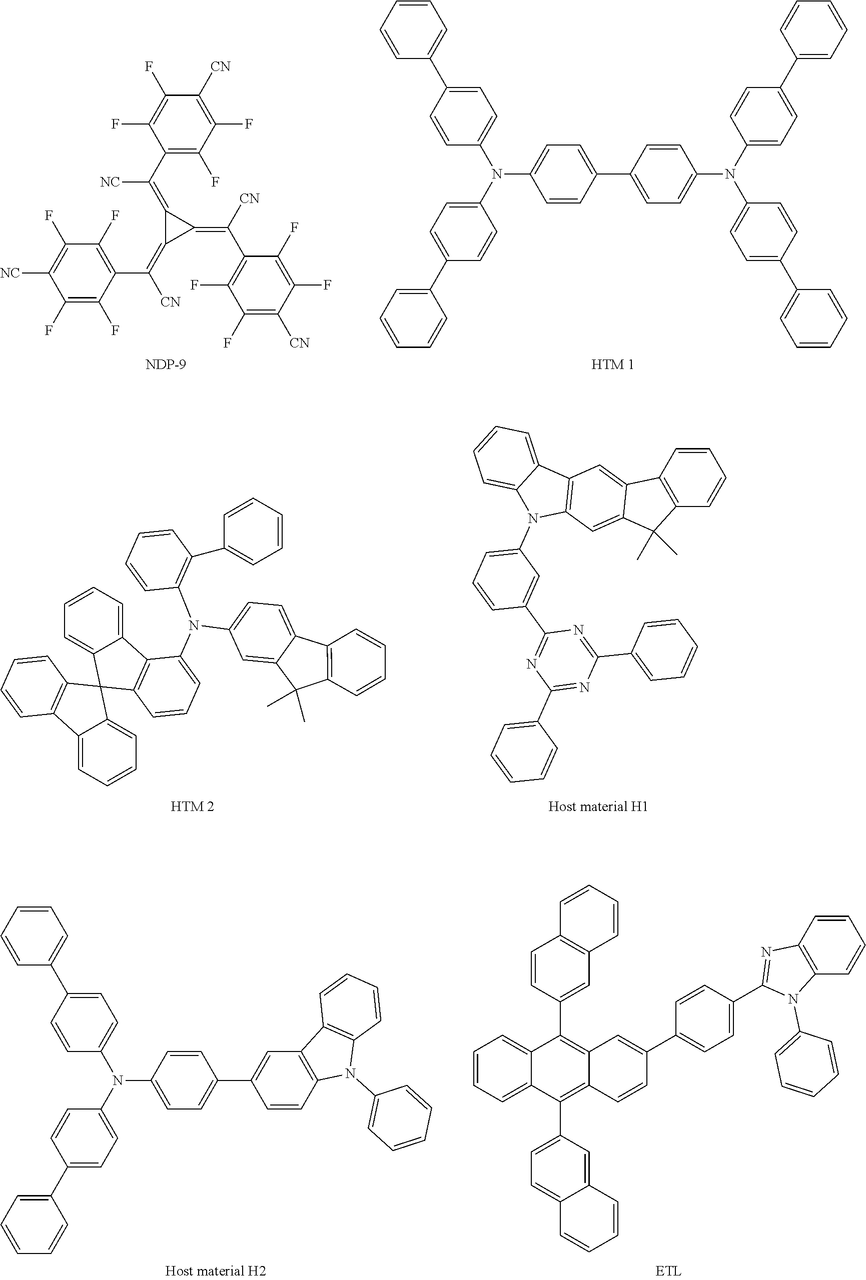

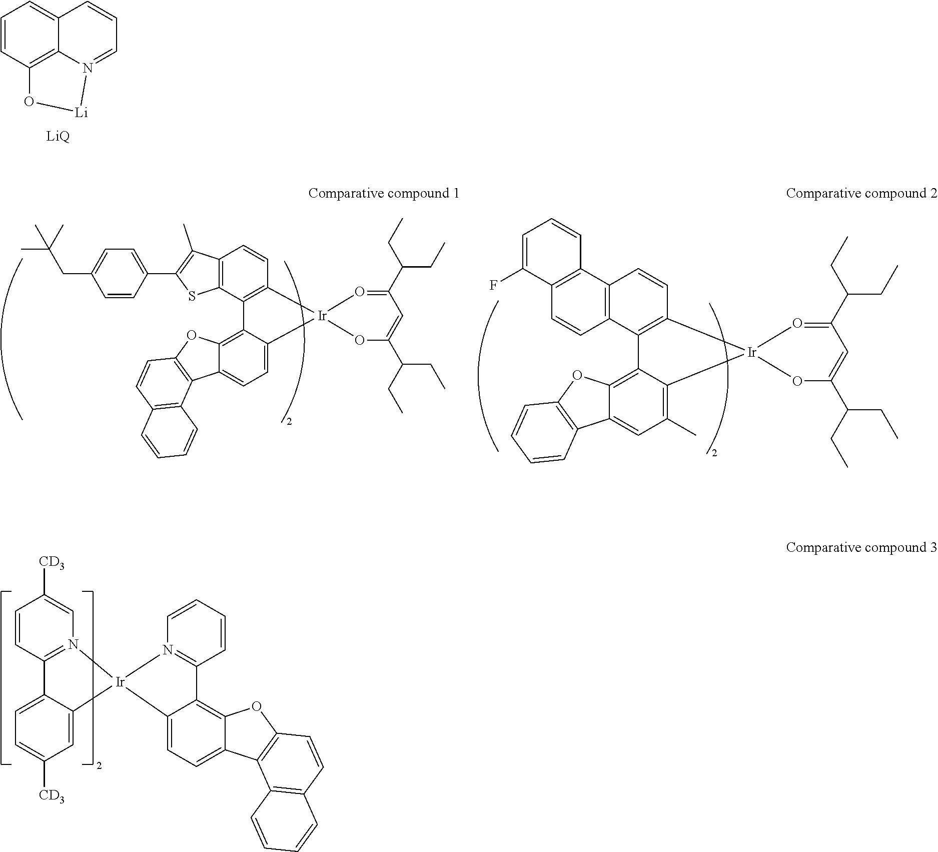

The organic electroluminescent devices prepared in Examples A1-A15 and Comparative Examples 1-4 of the present disclosure were shown in Table 1 below.

TABLE 1

| | | | | | Electron |
|---|---|---|---|---|---|
| | | | | | transport |
| | HIL | HTL | EBL | Light-emitting layer | layer |
| Example A1 | HTM1:NDP-9 | HTM1 | HTM2 | H1:H2:Ir(La006)₂(Lb005) | ETL:LiQ |
| Example A2 | HTM1:NDP-9 | HTM1 | HTM2 | H1:H2:Ir(La014)₂(Lb005) | ETL:LiQ |
| Example A3 | HTM1:NDP-9 | HTM1 | HTM2 | H1:H2:Ir(La017)₂(Lb005) | ETL:LiQ |
| Example A4 | HTM1:NDP-9 | HTM1 | HTM2 | H1:H2:Ir(La017)₂(Lb007) | ETL:LiQ |
| Example A5 | HTM1:NDP-9 | HTM1 | HTM2 | H1:H2:Ir(La022)₂(Lb005) | ETL:LiQ |
| Example A6 | HTM1:NDP-9 | HTM1 | HTM2 | H1:H2:Ir(La038)₂(Lb005) | ETL:LiQ |
| Example A7 | HTM1:NDP-9 | HTM1 | HTM2 | H1:H2:Ir(La038)₂(Lb031) | ETL:LiQ |
| Example A8 | HTM1:NDP-9 | HTM1 | HTM2 | H1:H2:Ir(La050)₂(Lb005) | ETL:LiQ |
| Example A9 | HTM1:NDP-9 | HTM1 | HTM2 | H1:H2:Ir(La055)₂(Lb005) | ETL:LiQ |
| Example A10 | HTM1:NDP-9 | HTM1 | HTM2 | H1:H2:Ir(La065)₂(Lb005) | ETL:LiQ |
| Example A11 | HTM1:NDP-9 | HTM1 | HTM2 | H1:H2:Ir(La071)₂(Lb043) | ETL:LiQ |
| Example A12 | HTM1:NDP-9 | HTM1 | HTM2 | H1:H2:Ir(La082)₂(Lb005) | ETL:LiQ |
| Example A13 | HTM1:NDP-9 | HTM1 | HTM2 | H1:H2:Ir(La092)₂(Lb031) | ETL:LiQ |
| Example A14 | HTM1:NDP-9 | HTM1 | HTM2 | H1:H2:Ir(La098)₂(Lb005) | ETL:LiQ |
| Example A15 | HTM1:NDP-9 | HTM1 | HTM2 | H1:H2:Ir(La105)₂(Lb017) | ETL:LiQ |
| Comparative | HTM1:NDP-9 | HTM1 | HTM2 | H1:H2:Comparative | ETL:LiQ |
| Example 1 | | | | Compound 1 | |
| Comparative | HTM1:NDP-9 | HTM1 | HTM2 | H1:H2:Comparative | ETL:LiQ |
| Example 2 | | | | Compound 2 | |
| Comparative | HTM1:NDP-9 | HTM1 | HTM2 | H1:H2:Comparative | ETL:LiQ |
| Example 3 | | | | Compound 3 | |

Evaluation: The above-mentioned organic electroluminescent device was subjected to device performance testing. In each of the examples and comparative examples, a constant current power supply (Keithley 2400) was used, and a constant current density (10 mA/cm²) was applied to the light-emitting element. The emission spectrum was measured using a spectral radiance luminance meter (CS 2000). The time (LT95) for the brightness to decay to 95% of its initial brightness was also measured. The results were shown in Table 2 below; the external quantum efficiency and lifespan were calculated with the values of Comparative Example 2 as 100.

TABLE 2

| | Starting | External | | Full Width | |
|---|---|---|---|---|---|
| | voltage@10 | quantum | Peak | at Half | |
| | mA/cm²/ | efficiency | wavelength/ | Maximum/ | LT95@ |
| | (V) | @10 mA/cm² | nm | nm | 5000 nits |
| Example A1 | 3.87 | 108 | 630 | 39 | 118 |
| Example A2 | 3.91 | 106 | 632 | 39 | 125 |
| Example A3 | 3.88 | 112 | 631 | 39 | 136 |
| Example A4 | 3.91 | 114 | 634 | 38 | 128 |
| Example A5 | 3.84 | 109 | 635 | 37 | 137 |
| Example A6 | 3.90 | 111 | 631 | 37 | 142 |
| Example A7 | 3.93 | 115 | 633 | 39 | 126 |
| Example A8 | 3.87 | 109 | 632 | 39 | 119 |
| Example A9 | 3.82 | 108 | 634 | 37 | 138 |
| Example A10 | 3.83 | 105 | 635 | 38 | 127 |
| Example A11 | 3.93 | 110 | 632 | 38 | 143 |
| Example A12 | 3.89 | 106 | 633 | 38 | 122 |
| Example A13 | 3.88 | 107 | 632 | 38 | 138 |
| Example A14 | 3.92 | 109 | 634 | 37 | 131 |
| Example A15 | 3.90 | 107 | 634 | 38 | 128 |
| Comparative | 4.55 | 97 | 621 | 56 | 94 |
| Example 1 | | | | | |
| Comparative | 3.97 | 100 | 621 | 42 | 100 |
| Example 2 | | | | | |
| Comparative | 3.11 | 96 | 568 | 49 | 98 |
| Example 3 | | | | | |

As can be seen from the data comparison in the table above, the compound of the present disclosure is a metal iridium complex prepared using an optional ring A-fused benzochalcogenophene as ligands. The prepared metal iridium complex possesses a strong rigid structure, and suppresses molecular vibrations via a cyclic fusion method, resulting in the complex having a narrow full width maximum. Meanwhile, this structure can suppress shoulder emission and reduce non-radiative transitions, which is beneficial for improving device efficiency and lifespan, such that the complex can be used as a dopant in organic electroluminescent devices. The compound of the present disclosure exhibits a deeper red spectrum with high color purity, demonstrating superior performance in terms of driving voltage, maximum external quantum efficiency, and device lifespan as compared with comparative compounds 1-3 under the same device configuration.

Compared with the existing technology, by using a special combination of optional azanaphthalene or phenanthrene fused benzofuran, the complex of the present disclosure unexpectedly provides a better device luminous efficiency, improved lifespan, and more saturated red luminescence. The above results indicate that the compounds of the present disclosure have advantages of low evaporation temperature, high photochemical and electrochemical stability, high color saturation, high luminous efficiency, and long device lifespan, thus can be used in organic electroluminescent devices. In particular, as a red light-emitting dopant, the compound of the present disclosure has the potential to be applied in the OLED industry, especially for displays, lighting and automobile taillight.

Furthermore, since the compounds of the present disclosure cannot be exhaustively listed one by one, Tables 1-2 above only list the properties of part of compounds or devices of the present disclosure. However, within the protection scope claimed herein, the compound represented by formula (1) provided in the present disclosure have advantages of high photochemical and electrochemical stability, low sublimation temperature, low driving voltage, high luminous efficiency, and long device lifespan, etc.

Although the embodiments of the present disclosure have been described in detail above, the present disclosure is not limited to the foregoing embodiments. Various modifications can be made by those skilled in the art within the scope of knowledge without departing from the gist of the present disclosure.

1. A metal iridium complex having a general formula of Ir(La)(Lb)(Lc), and a structure formula represented by formula (1): 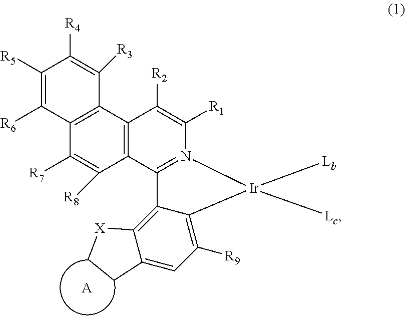
wherein: 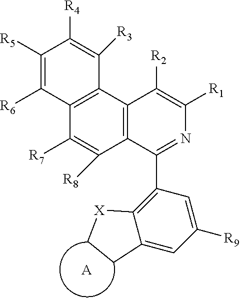
is a ligand La;
X is selected from the group consisting of O, S, and Se;
ring A is selected from the group consisting of a substituted or unsubstituted naphthalene ring, a substituted or unsubstituted phenanthrene ring, a substituted or unsubstituted azanaphthalene ring, and a substituted or unsubstituted azaphenanthrene ring;
R₁-R₉ are each independently selected from the group consisting of hydrogen, deuterium, halogen, cyano, isocyano, phosphino, substituted or unsubstituted C1-C40 alkyl, substituted or unsubstituted C3-C40 cycloalkyl, substituted or unsubstituted C1-C40 heteroalkyl, substituted or unsubstituted C3-C40 heterocycloalkyl, substituted or unsubstituted C3-C30 alkylsilyl, substituted or unsubstituted C1-C10 alkoxy, substituted or unsubstituted C7-C30 aralkyl, substituted or unsubstituted C6-C30 aryloxy, substituted or unsubstituted C2-C20 alkenyl, substituted or unsubstituted C2-C20 alkynyl, substituted or unsubstituted C6-C30 aryl, substituted or unsubstituted C3-C30 heteroaryl, substituted or unsubstituted C6-C30 arylsilyl, and substituted or unsubstituted C0-C20 alkylamino;
each substitution in R₁-R₉ is at least one selected from the group consisting of deuterium, F, Cl, Br, cyano, isocyano, phosphino, C1-C4 alkyl, C1-C4 alkoxy, C3-C6 cycloalkyl, and C1-C4 alkyl-substituted amino, wherein a number of substitutions ranges from monosubstitution to a maximum number of substitutions;
a heteroatom in the heteroalkyl, heterocycloalkyl, or heteroaryl is at least one selected from the group consisting of S, O, and N;
Lb and Lc are each a monoanionic bidentate ligand; optionally, any two of La, Lb, and Lc are connected by chemical bonds to form a multidentate ligand, or all three of La, Lb, and Lc are connected pairwise by chemical bonds to form a multidentate ligand; and
at least two of La, Lb and Lc are the same.

2. The metal iridium complex according to claim 1, wherein the ring A is one of the following structures: a substituted or unsubstituted naphthalene ring, a substituted or unsubstituted quinoline ring, a substituted or unsubstituted isoquinoline ring, a substituted or unsubstituted phenanthrene ring, a substituted or unsubstituted benzo[h]isoquinoline ring, a substituted or unsubstituted benzo[f]isoquinoline ring, or a substituted or unsubstituted 6-benzo[f]quinoline ring.

3. The metal iridium complex according to claim 1, wherein the ligand La is one of the structures represented by the following formulas (2) to (7): 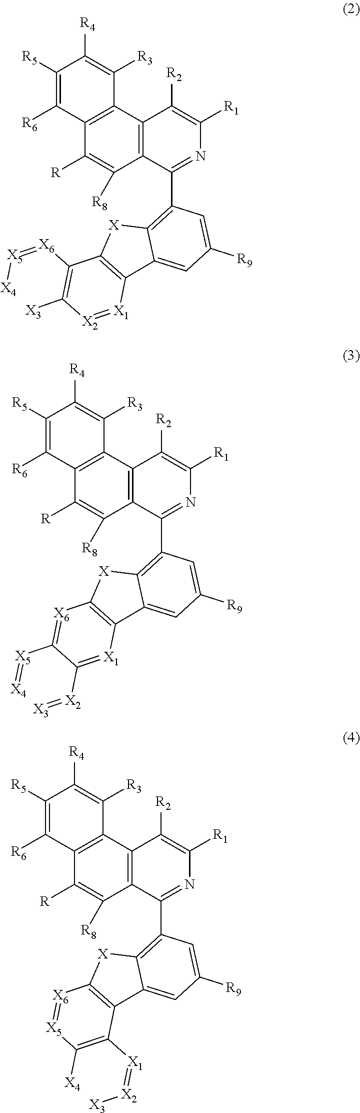 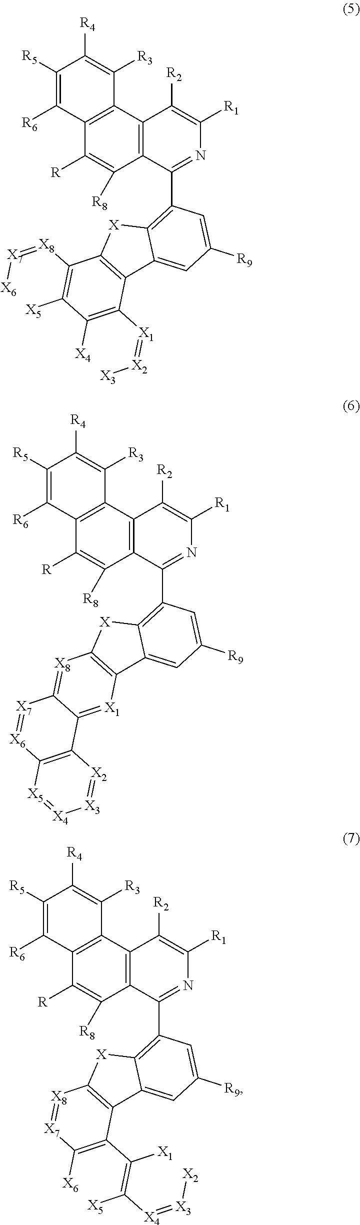
wherein:
X₁-X₈ are each independently selected from the group consisting of CR₀ and N;
R₀ is independently selected from the group consisting of hydrogen, deuterium, cyano, nitro, halogen, C1-C40 alkyl, C1-C40 heteroalkyl, C2-C40 alkenyl, C2-C40 alkynyl, C3-C40 cycloalkyl, C3-C40 heterocycloalkyl, C1-C40 alkoxy, C7-C30 aralkyl, C6-C30 aryloxy, C6-C30 aryl, C3-C30 heteroaryl, C3-C40 alkylsilane group, and C1-C40 alkylboryl.

4. The metal iridium complex according to claim 3, wherein X₃ or X₄ in formula (2) is N; X₁, X₃ or X₆ in formula (3) is N; X₃, X₄, X₅ or X₆ in formula (4) is N; X₂ in formula (5) is N; or X₂, X₇ or X₈ in formula (7) is N.

5. The metal iridium complex according to claim 3, wherein R₀ is independently selected from the group consisting of hydrogen, deuterium, cyano, halogen, C1-C10 alkyl, C3-C10 cycloalkyl, C6-C12 aryl, and C3-C12 heteroaryl.

6. The metal iridium complex according to claim 1, wherein R₁-R₈ are each independently selected from the group consisting of hydrogen, deuterium, halogen, cyano, substituted or unsubstituted C1-C10 alkyl, and substituted or unsubstituted C3-C6 heteroaryl.

7. The metal iridium complex according to claim 1, wherein Lb is a structure represented by formula (8): 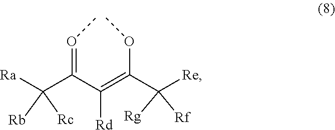
wherein:
a dotted line indicates a position connected to the metal iridium Ir;
Ra-Rg are each independently selected from the group consisting of hydrogen, deuterium, halogen, substituted or unsubstituted C1-C40 alkyl, substituted or unsubstituted C3-C40 cycloalkyl, substituted or unsubstituted C1-C40 heteroalkyl, and substituted or unsubstituted C3-C40 heterocycloalkyl;
optionally, any two of Ra, Rb, and Rc are connected to form an aliphatic ring structure, and optionally, any two of Re, Rf, and Rg are connected to form an aliphatic ring structure;
each substitution in Ra-Rg is at least one selected from the group consisting of deuterium, F, Cl, Br, cyano, isocyano, phosphino, C1-C4 alkyl, C1-C4 alkoxy, C3-C6 cycloalkyl, C1-C4 alkyl-substituted amino, wherein a number of substitutions ranges from monosubstitution to a maximum number of substitutions.

8. The metal iridium complex according to claim 7, wherein the aliphatic ring structure is a 3- to 20-membered liphatic ring structure.

9. The metal iridium complex according to claim 1, wherein X is O.

10. The metal iridium complex according to claim 1, wherein R₁-R₈ are each independently selected from the group consisting of hydrogen, deuterium, halogen, cyano, isocyano, substituted or unsubstituted C1-C20 alkyl, substituted or unsubstituted C3-C20 cycloalkyl, substituted or unsubstituted C1-C20 heteroalkyl, substituted or unsubstituted C3-C20 heterocycloalkyl, substituted or unsubstituted C6-C18 aryl, and substituted or unsubstituted C3-C18 heteroaryl.

11. The metal iridium complex according to claim 1, wherein R₉ is selected from the group consisting of substituted or unsubstituted C1-C20 alkyl, substituted or unsubstituted C3-C20 cycloalkyl, substituted or unsubstituted C1-C20 heteroalkyl, and substituted or unsubstituted C3-C20 heterocycloalkyl.

12. The metal iridium complex according to claim 9, wherein at least one of R₁-R₈ is an electron-withdrawing group, the others of R₁-R₈ are selected from the group consisting of hydrogen and deuterium, and the electron-withdrawing group is cyano, pyridyl, F, or F-substituted C1-C4 alkyl;
R₉ is substituted or unsubstituted C1-C10 alkyl, or substituted or unsubstituted C3-C10 cycloalkyl.

13. The metal iridium complex according to claim 3, wherein at most one of X₁-X₈ is N.

14. The metal iridium complex according to claim 3, wherein R₀ is independently selected from the group consisting of hydrogen, deuterium, cyano, halogen, C1-C20 alkyl, C3-C20 cycloalkyl, C3-C20 heterocycloalkyl, C6-C18 aryl, and C3-C18 heteroaryl.

15. The metal iridium complex according to claim 1, wherein Lc and La are the same, forming a (La) 2Ir (Lb) structure.

16. The metal iridium complex according to claim 7, wherein Ra, Rb, Rc are the same as Re, Rf, and Rg, respectively.

17. The metal iridium complex according to claim 7, wherein Ra, Rb, Rc, Re, Rf, and Rg are each independently selected from the group consisting of hydrogen, deuterium, halogen, substituted or unsubstituted C1-C20 alkyl, and substituted or unsubstituted C3-C20 cycloalkyl; optionally, any two of Ra, Rb, and Rc are connected to form a 3- to 10-membered aliphatic ring structure, and optionally, any two of Re, Rf, and Rg are connected to form a 3- to 10-membered aliphatic ring structure;
Rd is selected from the group consisting of hydrogen, deuterium, halogen, and substituted or unsubstituted C1-C20 alkyl;
each substitution in Ra-Rg is at least one selected from the group consisting of deuterium, F, Cl, Br, C1-C4 alkyl, and C3-C6 cycloalkyl.

18. The metal iridium complex according to claim 1, wherein Lb is one of the following structural formulas, or one of the following structural formulas in which hydrogen is substituted by at least one selected from the group consisting of deuterium and fluorine, and a number of substitutions ranges from monosubstitution to a maximum number of substitutions:

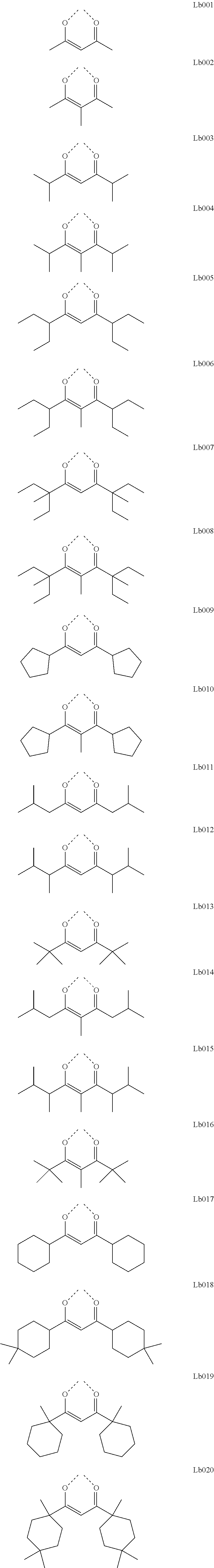

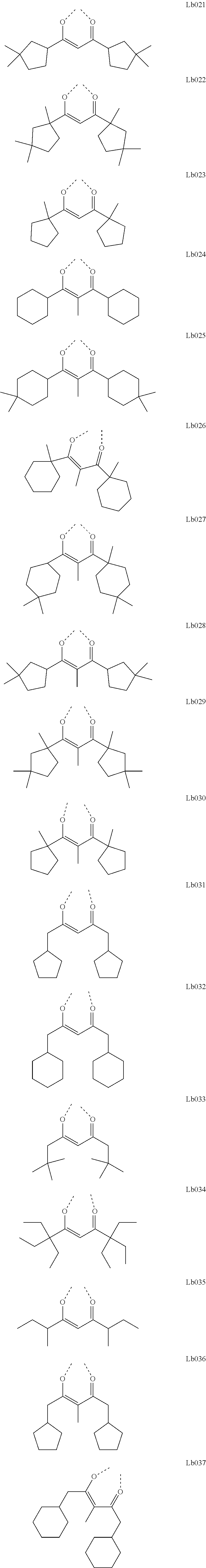

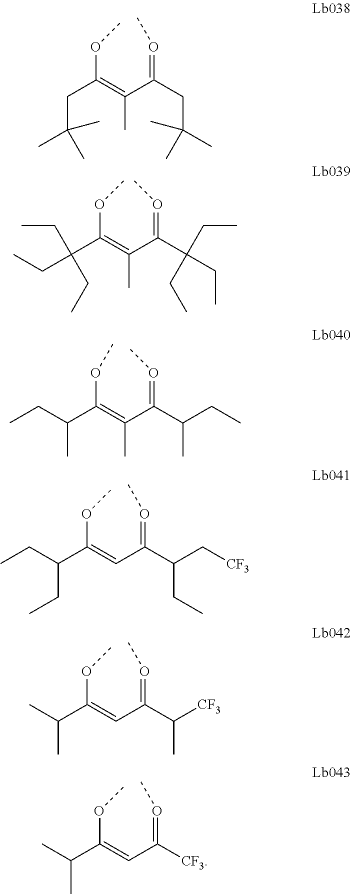

19. The metal iridium complex according to claim 1, wherein La is one of the following structural formulas, or one of the following structural formulas in which hydrogen is substituted by at least one selected from the group consisting of deuterium and fluorine, and a number of substitutions ranges from monosubstitution to a maximum number of substitutions:

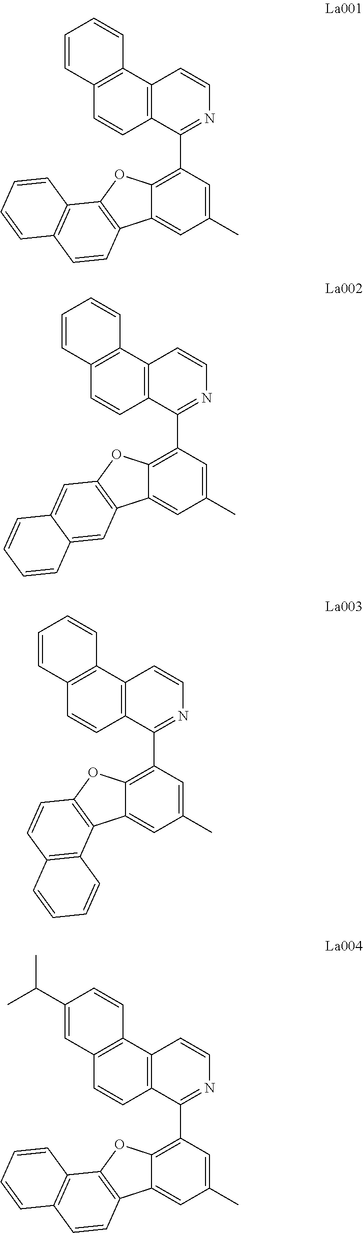

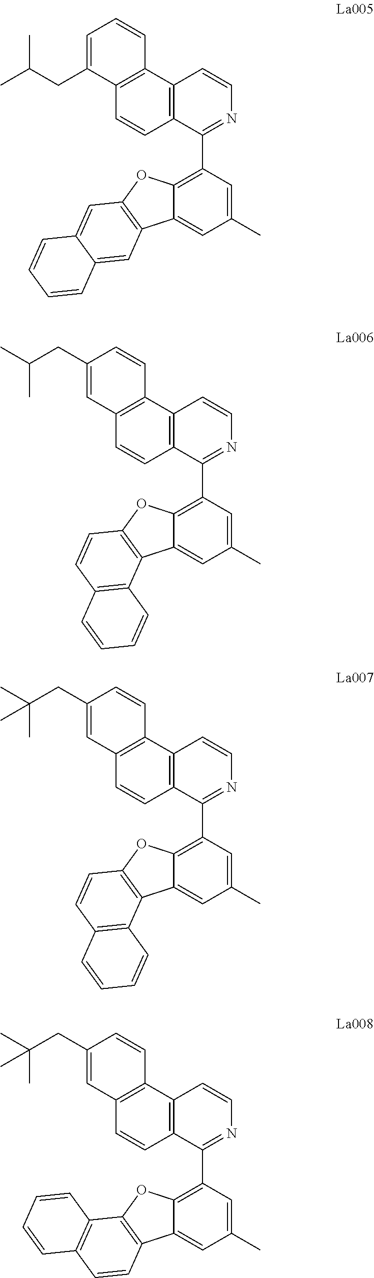

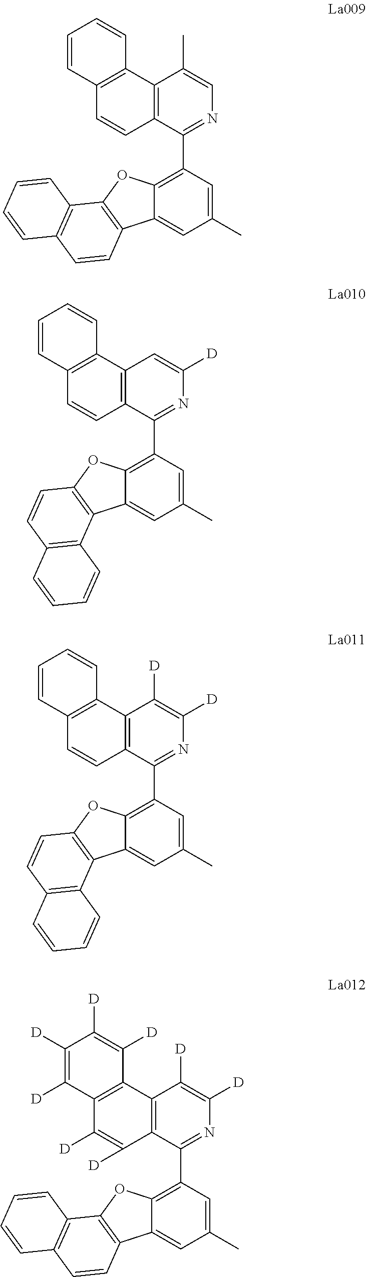

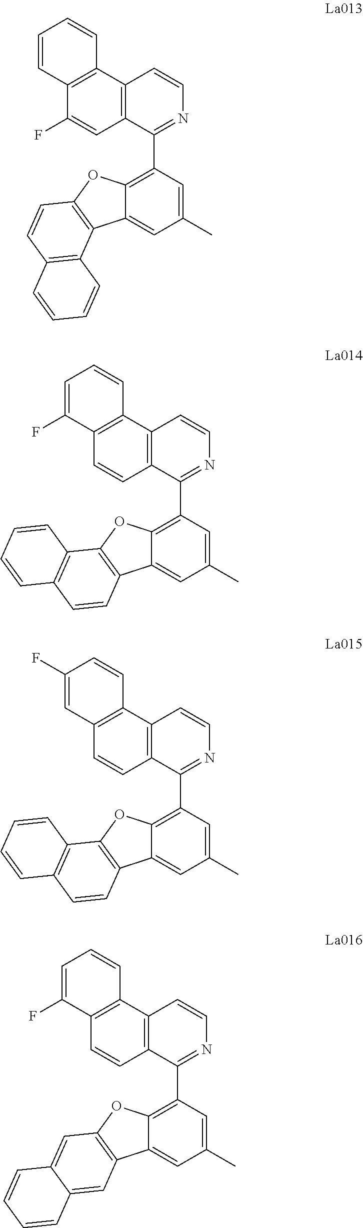 [SMILES: Cc1cc(-c2nccc3c2cc(F)c2ccccc23)c2oc3ccc4ccccc4c3c2c1 ; Cc1cc(-c2nccc3c2ccc2c(F)cccc23)c2oc3c4ccccc4ccc3c2c1 ; Cc1cc(-c2nccc3c2ccc2cc(F)ccc23)c2oc3c4ccccc4ccc3c2c1 ; Cc1cc(-c2nccc3c2ccc2c(F)cccc23)c2oc3cc4ccccc4cc3c2c1]

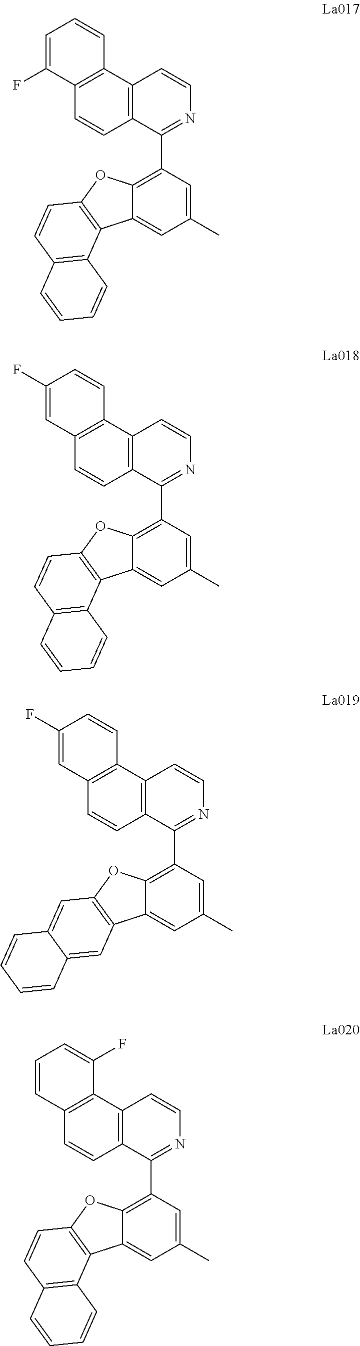 [SMILES: Cc1cc(-c2nccc3c2ccc2c(F)cccc23)c2oc3ccc4ccccc4c3c2c1 ; Cc1cc(-c2nccc3c2ccc2cc(F)ccc23)c2oc3ccc4ccccc4c3c2c1 ; Cc1cc(-c2nccc3c2ccc2cc(F)ccc23)c2oc3cc4ccccc4cc3c2c1 ; Cc1cc(-c2nccc3c2ccc2cccc(F)c23)c2oc3ccc4ccccc4c3c2c1]

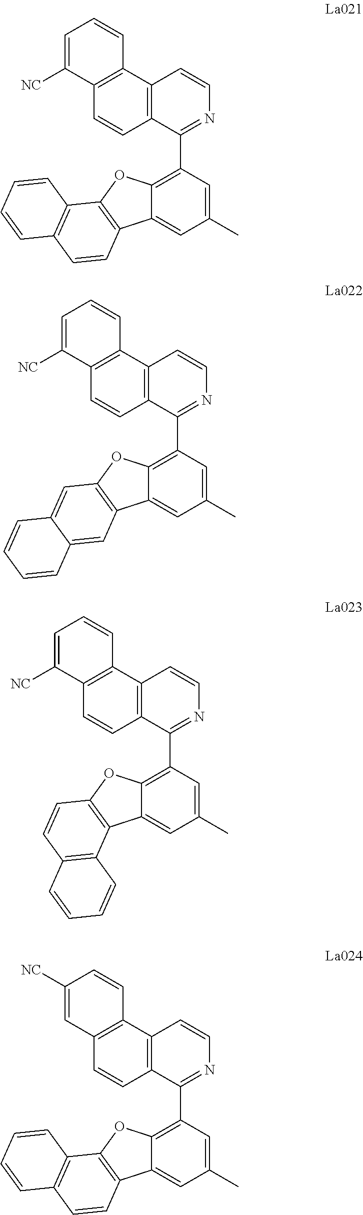

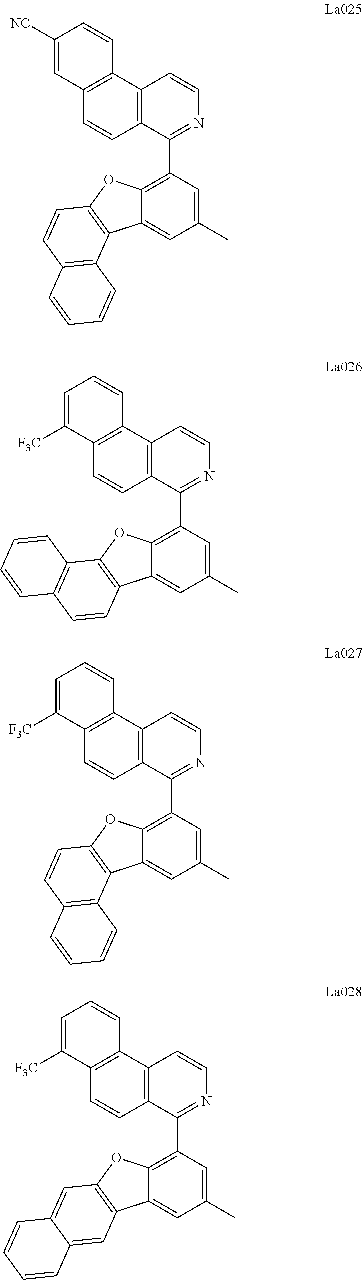

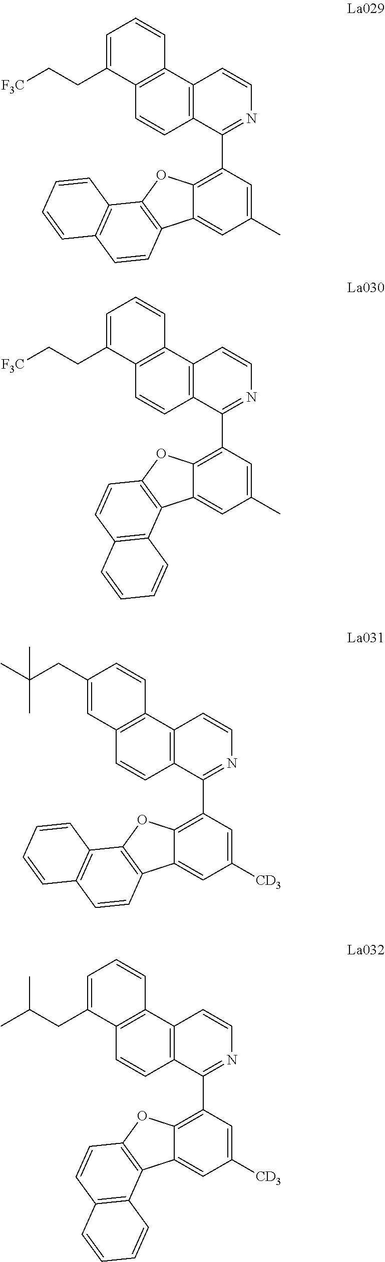

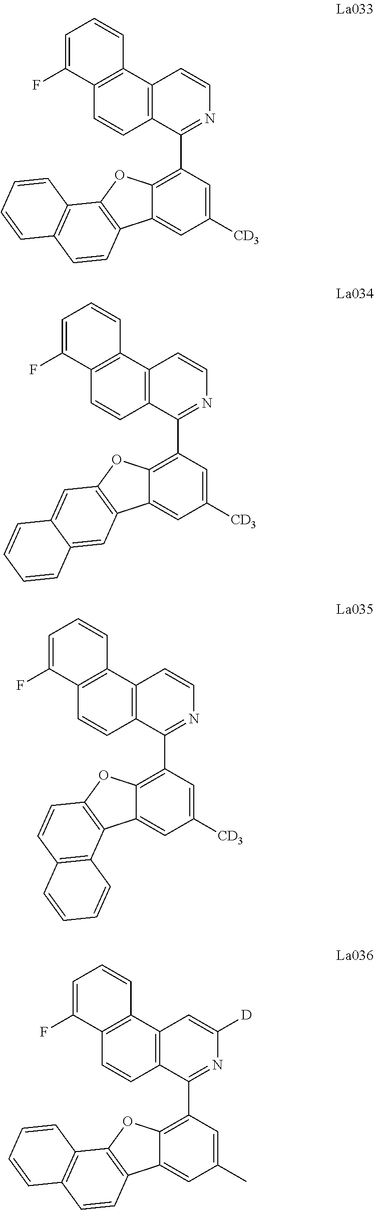

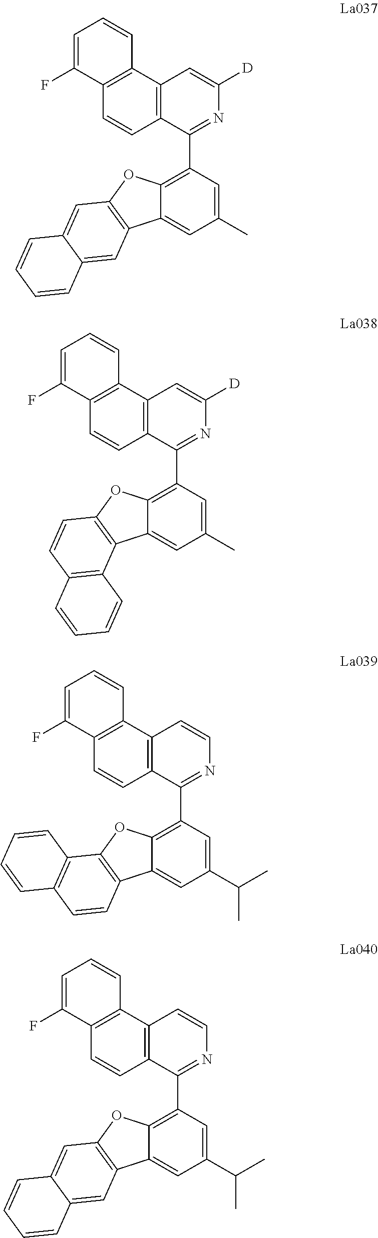

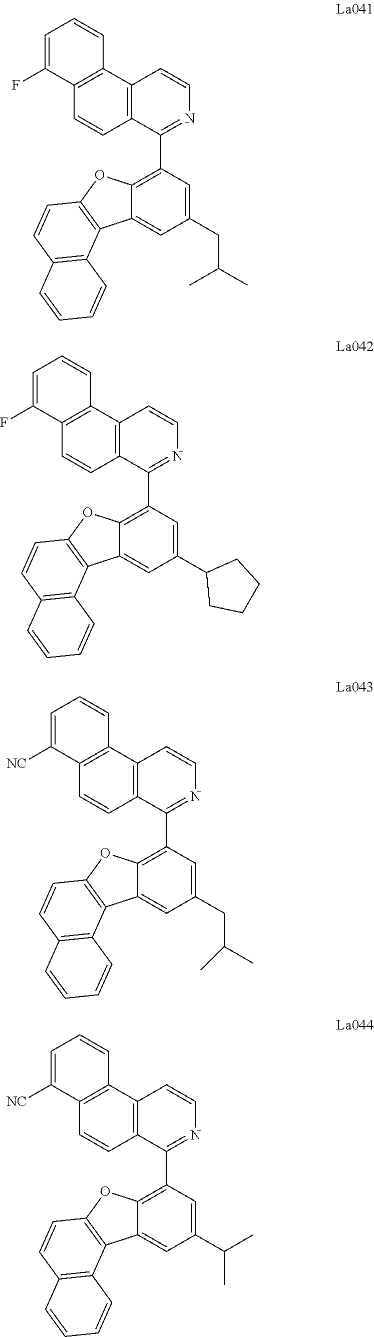

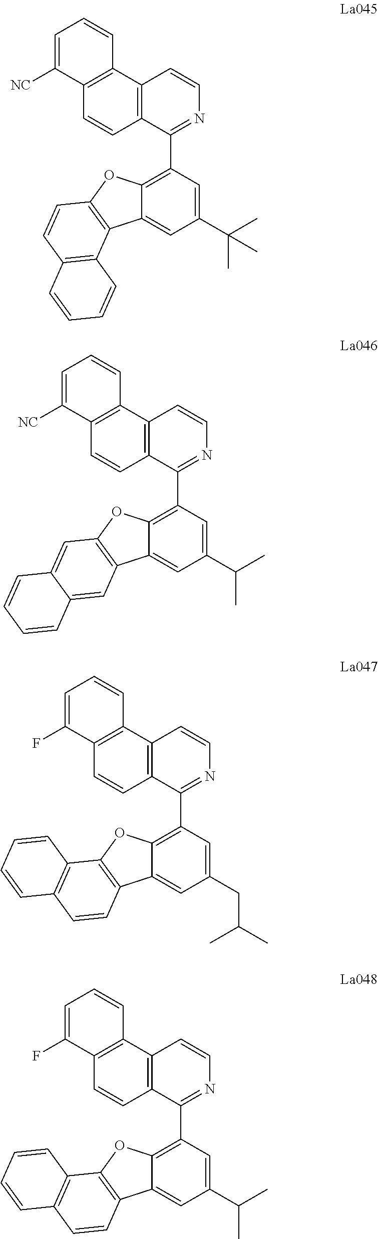

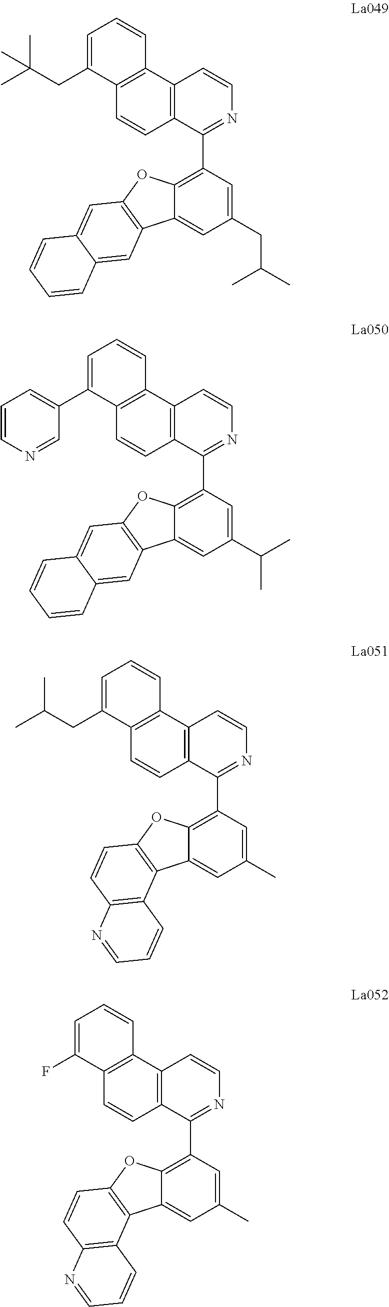

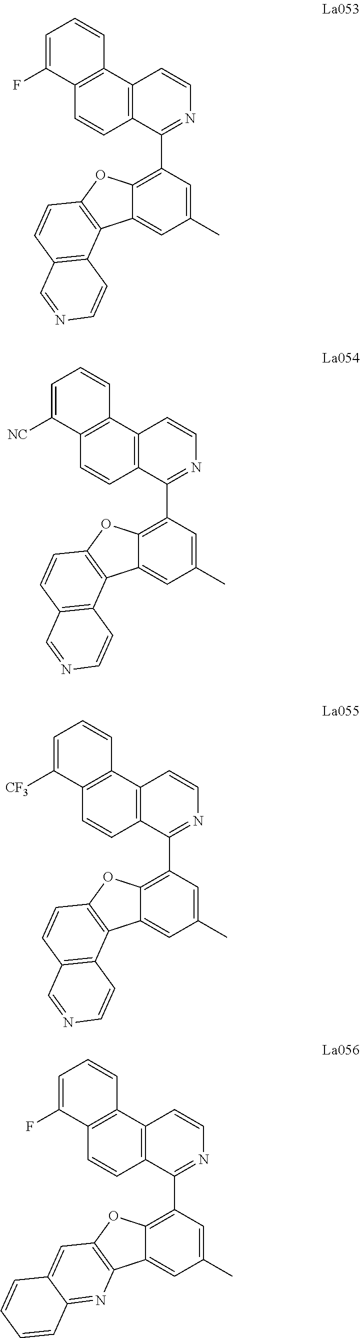

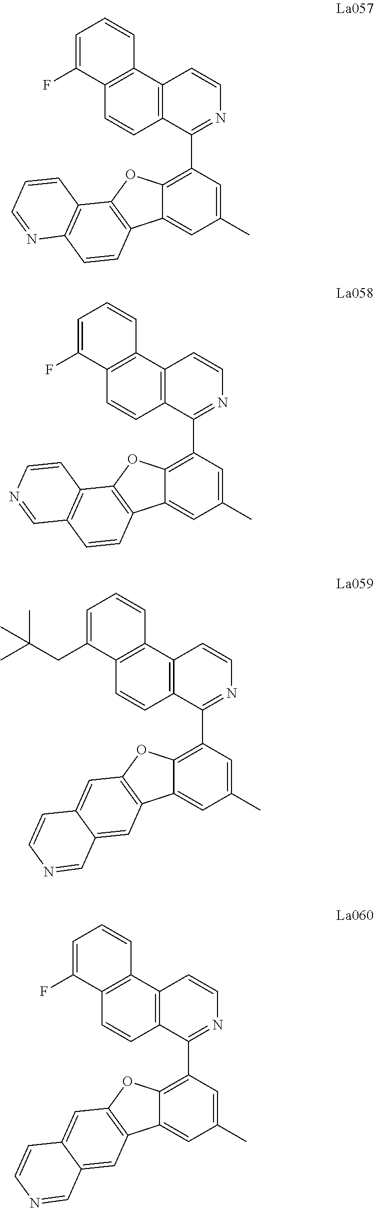

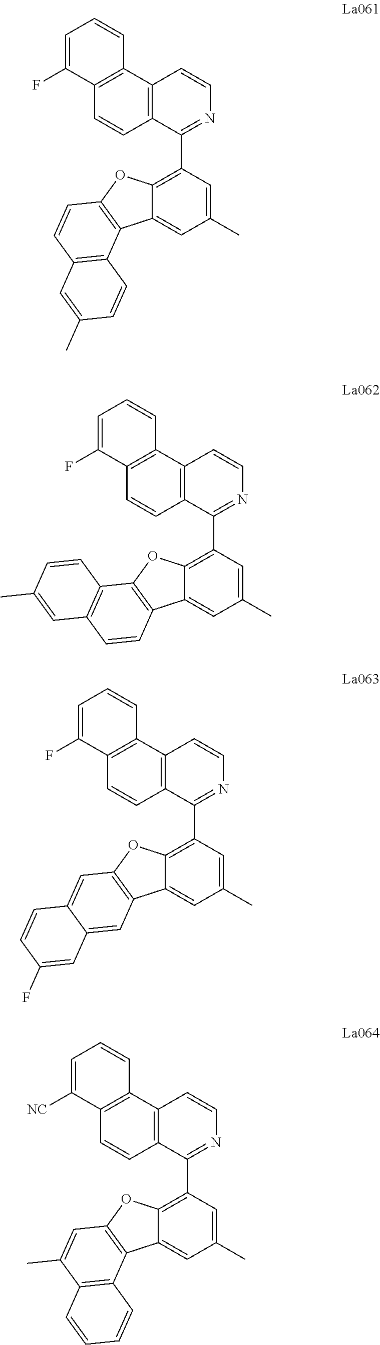

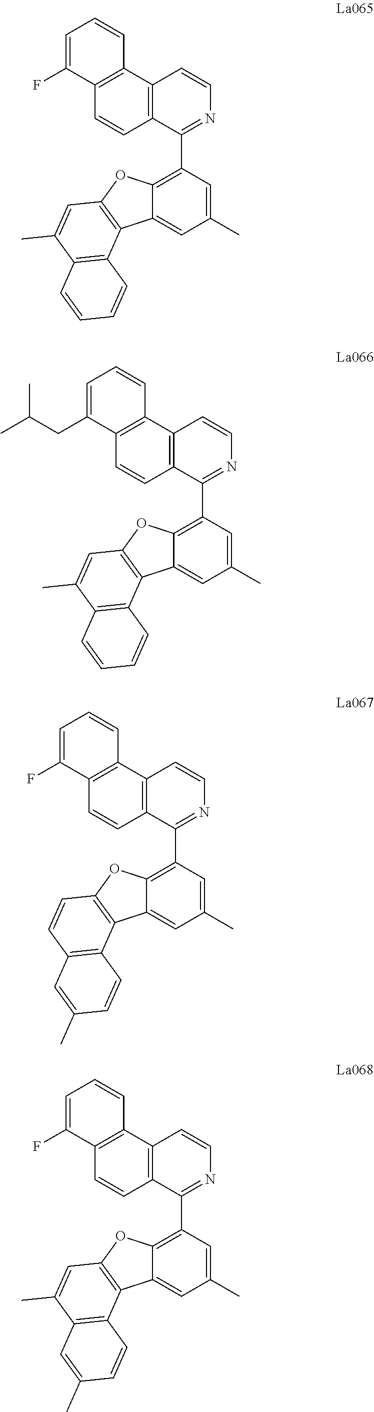

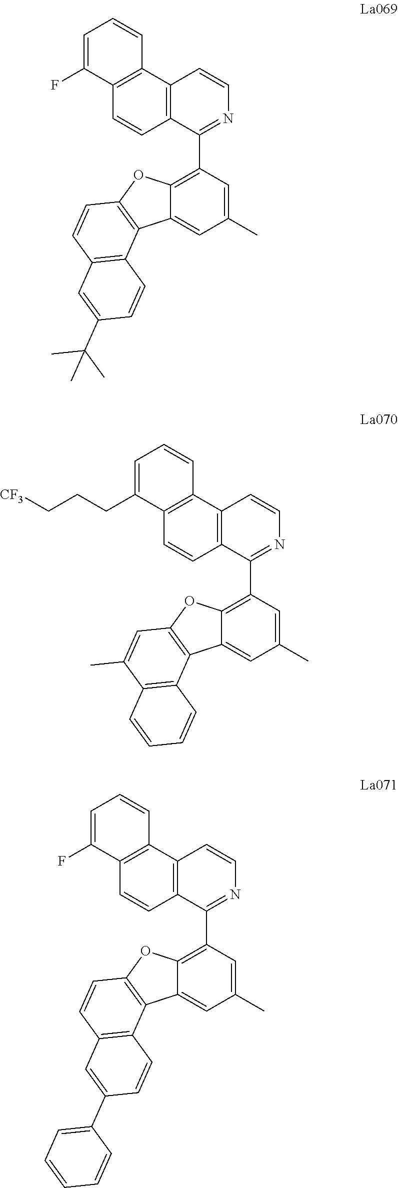 [SMILES: Cc1cc(-c2nccc3c2ccc2c(F)cccc23)c2oc3ccc4cc(C(C)(C)C)ccc4c3c2c1 ; Cc1cc(-c2nccc3c2ccc2c(CCCC(F)(F)F)cccc23)c2oc3cc(C)c4ccccc4c3c2c1 ; Cc1cc(-c2nccc3c2ccc2c(F)cccc23)c2oc3ccc4cc(-c5ccccc5)ccc4c3c2c1]

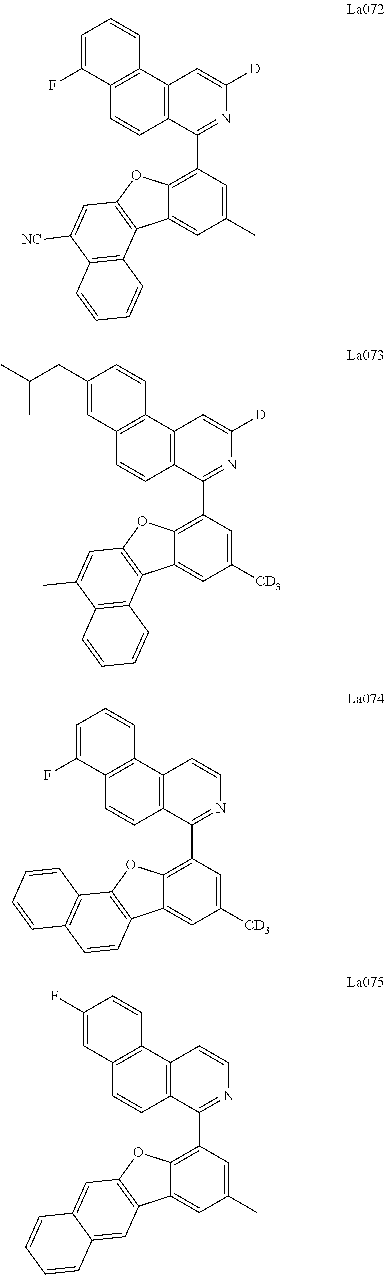

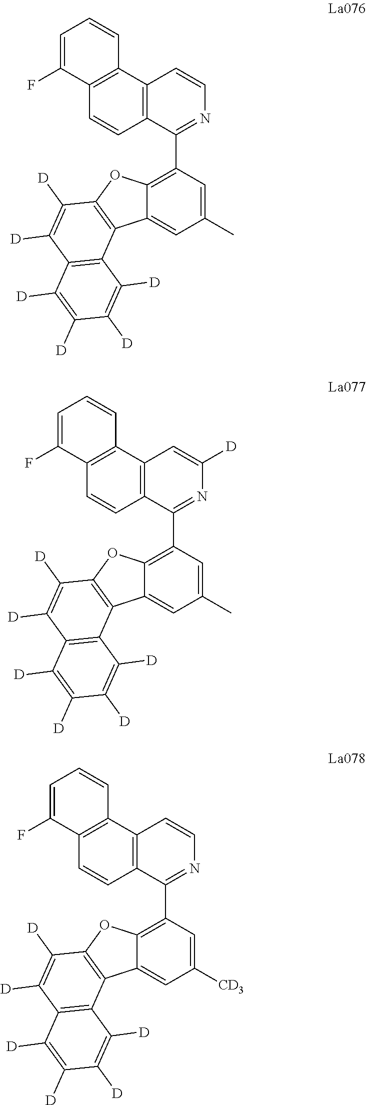

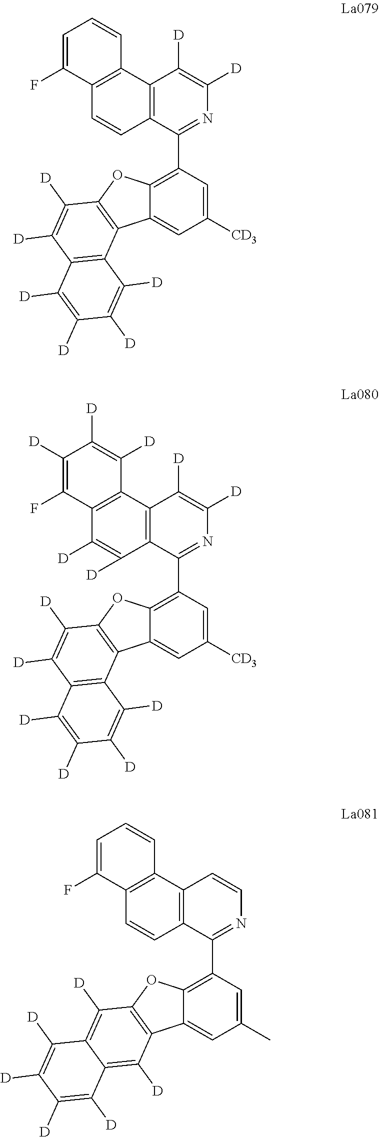 [SMILES: [2H]c1nc(-c2cc(C([2H])([2H])[2H])cc3c2oc2c([2H])c([2H])c4c([2H])c([2H])c([2H])c([2H])c4c23)c2ccc3c(F)cccc3c2c1[2H] ; [2H]c1nc(-c2cc(C([2H])([2H])[2H])cc3c2oc2c([2H])c([2H])c4c([2H])c([2H])c([2H])c([2H])c4c23)c2c([2H])c([2H])c3c(F)c([2H])c([2H])c([2H])c3c2c1[2H] ; [2H]c1c([2H])c([2H])c2c([2H])c3c(oc4c(-c5nccc6c5ccc5c(F)cccc56)cc(C)cc43)c([2H])c2c1[2H]]

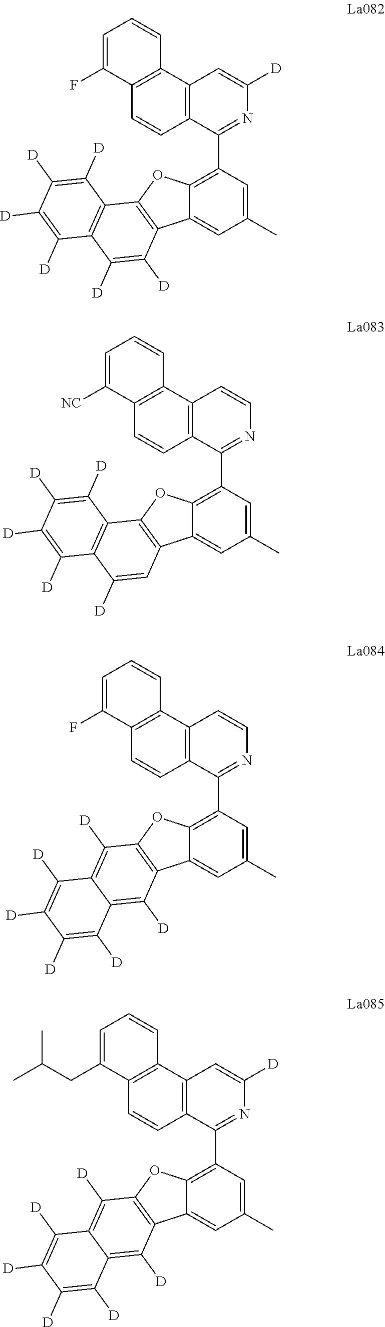 [SMILES: [2H]c1cc2c(ccc3c(F)cccc32)c(-c2cc(C)cc3c2oc2c4c([2H])c([2H])c([2H])c([2H])c4c([2H])c([2H])c32)n1 ; [2H]c1c([2H])c([2H])c2c(c([2H])cc3c4cc(C)cc(-c5nccc6c5ccc5c(C#N)cccc56)c4oc32)c1[2H] ; [2H]c1c([2H])c([2H])c2c([2H])c3c(oc4c(-c5nccc6c5ccc5c(F)cccc56)cc(C)cc43)c([2H])c2c1[2H] ; [2H]c1cc2c(ccc3c(CC(C)C)cccc32)c(-c2cc(C)cc3c2oc2c([2H])c4c([2H])c([2H])c([2H])c([2H])c4c([2H])c23)n1]

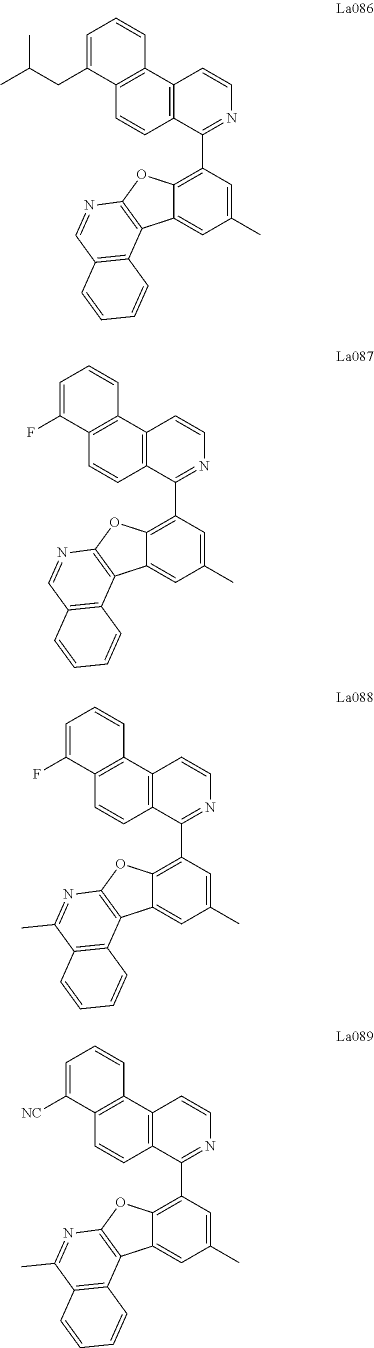

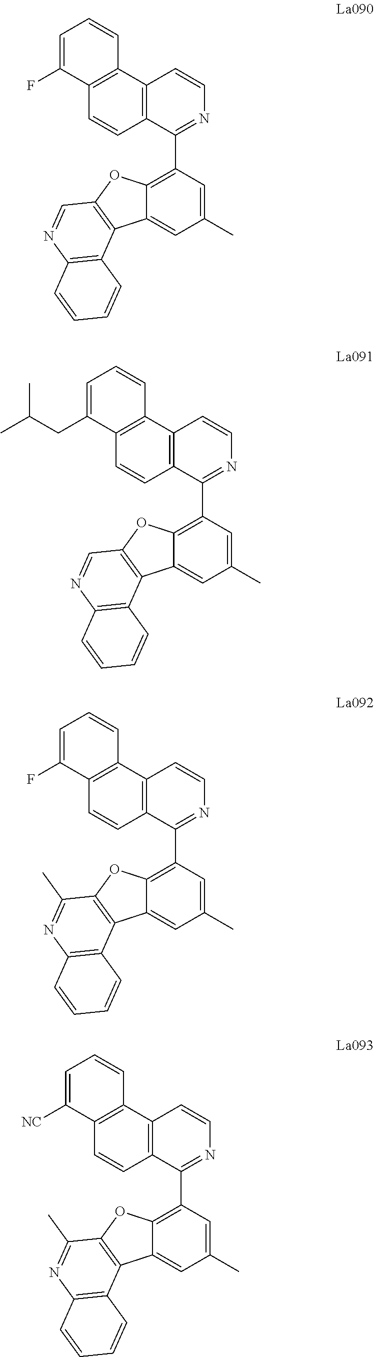

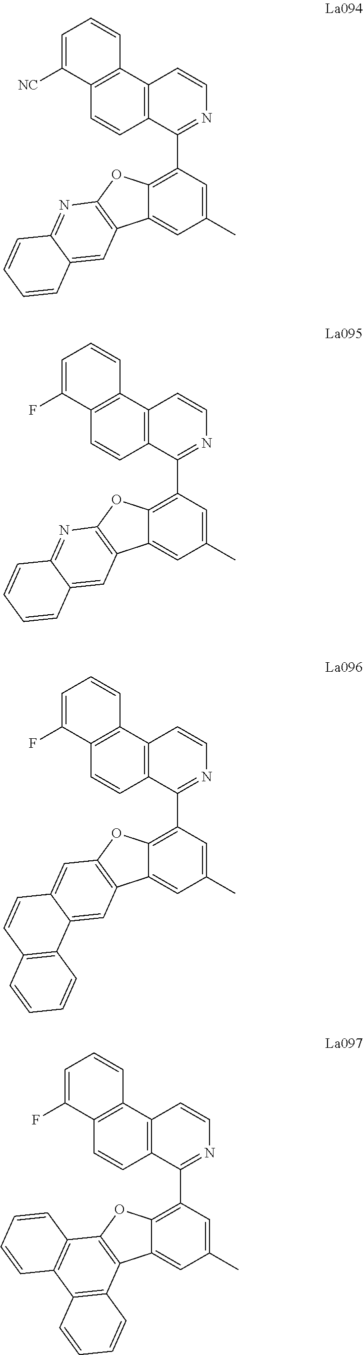 [SMILES: Cc1cc(-c2nccc3c2ccc2c(C#N)cccc23)c2oc3nc4ccccc4cc3c2c1 ; Cc1cc(-c2nccc3c2ccc2c(F)cccc23)c2oc3nc4ccccc4cc3c2c1 ; Cc1cc(-c2nccc3c2ccc2c(F)cccc23)c2oc3cc4ccc5ccccc5c4cc3c2c1 ; Cc1cc(-c2nccc3c2ccc2c(F)cccc23)c2oc3c4ccccc4c4ccccc4c3c2c1]

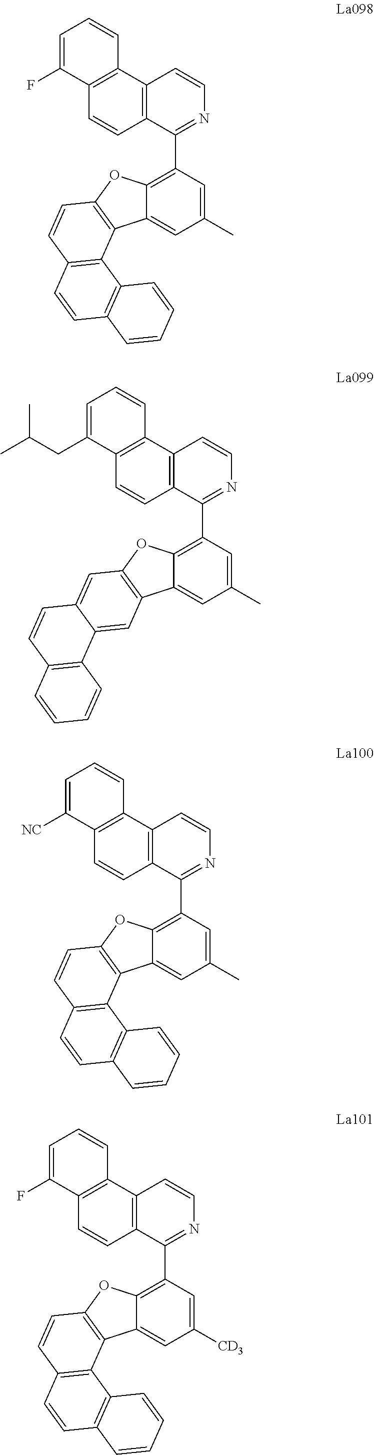

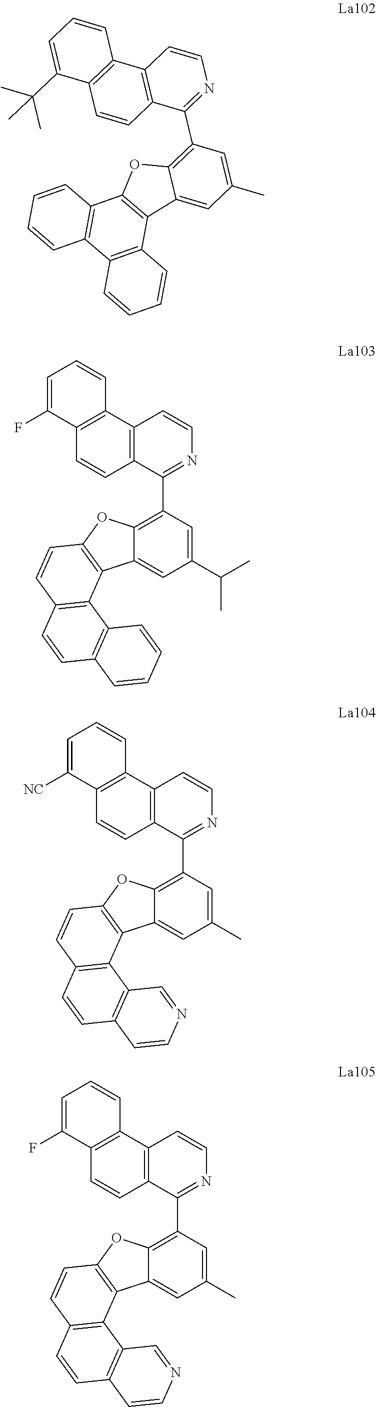

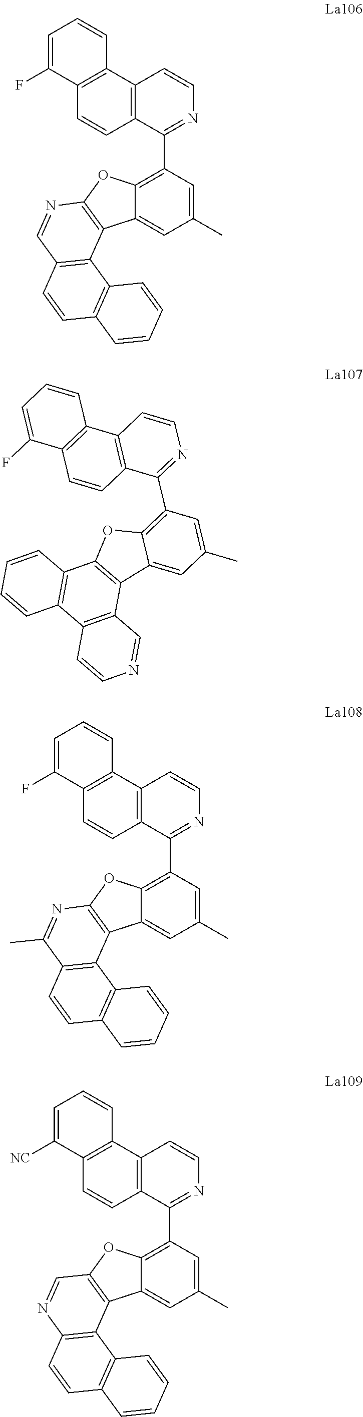

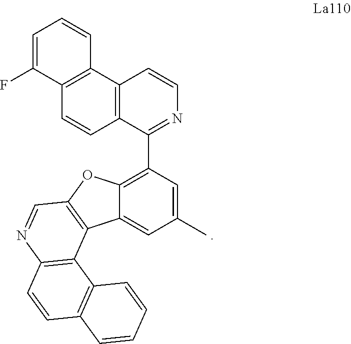 [SMILES: Cc1cc(-c2nccc3c2ccc2c(F)cccc23)c2oc3cnc4ccc5ccccc5c4c3c2c1]

20. An organic electroluminescent device, comprising: a cathode, an anode, and an organic layer arranged between the cathode and the anode, wherein at least one layer of the organic layer comprises the metal iridium complex of claim 1.
